(19) United States
(12) Patent Application Publication
(10) Pub. No.: US 2026/0370381 A1
(43) Pub. Date: Nov. 19, 2026

(54) METHOD, COMMUNICATION DEVICE, PROCESSING DEVICE, AND STORAGE MEDIUM FOR PERFORMING ENCODING

(71) Applicant: LG ELECTRONICS INC., Seoul (KR)

(72) Inventor: Bonghoe KIM, Seoul (KR)

(73) Assignee: LG ELECTRONICS INC., Seoul (KR)

(21) Appl. No.: 19/103,797

(22) PCT Filed: Aug. 18, 2022
(86) PCT No.: PCT/KR2022/012321

§ 371 Date: Feb. 13, 2025

(51) Int. Cl. H04L 1/00

(52) U.S. Cl. CPC H04L 1/0057

(57) ABSTRACT

A communication device determines an input u_n to a polar code on the basis of a length N of the polar code, a length K of the information block, and a polar sequence of Q^{N-1}₀={Q₀, Q₁, . . . , Q_{N-1}} having a length N and determines bits coded on the basis of encoding the input u_n on the basis of the polar code and the polar sequence. Here, Q^{N}ᵢ indicates a bit index and W(Q^{N}ᵢ) indicates a reliability of the bit index of Q^{N}ᵢ. The bit indices of the polar sequence satisfy the following: when expressed in a binary number, the greater the number of 1s, the higher the reliability, and when expressed in a binary number, the bit indices including the same number of is have a reliability of W(Q^{N}ₓ)<W(Q^{N}_{y}) for Q^{N}ₓ<Q^{N}_{y}.

### CROSS-REFERENCE TO RELATED APPLICATION(S)

This application is the National Stage filing under 35 U.S.C. 371 of International Application No. PCT/KR2022/012321, filed on Aug. 18, 2022, the contents of which are all incorporated by reference herein in its entirety.

### TECHNICAL FIELD

The present disclosure relates to a wireless communication system.

### BACKGROUND

A variety of technologies, such as machine-to-machine (M2M) communication, machine type communication (MTC), and a variety of devices demanding high data throughput, such as smartphones and tablet personal computers (PCs), have emerged and spread. Accordingly, the volume of data throughput demanded to be processed in a cellular network has rapidly increased. In order to satisfy such rapidly increasing data throughput, carrier aggregation technology or cognitive radio technology for efficiently employing more frequency bands and multiple input multiple output (MIMO) technology or multi-base station (BS) cooperation technology for raising data capacity transmitted on limited frequency resources have been developed.

As more and more communication devices have required greater communication capacity, there has been a need for enhanced mobile broadband (eMBB) communication relative to legacy radio access technology (RAT). In addition, massive machine type communication (mMTC) for providing various services at anytime and anywhere by connecting a plurality of devices and objects to each other is one main issue to be considered in next-generation communication.

Communication system design considering services/user equipment (UEs) sensitive to reliability and latency is also under discussion. The introduction of next-generation RAT is being discussed in consideration of eMBB communication, mMTC, ultra-reliable and low-latency communication (URLLC), and the like.

### SUMMARY

As new radio communication technology has been introduced, the number of UEs to which a BS should provide services in a prescribed resource region is increasing and the volume of data and control information that the BS transmits/receives to/from the UEs to which the BS provides services is also increasing. Since the amount of resources available to the BS for communication with the UE(s) is limited, a new method for the BS to efficiently receive/transmit uplink/downlink data and/or uplink/downlink control information from/to the UE(s) using the limited radio resources is needed. In other words, due to increase in the density of nodes and/or the density of UEs, a method for efficiently using high-density nodes or high-density UEs for communication is needed.

A method to efficiently support various services with different requirements in a wireless communication system is also needed.

Overcoming delay or latency is an important challenge to applications, performance of which is sensitive to delay/latency.

There is a need for a method to further improve the performance of polar codes, which is proposed as an alternative to existing channel codes.

The objects to be achieved with the present disclosure are not limited to what has been particularly described hereinabove and other objects not described herein will be more clearly understood by persons skilled in the art from the following detailed description.

In an aspect of the present disclosure, a method of encoding an information block in a wireless communication system is provided. The method includes determining an input u_n to a polar code based on a length N of the polar code, a length K of the information block, and a polar sequence Q^{N-1}₀={Q₀, Q₁, . . . , Q^{N-1}} of length N, determining coded bits based on the input u_n being encoded based on the polar code of length N and the polar sequence Q^{N-1}₀={Q₀, Q₁, . . . , Q_{N-1}} of length N, and transmitting the coded bits to another communication device. The polar sequence Q^{N-1}₀={Q₀, Q₁, . . . , Q^{N-1}} of length N is defined in ascending order of reliability W(Q^{N}₀)<W(Q^{N}₁)< . . . <W(Q^{N}_{N-1}), where 0<=Q^{N}ᵢ<=N−1 is a bit index for i=0, 1, . . . , N−1 and W(Q^{N}ᵢ) is the reliability of bit index Q^{N}ᵢ. Determining the input u_n includes determining K input indices at which K bits of the information block are to be located and input indices to be frozen from among input indices 0 to N−1 of the polar code of length N, based on the polar sequence Q^{N-1}₀={Q₀, Q₁, . . . , Q_{N-1}} of length N. Bit indices of the polar sequence Q^{N-1}₀={Q₀, Q₁, . . . , Q_{N-1}} of length N satisfy i) reliability increases as a number of 1s when expressed in binary increases, and ii) bit indices having the same number of is when expressed in binary are W(Q^{N}ₓ)<W(Q^{N}_{y}) for Q^{N}ₓ<Q^{N}_{y}.

In another aspect of the present disclosure, a communication device for encoding an information block in a wireless communication system is provided. The communication device includes at least one transceiver, at least one processor, and at least one computer memory operably connected to the at least one processor and storing instructions that, when executed, cause the at least one processor to perform operations. The operations include determining an input u_n to a polar code based on a length N of the polar code, a length K of the information block, and a polar sequence Q^{N-1}₀={Q₀, Q₁, . . . , Q^{N-1}} of length N, determining coded bits based on the input u_n being encoded based on the polar code of length N and the polar sequence Q^{N-1}₀={Q₀, Q₁, . . . , Q_{N-1}} of length N, and transmitting the coded bits to another communication device. The polar sequence Q^{N-1}₀={Q₀, Q₁, . . . , Q^{N-1}} of length N is defined in ascending order of reliability W(Q^{N}₀)<W(Q^{N}ᵢ)< . . . <W(Q^{N}_{N-1}), where 0<=Q^{N}ᵢ<=N−1 is a bit index for i=0, 1, . . . , N−1 and W(Q^{N}ᵢ) is the reliability of bit index Q^{N}ᵢ. Determining the input u_n includes determining K input indices at which K bits of the information block are to be located and input indices to be frozen from among input indices 0 to N−1 of the polar code of length N, based on the polar sequence Q^{N-1}₀={Q₀, Q₁, . . . , Q_{N-1}} of length N. Bit indices of the polar sequence Q^{N-1}₀={Q₀, Q₁, . . . , Q_{N-1}} of length N satisfy i) reliability increases as a number of 1s when expressed in binary increases, and ii) bit indices having the same number of is when expressed in binary are W(Q^{N}ₓ)<W(Q^{N}_{y}) for Q^{N}ₓ<Q^{N}_{y}.

In a further aspect of the present disclosure, a processing device in a wireless communication system is provided. The processing device includes at least one processor, and at least one computer memory operably connected to the at least one processor and storing instructions that, when executed, cause the at least one processor to perform operations. The operations include determining an input u_n to a polar code based on a length N of the polar code, a length K of an information block, and a polar sequence Q^{N-1}₀={Q₀, Q₁, . . . , Q_{N-1}} of length N, determining coded bits based on the input u_n being encoded based on the polar code of length N and the polar sequence Q^{N-1}₀={Q₀, Q₁, . . . , Q_{N-1}} of length N, and transmitting the coded bits to another communication device. The polar sequence Q^{N-1}₀={Q₀, Q₁, . . . , Q_{N-1}} of length N is defined in ascending order of reliability W(Q^{N}₀)<W(Q^{N}₁)< . . . <W(Q^{N}_{N-1}), where 0<=Q^{N}ᵢ<=N−1 is a bit index for i=0, 1, . . . , N−1 and W(Q^{N}ᵢ) is the reliability of bit index Q^{N}ᵢ. Determining the input u_n includes determining K input indices at which K bits of the information block are to be located and input indices to be frozen from among input indices 0 to N−1 of the polar code of length N, based on the polar sequence Q^{N-1}₀={Q₀, Q₁, . . . , Q_{N-1}} of length N. Bit indices of the polar sequence Q^{N-1}₀={Q₀, Q₁, . . . , Q_{N-1}} of length N satisfy i) reliability increases as a number of is when expressed in binary increases, and ii) bit indices having the same number of is when expressed in binary are W(Q^{N}ₓ)<W(Q^{N}_{y}) for Q^{N}ₓ<Q^{N}_{y}.

In a still further aspect of the present disclosure, a computer-readable storage medium is provided. The computer-readable storage medium stores at least one computer program including instructions that, when executed by at least one processor, cause the at least one processor to perform operations for a user equipment (UE). The operations include determining an input u_n to a polar code based on a length N of the polar code, a length K of an information block, and a polar sequence Q^{N-1}₀={Q₀, Q₁, . . . , Q_{N-1}} of length N, determining coded bits based on the input u_n being encoded based on the polar code of length N and the polar sequence Q^{N-1}₀={Q₀, Q₁, . . . , Q_{N-1}} of length N, and transmitting the coded bits to another communication device. The polar sequence Q^{N-1}₀={Q₀, Q₁, . . . , Q_{N-1}} of length N is defined in ascending order of reliability W(Q^{N}₀)<W(Q^{N}₁)< . . . <W(Q^{N}_{N-1}), where 0<=Q^{N}<=N−1 is a bit index for i=0, 1, . . . , N−1 and W(Q^{N}ᵢ) is the reliability of bit index Q^{N}ᵢ. Determining the input u_n includes determining K input indices at which K bits of the information block are to be located and input indices to be frozen from among input indices 0 to N−1 of the polar code of length N, based on the polar sequence Q^{N-1}₀={Q₀, Q₁, . . . , Q_{N-1}} of length N. Bit indices of the polar sequence Q^{N-1}₀={Q₀, Q₁, . . . , Q_{N-1}} of length N satisfy i) reliability increases as a number of 1s when expressed in binary increases, and ii) bit indices having the same number of is when expressed in binary are W(Q^{N}ₓ)<W(Q^{N}_{y}) for Q^{N}ₓ<Q^{N}_{y}.

In each aspect of the present disclosure, determining the input u_n may include determining an input v_n for convolution based on the length N of the polar code, a length K of the information block, and the polar sequence Q^{N-1}₀={Q₀, Q₁, . . . , Q_{N-1}} with a length N, and determining the input u_n based on performing the convolution on the input v_n.

In each aspect of the present disclosure, performing the convolution may include determining a number of shift registers based on the length N of the polar code from among predetermined numbers of shift registers for mother code sizes, and performing a convolution on the input v_n based on the determined number of shift registers.

In each aspect of the present disclosure, the predetermined numbers of shift registers may be greater than or equal to the respective maximum numbers of consecutive frozen bits for the mother code sizes.

In each aspect of the present disclosure, performing the convolution may include determining the input u_n based on

$${u}_{n} = {v}_{n} + {\sum }_{k = 1}^{m} {c}_{k} {u}_{n - k} .$$

In each aspect of the present disclosure, the same number of shift registers may be used for different mother code sizes.

The foregoing solutions are merely a part of the examples of the present disclosure and various examples into which the technical features of the present disclosure are incorporated may be derived and understood by persons skilled in the art from the following detailed description.

According to some implementation(s) of the present disclosure, a wireless communication signal may be efficiently transmitted/received. Accordingly, the total throughput of a wireless communication system may be raised.

According to some implementation(s) of the present disclosure, various services with different requirements may be efficiently supported in a wireless communication system.

According to some implementation(s) of the present disclosure, delay/latency generated during radio communication between communication devices may be reduced.

According to some implementation(s) of the present disclosure, the performance of channel coding based on polar codes may be improved by maximizing the minimum distance between codewords.

According to some implementations of the present disclosure, various information sizes may be supported in PAC codes while maximizing the minimum distance between codewords.

The effects according to the present disclosure are not limited to what has been particularly described hereinabove and other effects not described herein will be more clearly understood by persons skilled in the art related to the present disclosure from the following detailed description.

### BRIEF DESCRIPTION OF THE DRAWINGS

The accompanying drawings, which are included to provide a further understanding of the present disclosure, illustrate examples of implementations of the present disclosure and together with the detailed description serve to explain implementations of the present disclosure:

FIG. 1 illustrates an example of a communication system 1 to which implementations of the present disclosure are applied;

FIG. 2 is a block diagram illustrating examples of communication devices capable of performing a method according to the present disclosure;

FIG. 3 illustrates another example of a wireless device capable of performing implementation(s) of the present disclosure;

FIG. 4 illustrates an example of a frame structure used in a 3rd generation partnership project (3GPP)-based wireless communication system;

FIG. 5 illustrates a process for processing a transport block (TB) on a transmitting side;

FIG. 6 is an exemplary block diagram for a polar encoder;

FIG. 7 illustrates the concept of channel splitting and channel combining for channel polarization;

FIG. 8 illustrates N-th level channel combining for polar codes;

FIG. 9 illustrates evolution of decoding paths in a list-L decoding process;

FIG. 10 is a diagram to explain the concept of selecting position(s) to which information bit(s) are to be allocated in polar codes;

FIG. 11 illustrates puncturing and information bit allocation for polar codes;

FIG. 12 illustrates a method of generating parity check bit(s) used in polar codes;

FIG. 13 is a diagram to explain a rate matching process according to some implementations of the present disclosure;

FIG. 14 illustrates one structure of encoders/decoders for PAC codes available for some implementations of the present disclosure;

FIG. 15 illustrates a codeword tree to explain a concept of sequential decoding;

FIGS. 16 and 17 illustrate the results of a rate profile operation for a mother code size;

FIGS. 18 and 19 illustrate a recursive convolution operation;

FIG. 20 illustrates a channel encoding procedure according to some implementations of the present disclosure; and

FIG. 21 illustrates a channel decoding procedure according to some implementations of the present disclosure.

### DETAILED DESCRIPTION

Hereinafter, implementations according to the present disclosure will be described in detail with reference to the accompanying drawings. The detailed description, which will be given below with reference to the accompanying drawings, is intended to explain exemplary implementations of the present disclosure, rather than to show the only implementations that may be implemented according to the present disclosure. The following detailed description includes specific details in order to provide a thorough understanding of the present disclosure. However, it will be apparent to those skilled in the art that the present disclosure may be practiced without such specific details.

In some instances, known structures and devices may be omitted or may be shown in block diagram form, focusing on important features of the structures and devices, so as not to obscure the concept of the present disclosure. The same reference numbers will be used throughout the present disclosure to refer to the same or like parts.

A technique, a device, and a system described below may be applied to a variety of wireless multiple access systems. The multiple access systems may include, for example, a code division multiple access (CDMA) system, a frequency division multiple access (FDMA) system, a time division multiple access (TDMA) system, an orthogonal frequency division multiple access (OFDMA) system, a single-carrier frequency division multiple access (SC-FDMA) system, a multi-carrier frequency division multiple access (MC-FDMA) system, etc. CDMA may be implemented by radio technology such as universal terrestrial radio access (UTRA) or CDMA2000. TDMA may be implemented by radio technology such as global system for mobile communications (GSM), general packet radio service (GPRS), enhanced data rates for GSM evolution (EDGE) (i.e., GERAN), etc. OFDMA may be implemented by radio technology such as institute of electrical and electronics engineers (IEEE) 802.11 (Wi-Fi), IEEE 802.16 (WiMAX), IEEE 802.20, evolved-UTRA (E-UTRA), etc. UTRA is part of universal mobile telecommunications system (UMTS) and 3rd generation partnership project (3GPP) long-term evolution (LTE) is part of E-UMTS using E-UTRA. 3GPP LTE adopts OFDMA on downlink (DL) and adopts SC-FDMA on uplink (UL). LTE-advanced (LTE-A) is an evolved version of 3GPP LTE.

For convenience of description, description will be given under the assumption that the present disclosure is applied to LTE and/or new RAT (NR). However, the technical features of the present disclosure are not limited thereto. For example, although the following detailed description is given based on mobile communication systems corresponding to 3GPP LTE/NR systems, the mobile communication systems are applicable to other arbitrary mobile communication systems except for matters that are specific to the 3GPP LTE/NR system.

For terms and techniques that are not described in detail among terms and techniques used in the present disclosure, reference may be made to 3GPP based standard specifications, for example, 3GPP TS 36.211, 3GPP TS 36.212, 3GPP TS 36.213, 3GPP TS 36.321, 3GPP TS 36.300, 3GPP TS 36.331, 3GPP TS 37.213, 3GPP TS 38.211, 3GPP TS 38.212, 3GPP TS 38.213, 3GPP TS 38.214, 3GPP TS 38.300, 3GPP TS 38.331, etc.

In examples of the present disclosure described later, if a device “assumes” something, this may mean that a channel transmission entity transmits a channel in compliance with the corresponding “assumption.” This also may mean that a channel reception entity receives or decodes the channel in the form of conforming to the “assumption” on the premise that the channel has been transmitted in compliance with the “assumption.”

In the present disclosure, a user equipment (UE) may be fixed or mobile. Each of various devices that transmit and/or receive user data and/or control information by communicating with a base station (BS) may be the UE. The term UE may be referred to as terminal equipment, mobile station (MS), mobile terminal (MT), user terminal (UT), subscriber station (SS), wireless device, personal digital assistant (PDA), wireless modem, handheld device, etc. In the present disclosure, a BS refers to a fixed station that communicates with a UE and/or another BS and exchanges data and control information with a UE and another BS. The term BS may be referred to as advanced base station (ABS), Node-B (NB), evolved Node-B (eNB), base transceiver system (BTS), access point (AP), processing server (PS), etc. Particularly, a BS of a universal terrestrial radio access (UTRAN) is referred to as an NB, a BS of an evolved-UTRAN (E-UTRAN) is referred to as an eNB, and a BS of new radio access technology network is referred to as a gNB. Hereinbelow, for convenience of description, the NB, eNB, or gNB will be referred to as a BS regardless of the type or version of communication technology.

In the present disclosure, a node refers to a fixed point capable of transmitting/receiving a radio signal to/from a UE by communication with the UE. Various types of BSs may be used as nodes regardless of the names thereof. For example, a BS, NB, eNB, pico-cell eNB (PeNB), home eNB (HeNB), relay, repeater, etc. may be a node. Furthermore, a node may not be a BS. For example, a radio remote head (RRH) or a radio remote unit (RRU) may be a node. Generally, the RRH and RRU have power levels lower than that of the BS. Since the RRH or RRU (hereinafter, RRH/RRU) is connected to the BS through a dedicated line such as an optical cable in general, cooperative communication according to the RRH/RRU and the BS may be smoothly performed relative to cooperative communication according to BSs connected through a wireless link. At least one antenna is installed per node. An antenna may refer to a physical antenna port or refer to a virtual antenna or an antenna group. The node may also be called a point.

In the present disclosure, a cell refers to a specific geographical area in which one or more nodes provide communication services. Accordingly, in the present disclosure, communication with a specific cell may mean communication with a BS or a node providing communication services to the specific cell. A DL/UL signal of the specific cell refers to a DL/UL signal from/to the BS or the node providing communication services to the specific cell. A cell providing UL/DL communication services to a UE is especially called a serving cell. Furthermore, channel status/quality of the specific cell refers to channel status/quality of a channel or a communication link generated between the BS or the node providing communication services to the specific cell and the UE. In 3GPP-based communication systems, the UE may measure a DL channel state from a specific node using cell-specific reference signal(s) (CRS(s)) transmitted on a CRS resource and/or channel state information reference signal(s) (CSI-RS(s)) transmitted on a CSI-RS resource, allocated to the specific node by antenna port(s) of the specific node.

A 3GPP-based communication system uses the concept of a cell in order to manage radio resources, and a cell related with the radio resources is distinguished from a cell of a geographic area.

The “cell” of the geographic area may be understood as coverage within which a node may provide services using a carrier, and the “cell” of the radio resources is associated with bandwidth (BW), which is a frequency range configured by the carrier. Since DL coverage, which is a range within which the node is capable of transmitting a valid signal, and UL coverage, which is a range within which the node is capable of receiving the valid signal from the UE, depend upon a carrier carrying the signal, coverage of the node may also be associated with coverage of the “cell” of radio resources used by the node. Accordingly, the term “cell” may be used to indicate service coverage by the node sometimes, radio resources at other times, or a range that a signal using the radio resources may reach with valid strength at other times.

In 3GPP communication standards, the concept of the cell is used in order to manage radio resources. The “cell” associated with the radio resources is defined by a combination of DL resources and UL resources, that is, a combination of a DL component carrier (CC) and a UL CC. The cell may be configured by the DL resources only or by the combination of the DL resources and the UL resources. If carrier aggregation is supported, linkage between a carrier frequency of the DL resources (or DL CC) and a carrier frequency of the UL resources (or UL CC) may be indicated by system information. For example, the combination of the DL resources and the UL resources may be indicated by system information block type 2 (SIB2) linkage. In this case, the carrier frequency may be equal to or different from a center frequency of each cell or CC. When carrier aggregation (CA) is configured, the UE has only one radio resource control (RRC) connection with a network. During RRC connection establishment/re-establishment/handover, one serving cell provides non-access stratum (NAS) mobility information. During RRC connection re-establishment/handover, one serving cell provides security input. This cell is referred to as a primary cell (Pcell). The Pcell refers to a cell operating on a primary frequency on which the UE performs an initial connection establishment procedure or initiates a connection re-establishment procedure. According to UE capability, secondary cells (Scells) may be configured to form a set of serving cells together with the Pcell. The Scell may be configured after completion of RRC connection establishment and used to provide additional radio resources in addition to resources of a specific cell (SpCell). A carrier corresponding to the Pcell on DL is referred to as a downlink primary CC (DL PCC), and a carrier corresponding to the Pcell on UL is referred to as an uplink primary CC (UL PCC). A carrier corresponding to the Scell on DL is referred to as a downlink secondary CC (DL SCC), and a carrier corresponding to the Scell on UL is referred to as an uplink secondary CC (UL SCC).

In a dual connectivity (DC) operation, the term special cell (SpCell) refers to a Pcell of a master cell group (MCG) or a primary secondary cell (PSCell) of a secondary cell group (SCG). The SpCell supports PUCCH transmission and contention-based random access and is always activated. The MCG is a group of service cells associated with a master node (e.g., BS) and includes the SpCell (Pcell) and optionally one or more Scells. For a UE configured with DC, the SCG is a subset of serving cells associated with a secondary node and includes the PSCell and 0 or more Scells. The PSCell is a primary Scell of the SCG. For a UE in RRC_CONNECTED state, that is not configured with CA or DC, only one serving cell including only the Pcell is present. For a UE in RRC_CONNECTED state, that is configured with CA or DC, the term serving cells refers to a set of cells including SpCell(s) and all Scell(s). In DC, two medium access control (MAC) entities, i.e., one MAC entity for the MCG and one MAC entity for the SCG, are configured for the UE.

For a UE that is configured with CA and is not configured with DC, a Pcell PUCCH group including the Pcell and 0 or more Scells and an Scell PUCCH group including only Scell(s) may be configured. For the Scell, an Scell on which a PUCCH associated with the corresponding cell is transmitted (hereinafter, a PUCCH cell) may be configured. An Scell for which a PUCCH Scell is indicated belongs to the Scell PUCCH group and PUCCH transmission of related uplink control information (UCI) is performed on the PUCCH Scell. If a PUCCH Scell is not indicated for an Scell or a cell which is indicated for PUCCH transmission for the Scell is a Pcell, the Scell belongs to the Pcell PUCCH group and PUCCH transmission of related UCI is performed on the Pcell.

In a wireless communication system, the UE receives information on DL from the BS and the UE transmits information on UL to the BS. The information that the BS and UE transmit and/or receive includes data and a variety of control information and there are various physical channels according to types/usage of the information that the UE and the BS transmit and/or receive.

The 3GPP-based communication standards define DL physical channels corresponding to resource elements carrying information originating from a higher layer and DL physical signals corresponding to resource elements which are used by the physical layer but do not carry the information originating from the higher layer. For example, a physical downlink shared channel (PDSCH), a physical broadcast channel (PBCH), a physical multicast channel (PMCH), a physical control format indicator channel (PCFICH), a physical downlink control channel (PDCCH), etc. are defined as the DL physical channels, and a reference signal (RS) and a synchronization signal (SS) are defined as the DL physical signals. The RS, which is also referred to as a pilot, represents a signal with a predefined special waveform known to both the BS and the UE. For example, a demodulation reference signal (DMRS), a channel state information RS (CSI-RS), etc. are defined as DL RSs. The 3GPP-based communication standards define UL physical channels corresponding to resource elements carrying information originating from the higher layer and UL physical signals corresponding to resource elements which are used by the physical layer but do not carry the information originating from the higher layer. For example, a physical uplink shared channel (PUSCH), a physical uplink control channel (PUCCH), and a physical random access channel (PRACH) are defined as the UL physical channels, and a DMRS for a UL control/data signal, a sounding reference signal (SRS) used for UL channel measurement, etc. are defined.

In the present disclosure, a PDCCH refers to a set of time-frequency resources (e.g., resource elements (REs)) carrying downlink control information (DCI), and a PDSCH refers to a set of time-frequency resources carrying DL data. A PUCCH, a PUSCH, and a PRACH refer to a set of time-frequency resources carrying UCI, a set of time-frequency resources carrying UL data, and a set of time-frequency resources carrying random access signals, respectively. In the following description, “the UE transmits/receives a PUCCH/PUSCH/PRACH” is used as the same meaning that the UE transmits/receives the UCI/UL data/random access signals on or through the PUCCH/PUSCH/PRACH, respectively. In addition, “the BS transmits/receives a PBCH/PDCCH/PDSCH” is used as the same meaning that the BS transmits the broadcast information/DCI/DL data on or through a PBCH/PDCCH/PDSCH, respectively.

In the present disclosure, a radio resource (e.g., a time-frequency resource) scheduled or configured to the UE by the BS for transmission or reception of the PUCCH/PUSCH/PDSCH may be referred to as a PUCCH/PUSCH/PDSCH resource.

Since a communication device receives a synchronization signal block (SSB), DMRS, CSI-RS, PBCH, PDCCH, PDSCH, PUSCH, and/or PUCCH in the form of radio signals on a cell, the communication device may not select and receive radio signals including only a specific physical channel or a specific physical signal through a radio frequency (RF) receiver, or may not select and receive radio signals without a specific physical channel or a specific physical signal through the RF receiver. In actual operations, the communication device receives radio signals on the cell via the RF receiver, converts the radio signals, which are RF band signals, into baseband signals, and then decodes physical signals and/or physical channels in the baseband signals using one or more processors. Thus, in some implementations of the present disclosure, reception of physical signals and/or physical channels may mean that a communication device does not attempt to restore the physical signals and/or physical channels from radio signals, for example, does not attempt to decode the physical signals and/or physical channels, rather than that the communication device does not actually receive the radio signals including the corresponding physical signals and/or physical channels.

As more and more communication devices have required greater communication capacity, there has been a need for eMBB communication relative to legacy radio access technology (RAT). In addition, massive MTC for providing various services at anytime and anywhere by connecting a plurality of devices and objects to each other is one main issue to be considered in next-generation communication. Further, communication system design considering services/UEs sensitive to reliability and latency is also under discussion. The introduction of next-generation RAT is being discussed in consideration of eMBB communication, massive MTC, ultra-reliable and low-latency communication (URLLC), and the like. Currently, in 3GPP, a study on the next-generation mobile communication systems after EPC is being conducted. In the present disclosure, for convenience, the corresponding technology is referred to as a new RAT (NR) or fifth-generation (5G) RAT, and a system using NR or supporting NR is referred to as an NR system.

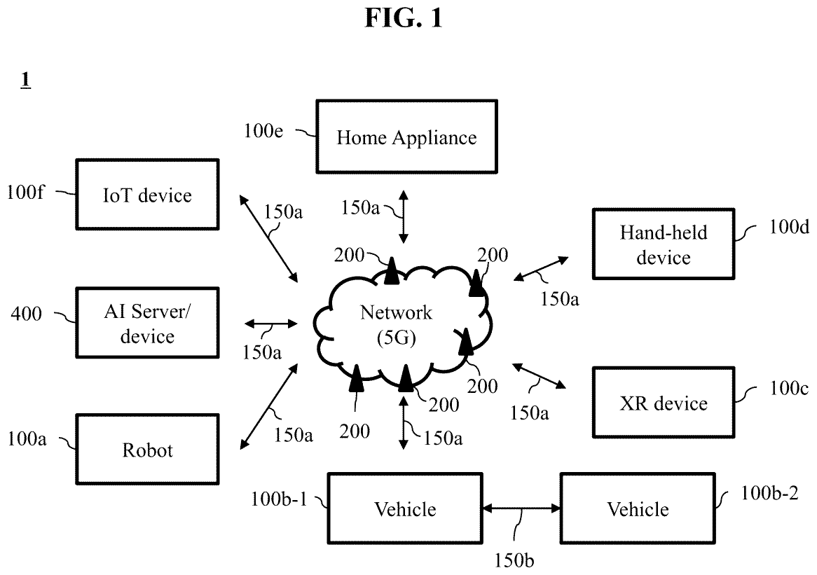

FIG. 1 illustrates an example of a communication system 1 to which implementations of the present disclosure are applied. Referring to FIG. 1, the communication system 1 applied to the present disclosure includes wireless devices, BSs, and a network. Here, the wireless devices represent devices performing communication using RAT (e.g., 5G NR or LTE (e.g., E-UTRA)) and may be referred to as communication/radio/5G devices. The wireless devices may include, without being limited to, a robot 100a, vehicles 100b-1 and 100b-2, an extended reality (XR) device 100c, a hand-held device 100d, a home appliance 100e, an Internet of Things (IoT) device 100f, and an artificial intelligence (AI) device/server 400. For example, the vehicles may include a vehicle having a wireless communication function, an autonomous driving vehicle, and a vehicle capable of performing vehicle-to-vehicle communication. Here, the vehicles may include an unmanned aerial vehicle (UAV) (e.g., a drone). The XR device may include an augmented reality (AR)/virtual reality (VR)/mixed reality (MR) device and may be implemented in the form of a head-mounted device (HMD), a head-up display (HUD) mounted in a vehicle, a television, a smartphone, a computer, a wearable device, a home appliance device, a digital signage, a vehicle, a robot, etc. The hand-held device may include a smartphone, a smartpad, a wearable device (e.g., a smartwatch or smartglasses), and a computer (e.g., a notebook). The home appliance may include a TV, a refrigerator, and a washing machine. The IoT device may include a sensor and a smartmeter. For example, the BSs and the network may also be implemented as wireless devices and a specific wireless device may operate as a BS/network node with respect to another wireless device.

The wireless devices 100a to 100f may be connected to a network 300 via BSs 200. AI technology may be applied to the wireless devices 100a to 100f and the wireless devices 100a to 100f may be connected to the AI server 400 via the network 300. The network 300 may be configured using a 3G network, a 4G (e.g., LTE) network, or a 5G (e.g., NR) network. Although the wireless devices 100a to 100f may communicate with each other through the BSs 200/network 300, the wireless devices 100a to 100f may perform direct communication (e.g., sidelink communication) with each other without passing through the BSs/network. For example, the vehicles 100b-1 and 100b-2 may perform direct communication (e.g., vehicle-to-vehicle (V2V)/Vehicle-to-everything (V2X) communication). The IoT device (e.g., a sensor) may perform direct communication with other IoT devices (e.g., sensors) or other wireless devices 100a to 100f.

Wireless communication/connections 150a and 150b may be established between the wireless devices 100a to 100f and the BSs 200 and between the wireless devices 100a to 100f). Here, the wireless communication/connections such as UL/DL communication 150a and sidelink communication 150b (or, device-to-device (D2D) communication) may be established by various RATs (e.g., 5GNNR). The wireless devices and the BSs/wireless devices may transmit/receive radio signals to/from each other through the wireless communication/connections 150a and 150b. To this end, at least a part of various configuration information configuring processes, various signal processing processes (e.g., channel encoding/decoding, modulation/demodulation, and resource mapping/demapping), and resource allocating processes, for transmitting/receiving radio signals, may be performed based on the various proposals of the present disclosure.

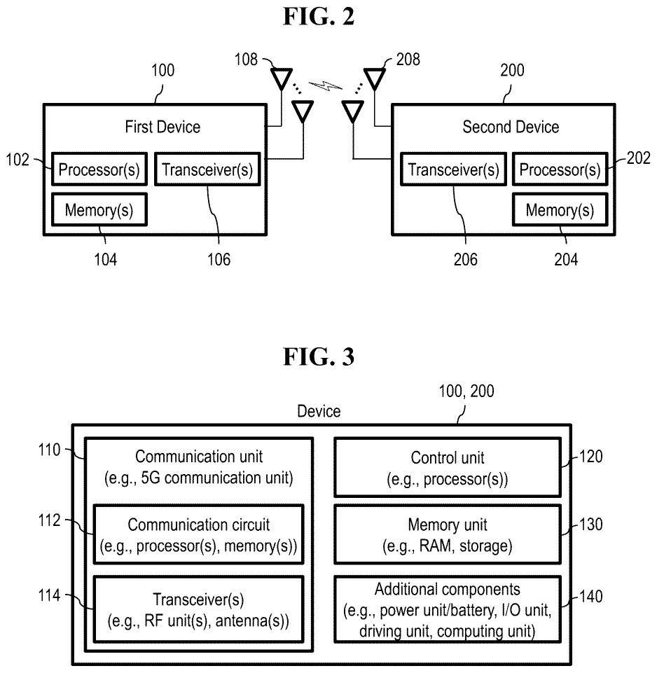

FIG. 2 is a block diagram illustrating examples of communication devices capable of performing a method according to the present disclosure. Referring to FIG. 2, a first wireless device 100 and a second wireless device 200 may transmit and/or receive radio signals through a variety of RATs (e.g., LTE and NR). Here, {the first wireless device 100 and the second wireless device 200} may correspond to {the wireless device 100x and the BS 200} and/or {the wireless device 100x and the wireless device 100x} of FIG. 1.

The first wireless device 100 may include one or more processors 102 and one or more memories 104 and additionally further include one or more transceivers 106 and/or one or more antennas 108. The processor(s) 102 may control the memory(s) 104 and/or the transceiver(s) 106 and may be configured to implement the below-described/proposed functions, procedures, and/or methods. For example, the processor(s) 102 may process information within the memory(s) 104 to generate first information/signals and then transmit radio signals including the first information/signals through the transceiver(s) 106. The processor(s) 102 may receive radio signals including second information/signals through the transceiver(s) 106 and then store information obtained by processing the second information/signals in the memory(s) 104. The memory(s) 104 may be connected to the processor(s) 102 and may store a variety of information related to operations of the processor(s) 102. For example, the memory(s) 104 may perform a part or all of processes controlled by the processor(s) 102 or store software code including instructions for performing the below-described/proposed procedures and/or methods. Here, the processor(s) 102 and the memory(s) 104 may be a part of a communication modem/circuit/chip designed to implement RAT (e.g., LTE or NR). The transceiver(s) 106 may be connected to the processor(s) 102 and transmit and/or receive radio signals through one or more antennas 108. Each of the transceiver(s) 106 may include a transmitter and/or a receiver. The transceiver(s) 106 is used interchangeably with radio frequency (RF) unit(s). In the present disclosure, the wireless device may represent the communication modem/circuit/chip.

The second wireless device 200 may include one or more processors 202 and one or more memories 204 and additionally further include one or more transceivers 206 and/or one or more antennas 208. The processor(s) 202 may control the memory(s) 204 and/or the transceiver(s) 206 and may be configured to implement the below-described/proposed functions, procedures, and/or methods. For example, the processor(s) 202 may process information within the memory(s) 204 to generate third information/signals and then transmit radio signals including the third information/signals through the transceiver(s) 206. The processor(s) 202 may receive radio signals including fourth information/signals through the transceiver(s) 106 and then store information obtained by processing the fourth information/signals in the memory(s) 204. The memory(s) 204 may be connected to the processor(s) 202 and may store a variety of information related to operations of the processor(s) 202. For example, the memory(s) 204 may perform a part or all of processes controlled by the processor(s) 202 or store software code including instructions for performing the below-described/proposed procedures and/or methods. Here, the processor(s) 202 and the memory(s) 204 may be a part of a communication modem/circuit/chip designed to implement RAT (e.g., LTE or NR). The transceiver(s) 206 may be connected to the processor(s) 202 and transmit and/or receive radio signals through one or more antennas 208. Each of the transceiver(s) 206 may include a transmitter and/or a receiver. The transceiver(s) 206 is used interchangeably with RF unit(s). In the present disclosure, the wireless device may represent the communication modem/circuit/chip.

The wireless communication technology implemented in the wireless devices 100 and 200 of the present disclosure may include narrowband Internet of things for low-power communication as well as LTE, NR, and 6G. For example, the NB-IoT technology may be an example of low-power wide-area network (LPWAN) technologies and implemented in standards such as LTE Cat NB1 and/or LTE Cat NB2. However, the NB-IoT technology is not limited to the above names. Additionally or alternatively, the wireless communication technology implemented in the wireless devices XXX and YYY of the present disclosure may perform communication based on the LTE-M technology. For example, the LTE-M technology may be an example of LPWAN technologies and called by various names including enhanced machine type communication (eMTC). For example, the LTE-M technology may be implemented in at least one of the following various standards: 1) LTE CAT 0, 2) LTE Cat M1, 3) LTE Cat M2, 4) LTE non-Bandwidth Limited (non-BL), 5) LTE-MTC, 6) LTE Machine Type Communication, and/or 7) LTE M, etc., but the LTE-M technology is not limited to the above names. Additionally or alternatively, the wireless communication technology implemented in the wireless devices XXX and YYY of the present disclosure may include at least one of ZigBee, Bluetooth, and LPWAN in consideration of low-power communication, but the wireless communication technology is not limited to the above names. For example, the ZigBee technology may create a personal area network (PAN) related to small/low-power digital communication based on various standards such as IEEE 802.15.4 and so on, and the ZigBee technology may be called by various names.

Hereinafter, hardware elements of the wireless devices 100 and 200 will be described more specifically. One or more protocol layers may be implemented by, without being limited to, one or more processors 102 and 202. For example, the one or more processors 102 and 202 may implement one or more layers (e.g., functional layers such as a physical (PHY) layer, medium access control (MAC) layer, a radio link control (RLC) layer, a packet data convergence protocol (PDCP) layer, radio resource control (RRC) layer, and a service data adaptation protocol (SDAP) layer). The one or more processors 102 and 202 may generate one or more protocol data units (PDUs) and/or one or more service data units (SDUs) according to the functions, procedures, proposals, and/or methods disclosed in the present disclosure. The one or more processors 102 and 202 may generate messages, control information, data, or information according to the functions, procedures, proposals, and/or methods disclosed in the present disclosure. The one or more processors 102 and 202 may generate signals (e.g., baseband signals) including PDUs, SDUs, messages, control information, data, or information according to the functions, procedures, proposals, and/or methods disclosed in the present disclosure and provide the generated signals to the one or more transceivers 106 and 206. The one or more processors 102 and 202 may receive the signals (e.g., baseband signals) from the one or more transceivers 106 and 206 and acquire the PDUs, SDUs, messages, control information, data, or information according to the functions, procedures, proposals, and/or methods disclosed in the present disclosure.

The one or more processors 102 and 202 may be referred to as controllers, microcontrollers, microprocessors, or microcomputers. The one or more processors 102 and 202 may be implemented by hardware, firmware, software, or a combination thereof. As an example, one or more application specific integrated circuits (ASICs), one or more digital signal processors (DSPs), one or more digital signal processing devices (DSPDs), one or more programmable logic devices (PLDs), or one or more field programmable gate arrays (FPGAs) may be included in the one or more processors 102 and 202. The functions, procedures, proposals, and/or methods disclosed in the present disclosure may be implemented using firmware or software, and the firmware or software may be configured to include the modules, procedures, or functions. Firmware or software configured to perform the functions, procedures, proposals, and/or methods disclosed in the present disclosure may be included in the one or more processors 102 and 202 or stored in the one or more memories 104 and 204 so as to be driven by the one or more processors 102 and 202. The functions, procedures, proposals, and/or methods disclosed in the present disclosure may be implemented using firmware or software in the form of code, commands, and/or a set of commands.

The one or more memories 104 and 204 may be connected to the one or more processors 102 and 202 and store various types of data, signals, messages, information, programs, code, commands, and/or instructions. The one or more memories 104 and 204 may be configured by read-only memories (ROMs), random access memories (RAMs), electrically erasable programmable read-only memories (EPROMs), flash memories, hard drives, registers, cash memories, computer-readable storage media, and/or combinations thereof. The one or more memories 104 and 204 may be located at the interior and/or exterior of the one or more processors 102 and 202. The one or more memories 104 and 204 may be connected to the one or more processors 102 and 202 through various technologies such as wired or wireless connection.

The one or more transceivers 106 and 206 may transmit user data, control information, and/or radio signals/channels, mentioned in the methods and/or operational flowcharts of the present disclosure, to one or more other devices. The one or more transceivers 106 and 206 may receive user data, control information, and/or radio signals/channels, mentioned in the functions, procedures, proposals, methods, and/or operational flowcharts disclosed in the present disclosure, from one or more other devices. For example, the one or more transceivers 106 and 206 may be connected to the one or more processors 102 and 202 and transmit and receive radio signals. For example, the one or more processors 102 and 202 may perform control so that the one or more transceivers 106 and 206 may transmit user data, control information, or radio signals to one or more other devices. The one or more processors 102 and 202 may perform control so that the one or more transceivers 106 and 206 may receive user data, control information, or radio signals from one or more other devices. The one or more transceivers 106 and 206 may be connected to the one or more antennas 108 and 208. The one or more transceivers 106 and 206 may be configured to transmit and receive user data, control information, and/or radio signals/channels, mentioned in the functions, procedures, proposals, methods, and/or operational flowcharts disclosed in the present disclosure, through the one or more antennas 108 and 208. In the present disclosure, the one or more antennas may be a plurality of physical antennas or a plurality of logical antennas (e.g., antenna ports). The one or more transceivers 106 and 206 may convert received radio signals/channels etc. from RF band signals into baseband signals in order to process received user data, control information, radio signals/channels, etc. using the one or more processors 102 and 202. The one or more transceivers 106 and 206 may convert the user data, control information, radio signals/channels, etc. processed using the one or more processors 102 and 202 from the base band signals into the RF band signals. To this end, the one or more transceivers 106 and 206 may include (analog) oscillators and/or filters.

FIG. 3 illustrates another example of a wireless device capable of performing implementation(s) of the present disclosure. Referring to FIG. 3, wireless devices 100 and 200 may correspond to the wireless devices 100 and 200 of FIG. 2 and may be configured by various elements, components, units/portions, and/or modules. For example, each of the wireless devices 100 and 200 may include a communication unit 110, a control unit 120, a memory unit 130, and additional components 140. The communication unit may include a communication circuit 112 and transceiver(s) 114. For example, the communication circuit 112 may include the one or more processors 102 and 202 and/or the one or more memories 104 and 204 of FIG. 2. For example, the transceiver(s) 114 may include the one or more transceivers 106 and 206 and/or the one or more antennas 108 and 208 of FIG. 2. The control unit 120 is electrically connected to the communication unit 110, the memory 130, and the additional components 140 and controls overall operation of the wireless devices. For example, the control unit 120 may control an electric/mechanical operation of the wireless device based on programs/code/commands/information stored in the memory unit 130. The control unit 120 may transmit the information stored in the memory unit 130 to the exterior (e.g., other communication devices) via the communication unit 110 through a wireless/wired interface or store, in the memory unit 130, information received through the wireless/wired interface from the exterior (e.g., other communication devices) via the communication unit 110.

The additional components 140 may be variously configured according to types of wireless devices. For example, the additional components 140 may include at least one of a power unit/battery, input/output (I/O) unit, a driving unit, and a computing unit. The wireless device may be implemented in the form of, without being limited to, the robot (100a of FIG. 1), the vehicles (100b-1 and 100b-2 of FIG. 1), the XR device (100c of FIG. 1), the hand-held device (100d of FIG. 1), the home appliance (100e of FIG. 1), the IoT device (100f of FIG. 1), a digital broadcast UE, a hologram device, a public safety device, an MTC device, a medicine device, a fintech device (or a finance device), a security device, a climate/environment device, the AI server/device (400 of FIG. 1), the BS (200 of FIG. 1), a network node, etc. The wireless device may be used in a mobile or fixed place according to a use-case/service.

In FIG. 3, the entirety of the various elements, components, units/portions, and/or modules in the wireless devices 100 and 200 may be connected to each other through a wired interface or at least a part thereof may be wirelessly connected through the communication unit 110. For example, in each of the wireless devices 100 and 200, the control unit 120 and the communication unit 110 may be connected by wire and the control unit 120 and first units (e.g., 130 and 140) may be wirelessly connected through the communication unit 110. Each element, component, unit/portion, and/or module within the wireless devices 100 and 200 may further include one or more elements. For example, the control unit 120 may be configured by a set of one or more processors. As an example, the control unit 120 may be configured by a set of a communication control processor, an application processor, an electronic control unit (ECU), a graphical processing unit, and a memory control processor. As another example, the memory 130 may be configured by a random access memory (RAM), a dynamic RAM (DRAM), a read-only memory (ROM)), a flash memory, a transitory memory, a non-transitory memory, and/or a combination thereof.

In the present disclosure, the at least one memory (e.g., 104 or 204) may store instructions or programs, and the instructions or programs may cause, when executed, at least one processor operably connected to the at least one memory to perform operations according to some embodiments or implementations of the present disclosure.

In the present disclosure, a computer readable (non-transitory) storage medium may store at least one instruction or program, and the at least one instruction or program may cause, when executed by at least one processor, the at least one processor to perform operations according to some embodiments or implementations of the present disclosure.

In the present disclosure, a processing device or apparatus may include at least one processor, and at least one computer memory operably connected to the at least one processor. The at least one computer memory may store instructions or programs, and the instructions or programs may cause, when executed, the at least one processor operably connected to the at least one memory to perform operations according to some embodiments or implementations of the present disclosure.

In the present disclosure, a computer program may include program code stored on at least one computer-readable (non-transitory) storage medium and, when executed, configured to perform operations according to some implementations of the present disclosure or cause at least one processor to perform the operations according to some implementations of the present disclosure. The computer program may be provided in the form of a computer program product. The computer program product may include at least one computer-readable (non-transitory) storage medium.

A communication device of the present disclosure includes at least one processor; and at least one computer memory operably connected to the at least one processor and configured to store instructions for causing, when executed, the at least one processor to perform operations according to example(s) of the present disclosure described later.

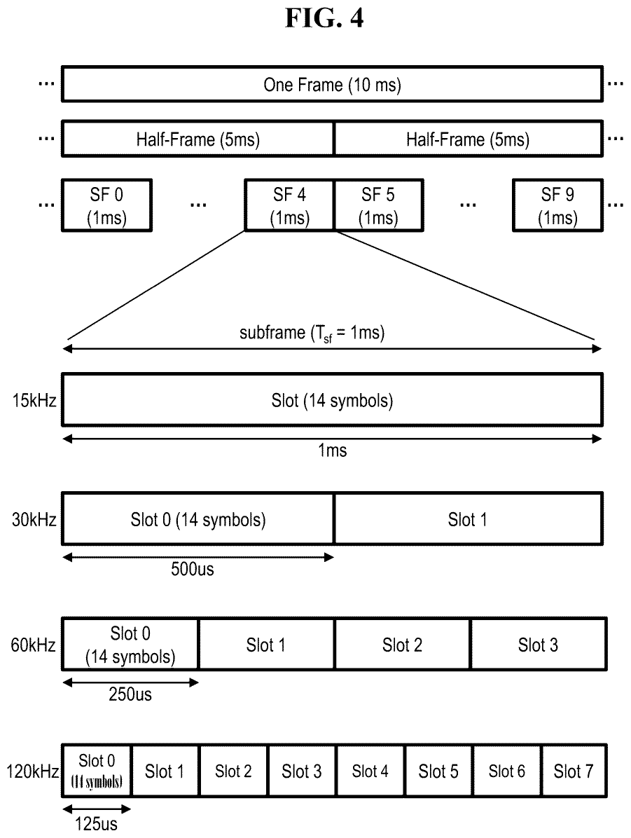

FIG. 4 illustrates an example of a frame structure used in a 3GPP-based wireless communication system.

The frame structure of FIG. 4 is purely exemplary and the number of subframes, the number of slots, and the number of symbols, in a frame, may be variously changed. In an NR system, different OFDM numerologies (e.g., subcarrier spacings (SCSs)) may be configured for multiple cells which are aggregated for one UE. Accordingly, the (absolute time) duration of a time resource including the same number of symbols (e.g., a subframe, a slot, or a transmission time interval (TTI)) may be differently configured for the aggregated cells. Here, the symbol may include an OFDM symbol (or cyclic prefix—OFDM (CP-OFDM) symbol) and an SC-FDMA symbol (or discrete Fourier transform-spread-OFDM (DFT-s-OFDM) symbol). In the present disclosure, the symbol, the OFDM-based symbol, the OFDM symbol, the CP-OFDM symbol, and the DFT-s-OFDM symbol are used interchangeably.

Referring to FIG. 4, in the NR system, UL and DL transmissions are organized into frames. Each frame has a duration of T_{f}=(Δfₘₐₓ*N_{f}/100)*T_{c}=10 ms and is divided into two half-frames of 5 ms each. A basic time unit for NR is T_{c}=1/(Δfₘₐₓ*N_{f}) where Δfₘₐₓ=480*103 Hz and N_{f}=4096. For reference, a basic time unit for LTE is Tₛ=1/(Δf_{ref}*N_{f,ref}) where Δf_{ref}=15*103 Hz and N_{f,ref}=2048. T_{c} and T_{f} have the relationship of a constant κ=T_{c}/T_{f}=64. Each half-frame includes 5 subframes and a duration T_{sf} of a single subframe (SF) is 1 ms. Subframes are further divided into slots and the number of slots in a subframe depends on a subcarrier spacing. Each slot includes 14 or 12 OFDM symbols based on a cyclic prefix. In a normal CP, each slot includes 14 OFDM symbols and, in an extended CP, each slot includes 12 OFDM symbols. The numerology depends on an exponentially scalable subcarrier spacing Δf=2^{u}*15 kHz. The table below shows the number of OFDM symbols (N^{slot}_{symb}) per slot, the number of slots (N^{frame,u}ₛₗₒₜ) per frame, and the number of slots (N^{subframe,u}ₛₗₒₜ) per subframe.

TABLE 1

| u | N^{slot}_{symb} | N^{frame, u}ₛₗₒₜ | N^{subframe, u}ₛₗₒₜ |
|---|---|---|---|
| 0 | 14 | 10 | 1 |
| 1 | 14 | 20 | 2 |
| 2 | 14 | 40 | 4 |
| 3 | 14 | 80 | 8 |
| 4 | 14 | 160 | 16 |

The table below shows the number of OFDM symbols per slot, the number of slots per frame, and the number of slots per subframe, according to the subcarrier spacing Δf=2^{u}*15 kHz.

TABLE 2

| u | N^{slot}_{symb} | N^{frame, u}ₛₗₒₜ | N^{subframe, u}ₛₗₒₜ |
|---|---|---|---|
| 2 | 12 | 40 | 4 |

For a subcarrier spacing configuration u, slots may be indexed within a subframe in ascending order as follows: n^{u}ₛ∈{0, . . . , n^{subframe,u}ₛₗₒₜ−1} and indexed within a frame in ascending order as follows: n^{u}_{s,f}∈{0, . . . , n^{frame,u}ₛₗₒₜ−1}.

The slot includes multiple (e.g., 14 or 12) symbols in the time domain. For each numerology (e.g., subcarrier spacing) and carrier, a resource grid of N^{size,u}_{grid,x}*N^{RB}_{sc} subcarriers and N^{subframe,u}_{symb} OFDM symbols is defined, starting at a common resource block (CRB) N^{start,u}_{grid} indicated by higher layer signaling (e.g., RRC signaling), where N^{size,u}_{grid,x} is the number of resource blocks (RBs) in the resource grid and the subscript x is DL for downlink and UL for uplink. N^{RB}_{sc} is the number of subcarriers per RB. In the 3GPP-based wireless communication system, N^{RB}_{sc} is typically 12. There is one resource grid for a given antenna port p, a subcarrier spacing configuration u, and a transmission link (DL or UL). The carrier bandwidth N^{size,u}_{grid} for the subcarrier spacing configuration u is given to the UE by a higher layer parameter (e.g., RRC parameter). Each element in the resource grid for the antenna port p and the subcarrier spacing configuration u is referred to as a resource element (RE) and one complex symbol may be mapped to each RE. Each RE in the resource grid is uniquely identified by an index k in the frequency domain and an index l representing a symbol location relative to a reference point in the time domain. In the NR system, an RB is defined by 12 consecutive subcarriers in the frequency domain. In the NR system, RBs are classified into CRBs and physical resource blocks (PRBs). The CRBs are numbered from 0 upwards in the frequency domain for the subcarrier spacing configuration u. The center of subcarrier 0 of CRB 0 for the subcarrier spacing configuration u is equal to ‘Point A’ which serves as a common reference point for RB grids. The PRBs for subcarrier spacing configuration u are defined within a bandwidth part (BWP) and numbered from 0 to N^{size,u}_{BWP,i}−1, where i is a number of the BWP. The relation between a PRB n_{PRB} in a BWP i and a CRB n^{u}_{CRB} is given by: n^{u}_{PRB}=n^{u}_{CRB}+N^{size,u}_{BWP,i}, where N^{size}_{BWP,i} is a CRB in which the BWP starts relative to CRB 0. The BWP includes a plurality of consecutive RBs in the frequency domain. For example, the BWP may be a subset of contiguous CRBs defined for a given numerology uᵢ in the BWP i on a given carrier. A carrier may include a maximum of N (e.g., 5) BWPs. The UE may be configured to have one or more BWPs on a given component carrier. Data communication is performed through an activated BWP and only a predetermined number of BWPs (e.g., one BWP) among BWPs configured for the UE may be active on the component carrier.

The UE for which carrier aggregation is configured may be configured to use one or more cells. If the UE is configured with a plurality of serving cells, the UE may be configured with one or multiple cell groups. The UE may also be configured with a plurality of cell groups associated with different BSs. Alternatively, the UE may be configured with a plurality of cell groups associated with a single BS. Each cell group of the UE includes one or more serving cells and includes a single PUCCH cell for which PUCCH resources are configured. The PUCCH cell may be a Pcell or an Scell configured as the PUCCH cell among Scells of a corresponding cell group. Each serving cell of the UE belongs to one of cell groups of the UE and does not belong to a plurality of cells.

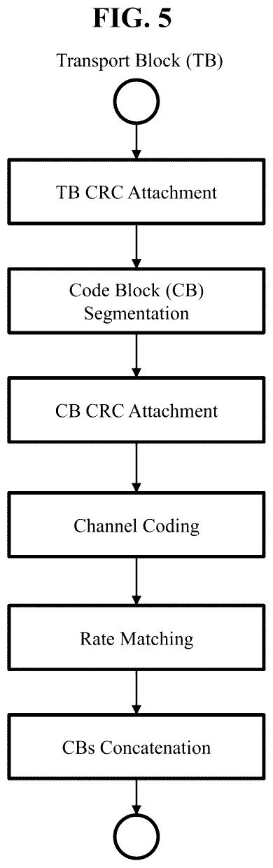

FIG. 5 illustrates a process for processing a transport block (TB) on a transmitting side.

In order for a receiving side to correct errors that radio signals experience in a radio channel, a transmitting side encodes information using a forward error correction code and then transmits the encoded information. The receiving side demodulates a received signal and decodes the error correction code to thereby recover the information transmitted by the transmitting side. In this decoding procedure, errors in the received signal caused by a radio channel are corrected.

Data arrives at a coding block in the form of a maximum of two transport blocks every transmission time interval (TTI) in each DL/UL cell. The following coding steps may be applied to each transport block of the DL/UL cell:
cyclic redundancy check (CRC) attachment to a transport block;
code block segmentation and CRC attachment to a code block;
channel coding;
rate matching; and
code block concatenation.

In an actual communication system, a transport block of a predetermined size or larger is divided into a plurality of smaller data blocks and then is encoded, to facilitate actual implementation of coding. The smaller data blocks are called code blocks. While the code blocks are generally of the same size, one of the code blocks may have a different size due to a limited size of an internal interleaver of a channel encoder. Error correction coding is performed on each code block of a predetermined interleaver size and then interleaving is performed to reduce the impact of burst errors that are generated during transmission over a radio channel. The error-corrected and interleaved code block is transmitted by being mapped to an actual radio resource. The amount of radio resources used for actual transmission is designated. Thus, the encoded code blocks are rate-matched to the amount of the radio resources. In general, rate matching is performed through puncturing or repetition. For example, if the amount of radio resources, i.e., the number of transmission bits capable of being transmitted on the radio resources, is M and if a coded bit sequence, i.e., the number of output bits of the encoder, is N, in which M is different from N, then rate matching is performed to match the length of the coded bit sequence to M. If M>N, then all or a part of bits of the coded bit sequence are repeated to match the length of the rate-matched sequence to M. If M<N, then a part of the bits of the coded bit sequence is punctured to match the length of the rate-matched sequence to M and the punctured bits are excluded from transmission.

In wireless communication systems, the transmitting side encodes data to be transmitted based on channel coding with a specific code rate. Then, the transmitting side adjusts the code rate of the data to be transmitted through a rate matching process involving puncturing and repetition.

There are various types of error correction codes, but the size of an information block capable of achieving optimal performance is determined depending on the error correction code. While many coding schemes are available for achieving high-capacity information performance with long information block lengths, the majority of the coding schemes do not consistently show good performance over a wide range of information block lengths and code rates. However, turbo codes, low-density parity check (LPDC) codes, and polar codes show promising BLER performance in a wide range of coding rates and code lengths and hence are considered to be used in the NR system. As demand for various cases such as eMBB, massive IoT, and URLLC has increased, a coding scheme providing greater channel coding efficiency than in turbo codes is needed. In addition, increase in a maximum number of subscribers capable of being accommodated by a channel, i.e., increase in capacity, has been required. Polar codes among various error correction codes are codes providing a new framework capable of solving problems of legacy channel codes and were invented by Ankan at Bilkent University (reference: E. Arikan, “Channel Polarization: A Method for Constructing Capacity-Achieving Codes for Symmetric Binary-Input Memoryless Channels,” in IEEE Transactions on Information Theory, vol. 55, no. 7, pp. 3051-3073, July 2009). Polar codes are the first capacity-achieving codes with low encoding and decoding complexities, which were proven mathematically. Polar codes outperform the turbo codes in large information block lengths while no error flow is present. Hereinafter, channel coding using the polar codes is referred to as polar coding.

Polar codes are known as codes capable of achieving the capacity of a given binary discrete memoryless channel. This can be achieved only when a block size is sufficiently large. That is, polar codes are codes capable of achieving the capacity of a channel if the size N of the codes infinitely increases. Polar codes have low encoding and decoding complexity and may be successfully decoded. Polar codes are a sort of linear block error correction codes. Multiple recursive concatenations are basic building blocks for the polar codes and are bases for code construction. Physical conversion of channels in which physical channels are converted into virtual channels occurs and such conversion is based on a plurality of recursive concatenations. If multiple channels are multiplied and accumulated, most of the channels may become better or worse. The idea underlying polar codes is to use good channels. For example, data is sent through good channels at rate 1 and data is sent through bad channels at rate 0. That is, through channel polarization, channels enter a polarized state from a normal state.

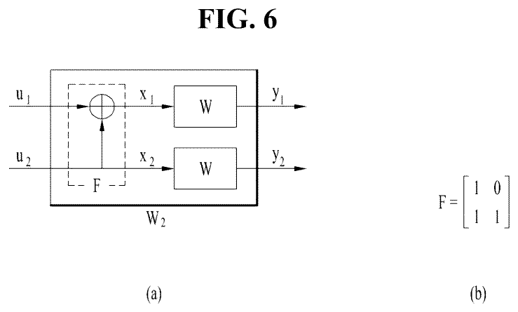

FIG. 6 is an example of a block diagram for a polar encoder.

FIG. 6(a) illustrates a base module of a polar code, particularly, first level channel combining for polar coding. In FIG. 6(a), W₂ denotes an entire equivalent channel obtained by combining two binary-input discrete memoryless channels (B-DMCs), Ws. Herein, u₁ and u₂ are binary-input source bits and y₁ and y₂ are output coded bits. Channel combining is a procedure of concatenating the B-DMCs in parallel.

FIG. 6(b) illustrates a base matrix F for the base module. The binary-input source bits u₁ and u₂ input to the base matrix F and the output coded bits x₁ and x₂ of the base matrix F have the following relationship.

$$[ \begin{matrix}{u}_{1} & {u}_{2}\end{matrix} ] [ \begin{matrix}1 & 0 \\ 1 & 1\end{matrix} ] = [ \begin{matrix}{x}_{1} & {x}_{2}\end{matrix} ] \qquad [ Equation 1 ]$$

The channel W₂ may achieve symmetric capacity I(W) which is a highest rate. In the B-DMC W, symmetric capacity is an important parameter which is used to measure a rate and is a highest rate at which reliable communication can occur over the channel W. The B-DMC may be defined as follows.

$$I ( W ) = {\sum }_{y ∈ Y} {\sum }_{x ∈ X} 1 / 2 W ( y \vert x ) log \frac{w ( y \vert x )}{1 / 2 w ( y \vert 0 ) + 1 / 2 w ( y \vert 1 )} \qquad [ Equation 2 ]$$

It is possible to synthesize or create a second set of N binary input channels out of N independent copies of a given B-DMC W and the channels have the properties {W_{N}⁽ⁱ⁾: 1<=i<=N}. If N increases, there is a tendency for a part of the channels to have capacity approximating to 1 and for the remaining channels to have capacity approximating to 0. This is called channel polarization. In other words, channel polarization is a process of creating a second set of N channels {W_{N}⁽ⁱ⁾: 1<=i<=N} using N independent copies of a given B-DMC W. The effect of channel polarization means that, when N increases, all symmetric capacity terms {I(W_{N}⁽ⁱ⁾)} tend towards 0 or 1 for all except a vanishing fraction of indexes i. In other words, the concept behind channel polarization in the polar codes is transforming N copies (i.e., N transmissions) of a channel having a symmetric capacity of I(W) (e.g., additive white Gaussian noise channel) into extreme channels of capacity close to 1 or 0. Among the N channels, an I(W) fraction will be perfect channels and an 1−I(W) fraction will be completely noise channels. Then, information bits are transmitted only through good channels and bits input to the other channels are frozen to 1 or 0. The amount of channel polarization increases along with a block length. Channel polarization consists of two phases: channel combining phase and channel splitting phase.

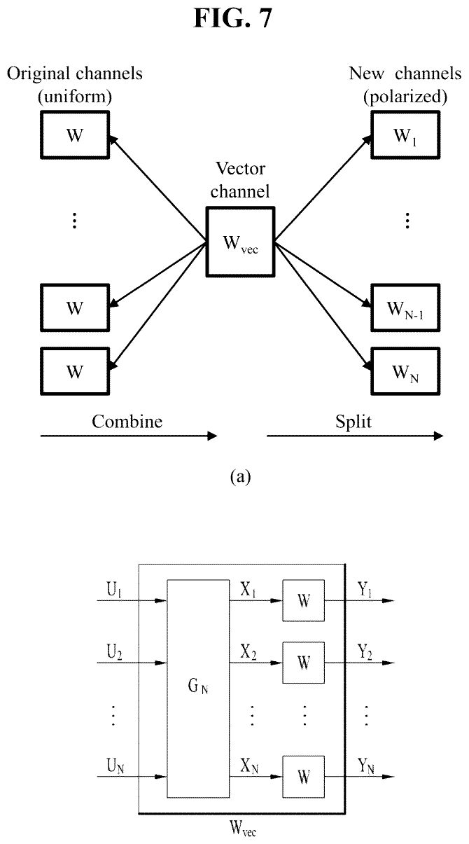

FIG. 7 illustrates the concept of channel combining and channel splitting for channel polarization. As illustrated in FIG. 7, when N copies of an original channel W are properly combined to create a vector channel W_{vec} and then are split into new polarized channels, the new polarized channels are categorized into channels having capacity C(W)=1 and channels having C(W)=0 if N is sufficiently large. In this case, since bits passing through the channels having the channel capacity C(W))=1 are transmitted without error, it is better to transmit information bits therethrough and, since bits passing through the channels having capacity C(W)=0 cannot transport information, it is better to transport frozen bits, which are meaningless bits, therethrough.

Referring to FIG. 7(a), copies of a given B-DMC W are combined in a recursive manner to output a vector channel W_{vec} given by X_{N}→Y_{N}, where N=2ⁿ and n is an integer equal to or greater than 0. Recursion always begins at the 0th level and W₁=W. If n is 1 (n=1), this means the first level of recursion in which two independent copies of W₁ are combined. If the above two copies are combined, a channel W₂: X₂→Y₂ is obtained. A transitional probability of this new channel W₂ may be represented by the following equation.

W₂(y₁,y₂|u₁,u₂)=W(y₁|u₁⊕u₂)W(Y₁|u₂) [Equation 3]

If the channel W₂ is obtained, two copies of the channel W₂ are combined to obtain a single copy of a channel W₄. Such recursion may be represented by W₄: X₄→Y₄ having the following transitional probability.

$${W}_{4} ( {y}_{1}^{4} \vert {u}_{1}^{4} ) = {W}_{2} ( {y}_{1}^{2} \vert {u}_{1} {⊕}_{2} , {u}_{3} {⊕}_{4} ) {W}_{2} ( {y}_{3}^{4} \vert {u}_{2} , {u}_{4} ) \qquad [ Equation 4 ]$$

In FIG. 7(b), G_{N} is a size-N generator matrix. The relationship between input u^{N}₁ to G_{N} and output x^{N}₁ of G_{N} of FIG. 7(b) may be represented as x^{N}₁=u^{N}₁G_{N}, where x^{N}₁={x₁, . . . , x_{N}}, u^{N}₁={u₁, . . . , u_{N}}. When N B-DMCs are combined, each B-DMC may be expressed in a recursive manner. That is, G_{N} may be indicated by the following equation.

G_{N}=B_{N}F^{Wn} [Equation 5]

Herein, ⊗ denotes the Kronecker product, N=2ⁿ, n>=1, F^{⊗n}=F⊗F^{⊗(n-1)}, and F^{⊗0}=1. B_{N} is a permutation matrix known as a bit-reversal operation and B_{N}=R_{N}(I₂⊗B_{N/2}) and may be recursively computed. I₂ is a 2-dimensional identity matrix and this recursion is initialized to B₂=I₂. R_{N} is a bit-reversal interleaver and is used to map an input s^{N}₁={s₁, . . . , s_{N}} to an output x^{N}₁={s₁, s₃, . . . , s_{N-1}, s₂, . . . , s_{N}}. For example, G₂ corresponds to a base matrix F shown in FIG. 6(b). G₄ may be expressed as the following matrix.

$${G}_{4} = {[ \begin{matrix}1 & 0 & 0 & 0 \\ 0 & 0 & 1 & 0 \\ 0 & 1 & 0 & 0 \\ 0 & 0 & 0 & 1\end{matrix} ] [ \begin{matrix}1 & 0 \\ 1 & 1\end{matrix} ]}^{{⊗}_{2}} = [ \begin{matrix}1 & 0 & 0 & 0 \\ 1 & 0 & 1 & 0 \\ 1 & 1 & 0 & 0 \\ 1 & 1 & 1 & 1\end{matrix} ] \qquad [ Equation 6 ]$$

A bit-reversal interleaver may not be included on the transmitting side. Without considering the bit-reversal interleaver, G_{N} may be expressed as G_{N}=(G₂)^{⊗}^{ₙ} (where N=2ⁿ). (G₂)^{⊗}^{ₙ} denotes the n-th Kronecker power of the matrix G₂, where G₂ is the same as the basic matrix F shown in FIG. 6(b).

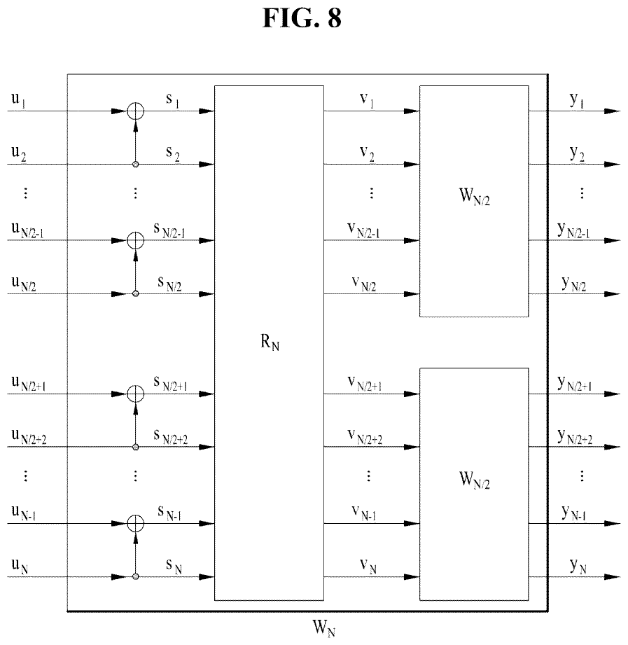

The relationship of Equation 5 is illustrated in FIG. 8.

FIG. 8 illustrates N-th level channel combining for a polar code.

A process of defining an equivalent channel for specific input after combining N B-DMCs Ws is called channel splitting. Channel splitting may be represented as a channel transition probability indicated by the following equation.

$${W}_{N}^{i} ( {y}_{1}^{N} , {u}_{1}^{i - 1} \vert {u}_{i} ) = {\sum }_{{u}_{i + 1}^{N}} \frac{1}{{2}^{N - 1}} {W}_{N} ( {y}_{1}^{N} \vert {u}_{1}^{N} ) \qquad [ Equation 7 ]$$

Channel polarization has the following characteristics:
>Conservation: C(W−)+C(W+)=2C(W),
>Extremization: C(W⁻)<=C(W)<=C(W⁺).

When channel combining and channel splitting are performed, the following theorem may be obtained.

* Theorem: For any B-DMC W, channels {W_{N}⁽ⁱ⁾} are polarized in the following sense. For any fixed δ∈{0,1}, as N goes to infinity through powers of 2, the fraction of indexes i∈{1, . . . , N} for channel capacity I(W_{N}⁽ⁱ⁾)∈(1−δ,1] goes to I(W) and the faction of i for channel capacity I(W_{N}⁽ⁱ⁾)∈[0,δ) goes to 1−I(W). Hence, if N→∞, then channels are perfectly noisy or are polarized free of noise. These channels can be accurately recognized by the transmitting side. Therefore, bad channels are fixed and non-fixed bits may be transmitted on good channels.

That is, if the size N of polar codes is infinite, a channel has much noise or is free of noise, with respect to a specific input bit. This has the same meaning that the capacity of an equivalent channel for a specific input bit is divided into 0 or I(W).

Inputs of a polar encoder are divided into bit channels to which information data is mapped and bit channels to which the information data is not mapped. As described earlier, according to the theorem of the polar code, if a codeword of the polar code goes to infinity, the input bit channels may be classified into noiseless channels and noise channels. Therefore, if information is allocated to the noiseless bit channels, channel capacity may be obtained. However, in actuality, a codeword of an infinite length cannot be configured, reliabilities of the input bit channels are calculated and data bits are allocated to the input bit channels in order of reliabilities. In the present disclosure, bit channels to which data bits are allocated are referred to as good bit channels. The good bit channels may be input bit channels to which the data bits are mapped. Bit channels to which data is not mapped are referred to as frozen bit channels. A known value (e.g., 0) is input to the frozen bit channels and then encoding is performed. Any values which are known to the transmitting side and the receiving side may be mapped to the frozen bit channels. When puncturing or repetition is performed, information about the good bit channels may be used. For example, positions of codeword bits (i.e., output bits) corresponding to positions of input bits to which information bits are not allocated may be punctured.

A decoding scheme of the polar codes is a successive cancellation (SC) decoding scheme. The SC decoding scheme obtains a channel transition probability and then calculates a likelihood ratio (LLR) of input bits using the channel transition probability. In this case, the channel transition probability may be calculated in a recursive form if channel combining and channel splitting procedures use characteristics of the recursive form. Therefore, a final LLR value may also be calculated in the recursive form. First, a channel transition probability W_{N}⁽ⁱ⁾(y₁^{N},u₁ⁱ⁻¹|u₁) of an input bit uᵢ may be obtained as follows. u₁ⁱ may be split into odd indexes and even indexes as expressed as u_{1,o}ⁱ, u_{1,e}ⁱ, respectively. The channel transition probability may be indicated by the following equations.

$${W}_{2 N}^{( 2 i - 1 )} ( {y}_{1}^{2 N} , {u}_{1}^{2 i - 1} \vert {u}_{2 i - 1} ) = {\sum }_{{u}_{2 i}^{2 N}} \frac{1}{{2}^{2 N - 1}} {W}_{2 N} ( {y}_{1}^{2 N} \vert {u}_{1}^{2 N} ) = {\sum }_{{u}_{2 i , o}^{2 N} , {u}_{2 i , e}^{2 N}} \frac{1}{{2}^{2 N - 1}} {W}_{N} ( {y}_{1}^{N} \vert {u}_{1 , o}^{2 N} ⊕ {u}_{i , e}^{2 N} ) {W}_{N} ( {y}_{N + 1}^{2 N} \vert {u}_{1 , e}^{2 N} ) = {\sum }_{{u}_{2 i}} \frac{1}{2} {\sum }_{{u}_{2 i + 1 , e}^{2 N}} \frac{1}{{2}^{N - 1}} {W}_{N} ( {y}_{N + 1}^{2 N} \vert {u}_{1 , e}^{2 N} ) \cdot {\sum }_{{u}_{2 i + 1 , o}^{2 N}} \frac{1}{{2}^{N - 1}} {W}_{N} ( {y}_{1}^{N} \vert {u}_{1 , o}^{2 N} ⊕ {u}_{i , e}^{2 N} ) = {\sum }_{{u}_{2 i}} \frac{1}{2} {W}_{N}^{( i )} ( {y}_{1}^{N} , {u}_{1 , o}^{2 i - 2} ⊕ {u}_{i , e}^{2 i - 2} \vert {u}_{2 i - 1} ⊕ {u}_{2 i} ) \cdot {W}_{N}^{( i )} ( {y}_{N + 1}^{2 N} , {u}_{1 , e}^{2 i - 2} \vert {u}_{2 i} ) \qquad [ Equation 8 ]$$

$$where {W}_{N}^{( i )} ( {y}_{1}^{N} , {u}_{1}^{i - 1} \vert {u}_{i} ) = {\sum }_{{u}_{i + 1}^{N}} \frac{1}{{2}^{N - 1}} {W}_{N} ( {y}_{1}^{N} \vert {u}_{1}^{N} ) .$$

$${W}_{2 N}^{( 2 )} ( {y}_{1}^{2 N} , {u}_{1}^{{2}^{- 1}} \vert {u}_{2 i} ) = {\sum }_{{u}_{2 i + 1}^{2 N}} \frac{1}{{2}^{2 N - 1}} {W}_{2 N} ( {y}_{1}^{2 N} \vert {u}_{1}^{2 N} ) = {\sum }_{{u}_{2 i + 1 , o}^{2 N} {u}_{2 i + 1 , e}^{2 N}} \frac{1}{{2}^{2 N - 1}} {W}_{N} ( {y}_{1}^{N} \vert {u}_{1 , o}^{2 N} ⊕ {u}_{i , e}^{2 N} ) {W}_{N} ( {y}_{N + 1}^{2 N} \vert {u}_{1 , e}^{2 N} ) = \frac{1}{2} {\sum }_{{u}_{2 i + 1 , e}^{2 N}} \frac{1}{{2}^{N - 1}} {W}_{N} ( {y}_{N + 1}^{2 N} \vert {u}_{1 , e}^{2 N} ) \cdot {\sum }_{{u}_{2 i + 1 , o}^{2 N}} \frac{1}{{2}^{N - 1}} {W}_{N} ( {y}_{1}^{N} \vert {u}_{1 , o}^{2 N} ⊕ {u}_{i , e}^{2 N} ) = \frac{1}{2} {W}_{N}^{( i )} ( {y}_{1}^{N} , {u}_{1 , o}^{2 i - 2} ⊕ {u}_{i , e}^{2 i - 2} \vert {u}_{2 i - 1} ⊕ {u}_{2 i} ) \cdot {W}_{N}^{( i )} ( {y}_{N + 1}^{2 N} , {u}_{1 , e}^{2 - 2} \vert {u}_{2 i} ) \qquad [ Equation 9 ]$$

A polar decoder retrieves information and generates an estimate u\hat{ }^{N}₁ of u^{N}₁ using values (e.g., reception bits, frozen bits, etc.) known for the polar codes. The LLR is defined as follows.

$${L}_{N}^{( i )} ( {y}_{1}^{N} , {u}_{1}^{i - 1} ) = \frac{{W}_{N}^{( i )} ( {y}_{1}^{N} , {u}_{1}^{i - 1} \vert {u}_{i} = 0 )}{{W}_{N}^{( i )} ( {y}_{1}^{N} , {u}_{1}^{i - 1} \vert {u}_{i} = 1 )} \qquad [ Equation 10 ]$$

The LLR may be recursively calculated as follows.

$${L}_{N}^{( 2 i - 1 )} ( {y}_{1}^{N} , {\hat{u}}_{1}^{2 i - 2} ) = \frac{{L}_{N / 2}^{( i )} ( {y}_{1}^{N / 2} , {\hat{u}}_{1 , o}^{2 i - 2} ⊕ {\hat{u}}_{1 , e}^{2 i - 2} ) \cdot {L}_{N / 2}^{( i )} ( {y}_{N / 2 + 1}^{N} , {\hat{u}}_{1 , e}^{2 i - 2} ) + 1}{{L}_{N / 2}^{( i )} ( {y}_{1}^{N / 2} , {\hat{u}}_{1 , o}^{2 i - 2} ⊕ {\hat{u}}_{1 , e}^{2 i - 2} ) + {L}_{N / 2}^{( i )} ( {y}_{N / 2 + 1}^{N} , {\hat{u}}_{1 , e}^{2 i - 2} )} \\ {L}_{N}^{( 2 i )} ( {y}_{1}^{N} , {\hat{u}}_{1}^{2 i - 1} ) = {[ {L}_{N / 2}^{( i )} ( {y}_{1}^{N / 2} , {\hat{u}}_{1 , o}^{2 i - 2} ⊕ {\hat{u}}_{1 , e}^{2 i - 2} ) ]}^{1 - 2 {\hat{u}}_{2 i - 1}} \cdot {L}_{N / 2}^{( i )} ( {y}_{N / 2 + 1}^{N} , {\hat{u}}_{1 , e}^{2 i - 2} ) \qquad [ Equation 11 ]$$

Recursive calculation of LLRs is traced back to a code length of 1 with an LLR L⁽¹⁾₁(yᵢ)=W(yᵢ|0)/W(yᵢ|1). L⁽¹⁾₁(yᵢ) is soft information observed from a channel.

The complexity of a polar encoder and an SC decoder varies with the length N of polar codes and is known as having O(N log N). Assuming that K input bits are used for a length-N polar code, a coding rate becomes N/K. If a generator matrix of a polar encoder of a data payload size N is G_{N}, an encoded bit may be represented as x^{N}₁=u^{N}₁G_{N}. It is assumed that K bits out of u^{N} correspond to payload bits, a row index of G_{N} corresponding to the payload bits is i, and a row index of G_{N} corresponding to (N−K) bits is F. A minimum distance of the polar codes may be given as dₘᵢₙ(C)=minᵢ∈_{I}2^{wt(i)}, where wt(i) is the number of 1s within binary extension of i and i=0, 1, . . . , N−1.

SC list (SCL) decoding is an extension of a basic SC decoder. In this type of decoder, L decoding paths are simultaneously considered in each decoding stage. Herein, L is an integer. In other words, in the case of the polar codes, a list-L decoding algorithm is an algorithm for simultaneously tracking L paths in a decoding process.

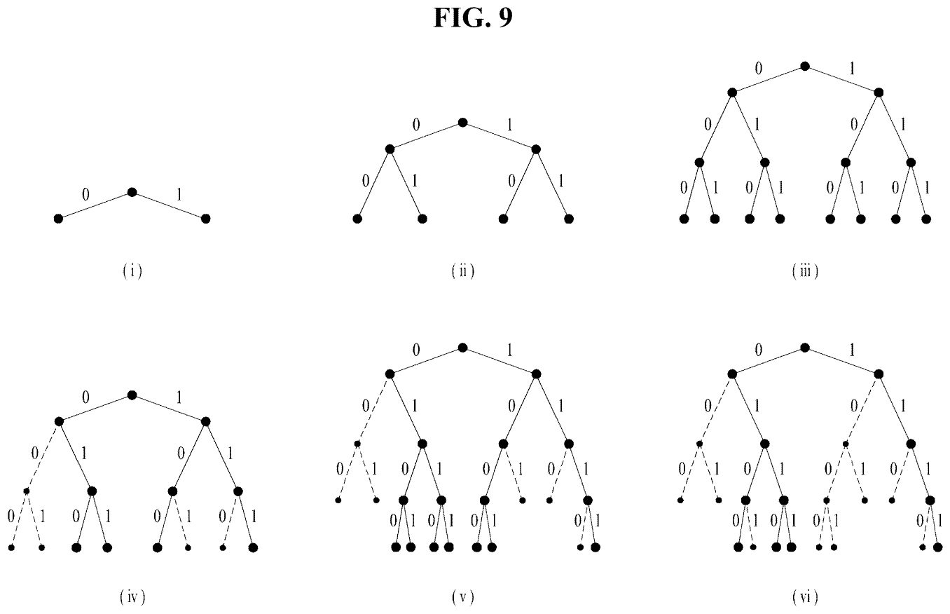

FIG. 9 illustrates an evolution of decoding paths in a list-L decoding process. For convenience of description, it is assumed that the number of bits that should be determined is n and all bits are not frozen. If a list size L is 4, each level includes at most 4 nodes with paths that continue downward. Discontinued paths are expressed by dotted lines in FIG. 9. A process in which decoding paths evolve in list-L decoding will now be described with reference to FIG. 9. i) If list-L decoding is started, the first unfrozen bit may be either 0 or 1. ii) list-L decoding continues. The second unfrozen bits may be either 0 or 1. Since the number of paths is not greater than L=4, pruning is not needed yet. iii) Consideration of all options for the first bit (i.e., a bit of the first level), the second bit (i.e. a bit of the second level), and the third bit (i.e., a bit of the third level) results in 8 decoding paths which are excessive because L=4. iv) the 8 decoding paths are pruned to L (=4) promising paths. v) 4 active paths continue by considering two options of the fourth unfrozen bit. In this case, the number of paths is doubled, i.e., 8 paths which are excessive because L=4. vi) The 8 paths are pruned back to L (=4) best paths. In the example of FIG. 7, 4 candidate codewords 0100, 0110, 0111, and 1111 are obtained and one of the codewords is determined to be a codeword most similar to an original codeword. In a similar manner to a normal decoding process, for example, in a pruning process or a process of determining a final codeword, a path in which the sum of LLR absolute values is largest may be selected as a survival path. If a CRC is present, the survival path may be selected through the CRC.

Meanwhile, CRC-aided SCL decoding is SCL decoding using CRC and improves the performance of polar codes. CRC is the most widely used technique in error detection and error correction in the field of information theory and coding. For example, if an input block of an error correction encoder has K bits and the length of information bits is k, and the length of CRC sequences is m bits, then K=k+m. CRC bits are a part of source bits for an error correction code. If the size of channel codes used for encoding is N, a code rate R is defined as R=K/N. CRC aided SCL decoding serves to detect an errorless path while a receiving device confirms a CRC code with respect to each path. An SCL decoder outputs candidate sequences to a CRC detector. The CRC detector feeds back a check result in order to aid in determining a codeword.

Although complicated as compared with an SC algorithm, SCL decoding or CRC aided SCL decoding has an advantage of excellent decoding performance. For more details of a list-L decoding algorithm of the polar codes, refer to ‘I. Tal and A. Vardy, “List decoding of polar codes,” in Proc. IEEE Int. Symp. Inf. Theory, pp. 1-5, July 2011’.

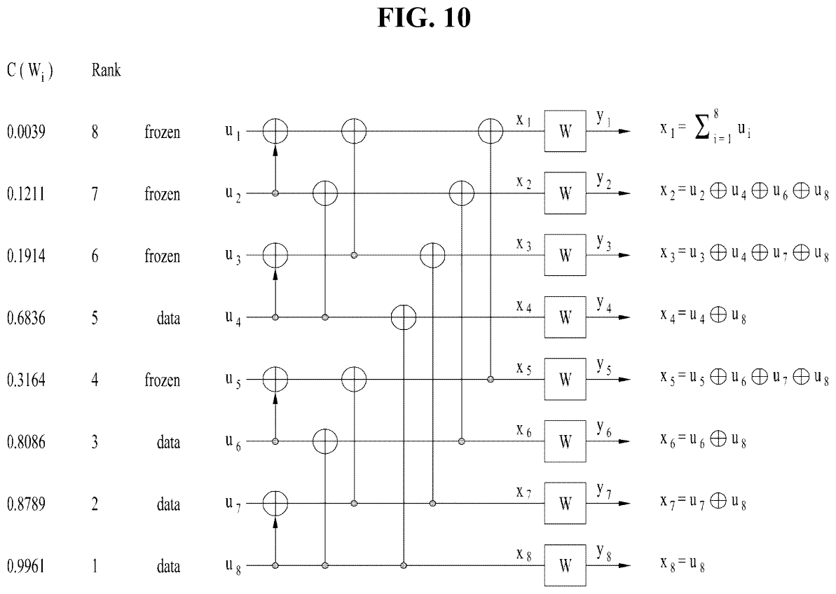

FIG. 10 illustrates the concept of selecting position(s) to which information bit(s) are to be allocated in polar codes.

In the example of FIG. 10, it is assumed that the size N of mother codes is 8, i.e., the size N of polar codes is 8, and a code rate is ½.

In FIG. 10, C(Wᵢ) denotes the capacity of a channel Wᵢ and corresponds to the reliability of channels that input bits of a polar code experience. When channel capacities corresponding to input bit positions of the polar code are as illustrated in FIG. 10, reliabilities of the input bit positions are ranked as illustrated in FIG. 10. To transmit data at a code rate of ½, a transmitting device allocates 4 bits constituting the data to 4 input bit positions having high channel capacities among 8 input bit positions (i.e., input bit positions denoted as u₄, u₆, u₇, and us among input bit positions u₁ to u₈ of FIG. 10) and freezes the other input bit positions. A generator matrix G₈ corresponding to the polar code of FIG. 10 is as follows. The generator matrix Gₛ may be acquired based on (G₂)^{⊗}^{ₙ}.

$${G}_{8} = [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] \qquad [ Equation 12 ]$$

The input bit positions denoted as u₁ to u₈ of FIG. 10 correspond one by one to rows from the highest row to the lowest row of G₈. Referring to FIG. 10, it may be appreciated that the input bit corresponding to us affects all output coded bits. On the other hand, it may be appreciated that the input bit corresponding to u₁ affects only yᵢ among the output coded bits. Referring to Equation 12, when binary-input source bits u₁ to u₈ are multiplied by G₈, a row in which the input bits appear at all output bits is the lowest row [1, 1, 1, 1, 1, 1, 1, 1] in which all elements are 1, among rows of G₈. Meanwhile, a row in which the binary-input source bits appear at only one output bit is a row in which one element is 1 among the rows of G₈, i.e., a row [1, 0, 0, 0, 0, 0, 0, 0] in which a row weight is 1. Similarly, it may be appreciated that a row in which a row weight is 2 reflects input bits corresponding to the row in two output bits. Referring to FIG. 10 and Equation 12, u₁ to us correspond one by one to the rows of Gₛ and bit indexes for distinguishing between input positions of u₁ to u₈, i.e., bit indexes for distinguishing between the input positions, may be assigned to the rows of G₈.

Hereinafter, for Polar codes, it may be assumed that bit indexes from 0 to N−1 are sequentially allocated to rows of G_{N} starting from the highest row having the smallest row weight with respect to N input bits. For example, referring to FIG. 10, a bit index 0 is allocated to the input position of u₁, i.e., the first row of G₈ and a bit index 7 is allocated to the input position of us, i.e., the last row of G₈. However, since the bit indexes are used to indicate input positions of the polar code, a scheme different from the above allocation scheme may be used. For example, bit indexes from 0 to N−1 may be allocated staring from the lowest row having the largest row weight.

In the case of output bit indexes, as illustrated in FIG. 10 and Equation 12, it may be assumed that bit indexes from 0 to N−1 or bit indexes from 1 to N are assigned to columns from the first column having the largest column weight to the last column having the smallest column weight among columns of G_{N}.

In Polar codes, setting of information bits and frozen bits is one of the most important elements in the configuration and performance of the polar code. That is, determination of ranks of input bit positions may be an important element in the performance and configuration of the polar code. For Polar codes, bit indexes may distinguish input or output positions of the polar code. In the present disclosure, a sequence obtained by enumerating reliabilities of bit positions in ascending or descending order are referred to as a bit index sequence or polar sequence. That is, the bit index sequence represents reliabilities of input or output bit positions of the polar code in ascending or descending order. A transmitting device inputs information bits to input bits having high reliabilities based on the input bit index sequence and performs encoding using the polar code. A receiving device may discern input positions to which information bits are allocated or input positions to which frozen bits are allocated, using the same or corresponding input bit index sequence. That is, the receiving device may perform polar decoding using an input bit index sequence which is identical to or corresponds to an input bit index sequence used by the transmitting device and using a corresponding polar code. In the following description, it may be assumed that an input bit index sequence is predetermined so that information bit(s) may be allocated to input bit position(s) having high reliabilities. In the present disclosure, the input bit index sequence is also called a Polar sequence.

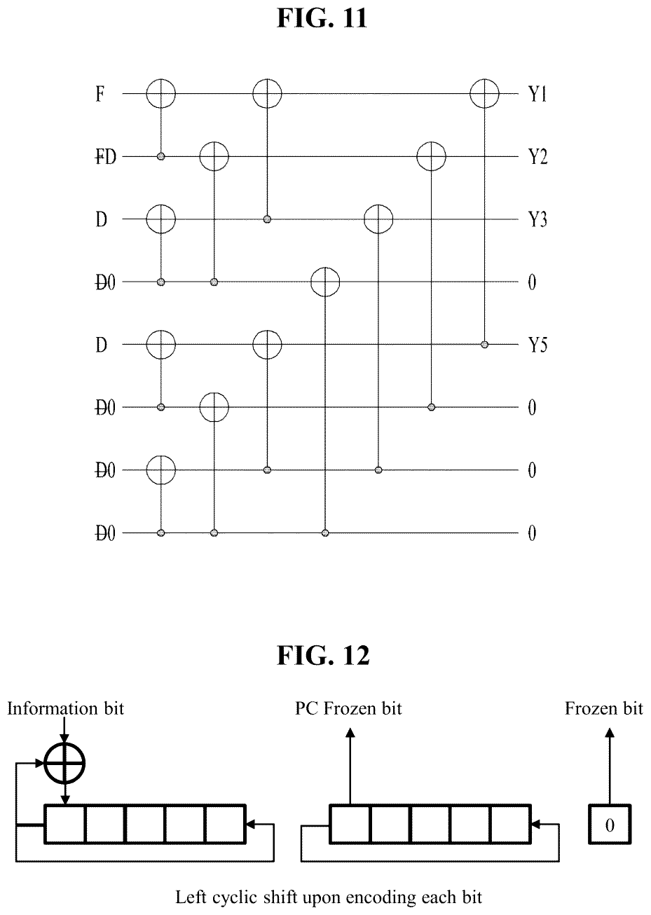

FIG. 11 illustrates puncturing and information bit allocation for polar codes. In FIG. 11, F denotes a frozen bit, D denotes an information bit, and 0 denotes a skipping bit.

Among coded bits, the case in which an information bit is changed to a frozen bit may occur according to an index or position of a punctured bit. For example, if output coded bits for a mother code of N=8 should be punctured in order of Y8, Y7, Y6, Y4, Y5, Y3, Y2, and Y1 and a target code rate is ½, then Y8, Y7, Y6, and Y4 are punctured, U8, U7, U6, and U4 connected only to Y8, Y7, Y6, and Y4 are frozen to 0, and these input bits are not transmitted, as illustrated in FIG. 9. An input bit changed to a frozen bit by puncturing of a coded bit is referred to as a skipping bit or a shortening bit and a corresponding input position is referred to as a skipping position or a shortening position. Shortening is a rate matching method of inserting a known bit into an input bit position connected to a position of an output bit desired to be transmitted while maintaining the size of input information (i.e., the size of information blocks). Shortening is possible starting from input corresponding to a column in which a column weight is 1 in a generator matrix G_{N} and next shortening may be performed with respect to input corresponding to a column in which a column weight is 1 in a remaining matrix from which a column and row in which a column weight is 1 are removed. To prevent all information bits from being punctured, an information bit that should have been allocated to an information bit position may be reallocated in order of a high reliability within a set of frozen bit positions.

In the case of the polar code, decoding may be generally performed in the following order.
1. Bit(s) having low reliabilities are recovered first. Although reliability differs according to the structure of a decoder, since an input index in an encoder (hereinafter, an encoder input bit index or bit index) having a low value usually has a low reliability, decoding is generally performed staring from a low encoder input bit index.
2. When there is a known bit for a recovered bit, the known bit is used together with the recovered bit or the process of 1 is omitted and a known bit for a specific input bit position is immediately used, thereby recovering an information bit, which is an unknown bit. The information bit may be a source information bit (e.g., a bit of a transport block) or a CRC bit.

As explained earlier, the process of channel combining and channel splitting results in an equivalent channel being divided into a noisy channel and a noise-free channel. A data payload needs be transmitted over the noise-free channel. In other words, the data payload needs to be transmitted over the noise-free equivalent channel to achieve the desired performance. The noise-free equivalent channel may be determined by computing the value of the equivalent channel, Z(W)=Σ\sqrt{W(y|0)W(y|1)} for each input bit. Z(W) is called the Battacharyya parameter, which may represent a value corresponding to the upper bound of the error probability when a MAP (maximum a posteriori probability) decision for transmission of binary input 0 or 1 is performed. Therefore, the transmitting side may obtain the values of Z(W), select equivalent channel(s) up to the size of the data payload in ascending order (e.g., decreasing order) of the values of Z(W), and use the equivalent channel(s) for transmission of the data payload. For a binary erasure channel (BEC), Z(W) may be obtained through Equation 13.

$$Z ( {W}_{N}^{( i )} ) = Z ( {W}_{( {b}_{1} , {b}_{2} , … , {b}_{k - 1} )} ) = \{ \begin{matrix}2 Z ( {W}_{( {b}_{1} , {b}_{2} , … , {b}_{k - 1} )} ) - {Z ( {W}_{( {b}_{1} , {b}_{2} , … , {b}_{k - 1} )} )}^{2} , & if {b}_{k} = 0 \\ Z {( {W}_{( {b}_{1} , {b}_{2} , … , {b}_{k - 1} )} )}^{2} & if {b}_{k} = 1\end{matrix} \qquad [ Equation 13 ]$$

For example, when the BEC has a binary probability of 0.5 and a code block size of 8, the values of Z(W) may be calculated according to Equation 11 as follows: Z(W)={1.00, 0.68, 0.81, 0.12, 0.88, 0.19, 0.32, 0.00}. Thus, when the size of a data payload is 2, the data payload may be transmitted over equivalent channel 8 with Z(W)=0.00 and equivalent channel 4 with Z(W)=0.12.

As described above, since a polar encoder has different reliability depending on input positions, the transmitting side may allocate a data block (i.e., an information block before encoding) to bit channel(s) in order of reliability according to the size of the corresponding data block and perform encoding by setting all others to be frozen (e.g., with a value of ‘0’). For example, if the mother code size of the polar encoder (i.e., the maximum size of a code block that the polar encoder is capable of encoding) is N, and if the size of a data block input to the polar encoder is K, polar encoding is performed by arranging the bits of the data block in order of reliability in K bit channels and setting 0 to N−K bit channel(s).

The following shows the polar sequence used in NR (5G) systems (see the polar sequence defined in 3GPP TS 38.212 Rel-15).

### <Polar Sequence>

| W | I |
|---|---|
| 0 | 0 |
| 1 | 1 |
| 2 | 2 |
| 3 | 4 |
| 4 | 8 |
| 5 | 16 |
| 6 | 32 |
| 7 | 3 |
| 8 | 5 |
| 9 | 64 |
| 10 | 9 |
| 11 | 6 |
| 12 | 17 |
| 13 | 10 |
| 14 | 18 |
| 15 | 128 |
| 16 | 12 |
| 17 | 33 |
| 18 | 65 |
| 19 | 20 |
| 20 | 256 |
| 21 | 34 |
| 22 | 24 |
| 23 | 36 |
| 24 | 7 |
| 25 | 129 |
| 26 | 66 |
| 27 | 512 |
| 28 | 11 |
| 29 | 40 |
| 30 | 68 |
| 31 | 130 |
| 32 | 19 |
| 33 | 13 |
| 34 | 48 |
| 35 | 14 |
| 36 | 72 |
| 37 | 257 |
| 38 | 21 |
| 39 | 132 |
| 40 | 35 |
| 41 | 258 |
| 42 | 26 |
| 43 | 513 |
| 44 | 80 |
| 45 | 37 |
| 46 | 25 |
| 47 | 22 |
| 48 | 136 |
| 49 | 260 |
| 50 | 264 |
| 51 | 38 |
| 52 | 514 |
| 53 | 96 |
| 54 | 67 |
| 55 | 41 |
| 56 | 144 |
| 57 | 28 |
| 58 | 69 |
| 59 | 42 |
| 60 | 516 |
| 61 | 49 |
| 62 | 74 |
| 63 | 272 |
| 64 | 160 |
| 65 | 520 |
| 66 | 288 |
| 67 | 528 |
| 68 | 192 |
| 69 | 544 |
| 70 | 70 |
| 71 | 44 |
| 72 | 131 |
| 73 | 81 |
| 74 | 50 |
| 75 | 73 |
| 76 | 15 |
| 77 | 320 |
| 78 | 133 |
| 79 | 52 |
| 80 | 23 |
| 81 | 134 |
| 82 | 384 |
| 83 | 76 |
| 84 | 137 |
| 85 | 82 |
| 86 | 56 |
| 87 | 27 |
| 88 | 97 |
| 89 | 39 |
| 90 | 259 |
| 91 | 84 |
| 92 | 138 |
| 93 | 145 |
| 94 | 261 |
| 95 | 29 |
| 96 | 43 |
| 97 | 98 |
| 98 | 515 |
| 99 | 88 |
| 100 | 140 |
| 101 | 30 |
| 102 | 146 |
| 103 | 71 |
| 104 | 262 |
| 105 | 265 |
| 106 | 161 |
| 107 | 576 |
| 108 | 45 |
| 109 | 100 |
| 110 | 640 |
| 111 | 51 |
| 112 | 148 |
| 113 | 46 |
| 114 | 75 |
| 115 | 266 |
| 116 | 273 |
| 117 | 517 |
| 118 | 104 |
| 119 | 162 |
| 120 | 53 |
| 121 | 193 |
| 122 | 152 |
| 123 | 77 |
| 124 | 164 |
| 125 | 768 |
| 126 | 268 |
| 127 | 274 |
| 128 | 518 |
| 129 | 54 |
| 130 | 83 |
| 131 | 57 |
| 132 | 521 |
| 133 | 112 |
| 134 | 135 |
| 135 | 78 |
| 136 | 289 |
| 137 | 194 |
| 138 | 85 |
| 139 | 276 |
| 140 | 522 |
| 141 | 58 |
| 142 | 168 |
| 143 | 139 |
| 144 | 99 |
| 145 | 86 |
| 146 | 60 |
| 147 | 280 |
| 148 | 89 |
| 149 | 290 |
| 150 | 529 |
| 151 | 524 |
| 152 | 196 |
| 153 | 141 |
| 154 | 101 |
| 155 | 147 |
| 156 | 176 |
| 157 | 142 |
| 158 | 530 |
| 159 | 321 |
| 160 | 31 |
| 161 | 200 |
| 162 | 90 |
| 163 | 545 |
| 164 | 292 |
| 165 | 322 |
| 166 | 532 |
| 167 | 263 |
| 168 | 149 |
| 169 | 102 |
| 170 | 105 |
| 171 | 304 |
| 172 | 296 |
| 173 | 163 |
| 174 | 92 |
| 175 | 47 |
| 176 | 267 |
| 177 | 385 |
| 178 | 546 |
| 179 | 324 |
| 180 | 208 |
| 181 | 386 |
| 182 | 150 |
| 183 | 153 |
| 184 | 165 |
| 185 | 106 |
| 186 | 55 |
| 187 | 328 |
| 188 | 536 |
| 189 | 577 |
| 190 | 548 |
| 191 | 113 |
| 192 | 154 |
| 193 | 79 |
| 194 | 269 |
| 195 | 108 |
| 196 | 578 |
| 197 | 224 |
| 198 | 166 |
| 199 | 519 |
| 200 | 552 |
| 201 | 195 |
| 202 | 270 |
| 203 | 641 |
| 204 | 523 |
| 205 | 275 |
| 206 | 580 |
| 207 | 291 |
| 208 | 59 |
| 209 | 169 |
| 210 | 560 |
| 211 | 114 |
| 212 | 277 |
| 213 | 156 |
| 214 | 87 |
| 215 | 197 |
| 216 | 116 |
| 217 | 170 |
| 218 | 61 |
| 219 | 531 |
| 220 | 525 |
| 221 | 642 |
| 222 | 281 |
| 223 | 278 |
| 224 | 526 |
| 225 | 177 |
| 226 | 293 |
| 227 | 388 |
| 228 | 91 |
| 229 | 584 |
| 230 | 769 |
| 231 | 198 |
| 232 | 172 |
| 233 | 120 |
| 234 | 201 |
| 235 | 336 |
| 236 | 62 |
| 237 | 282 |
| 238 | 143 |
| 239 | 103 |
| 240 | 178 |
| 241 | 294 |
| 242 | 93 |
| 243 | 644 |
| 244 | 202 |
| 245 | 592 |
| 246 | 323 |
| 247 | 392 |
| 248 | 297 |
| 249 | 770 |
| 250 | 107 |
| 251 | 180 |
| 252 | 151 |
| 253 | 209 |
| 254 | 284 |
| 255 | 648 |
| 256 | 94 |
| 257 | 204 |
| 258 | 298 |
| 259 | 400 |
| 260 | 608 |
| 261 | 352 |
| 262 | 325 |
| 263 | 533 |
| 264 | 155 |
| 265 | 210 |
| 266 | 305 |
| 267 | 547 |
| 268 | 300 |
| 269 | 109 |
| 270 | 184 |
| 271 | 534 |
| 272 | 537 |
| 273 | 115 |
| 274 | 167 |
| 275 | 225 |
| 276 | 326 |
| 277 | 306 |
| 278 | 772 |
| 279 | 157 |
| 280 | 656 |
| 281 | 329 |
| 282 | 110 |
| 283 | 117 |
| 284 | 212 |
| 285 | 171 |
| 286 | 776 |
| 287 | 330 |
| 288 | 226 |
| 289 | 549 |
| 290 | 538 |
| 291 | 387 |
| 292 | 308 |
| 293 | 216 |
| 294 | 416 |
| 295 | 271 |
| 296 | 279 |
| 297 | 158 |
| 298 | 337 |
| 299 | 550 |
| 300 | 672 |
| 301 | 118 |
| 302 | 332 |
| 303 | 579 |
| 304 | 540 |
| 305 | 389 |
| 306 | 173 |
| 307 | 121 |
| 308 | 553 |
| 309 | 199 |
| 310 | 784 |
| 311 | 179 |
| 312 | 228 |
| 313 | 338 |
| 314 | 312 |
| 315 | 704 |
| 316 | 390 |
| 317 | 174 |
| 318 | 554 |
| 319 | 581 |
| 320 | 393 |
| 321 | 283 |
| 322 | 122 |
| 323 | 448 |
| 324 | 353 |
| 325 | 561 |
| 326 | 203 |
| 327 | 63 |
| 328 | 340 |
| 329 | 394 |
| 330 | 527 |
| 331 | 582 |
| 332 | 556 |
| 333 | 181 |
| 334 | 295 |
| 335 | 285 |
| 336 | 232 |
| 337 | 124 |
| 338 | 205 |
| 339 | 182 |
| 340 | 643 |
| 341 | 562 |
| 342 | 286 |
| 343 | 585 |
| 344 | 299 |
| 345 | 354 |
| 346 | 211 |
| 347 | 401 |
| 348 | 185 |
| 349 | 396 |
| 350 | 344 |
| 351 | 586 |
| 352 | 645 |
| 353 | 593 |
| 354 | 535 |
| 355 | 240 |
| 356 | 206 |
| 357 | 95 |
| 358 | 327 |
| 359 | 564 |
| 360 | 800 |
| 361 | 402 |
| 362 | 356 |
| 363 | 307 |
| 364 | 301 |
| 365 | 417 |
| 366 | 213 |
| 367 | 568 |
| 368 | 832 |
| 369 | 588 |
| 370 | 186 |
| 371 | 646 |
| 372 | 404 |
| 373 | 227 |
| 374 | 896 |
| 375 | 594 |
| 376 | 418 |
| 377 | 302 |
| 378 | 649 |
| 379 | 771 |
| 380 | 360 |
| 381 | 539 |
| 382 | 111 |
| 383 | 331 |
| 384 | 214 |
| 385 | 309 |
| 386 | 188 |
| 387 | 449 |
| 388 | 217 |
| 389 | 408 |
| 390 | 609 |
| 391 | 596 |
| 392 | 551 |
| 393 | 650 |
| 394 | 229 |
| 395 | 159 |
| 396 | 420 |
| 397 | 310 |
| 398 | 541 |
| 399 | 773 |
| 400 | 610 |
| 401 | 657 |
| 402 | 333 |
| 403 | 119 |
| 404 | 600 |
| 405 | 339 |
| 406 | 218 |
| 407 | 368 |
| 408 | 652 |
| 409 | 230 |
| 410 | 391 |
| 411 | 313 |
| 412 | 450 |
| 413 | 542 |
| 414 | 334 |
| 415 | 233 |
| 416 | 555 |
| 417 | 774 |
| 418 | 175 |
| 419 | 123 |
| 420 | 658 |
| 421 | 612 |
| 422 | 341 |
| 423 | 777 |
| 424 | 220 |
| 425 | 314 |
| 426 | 424 |
| 427 | 395 |
| 428 | 673 |
| 429 | 583 |
| 430 | 355 |
| 431 | 287 |
| 432 | 183 |
| 433 | 234 |
| 434 | 125 |
| 435 | 557 |
| 436 | 660 |
| 437 | 616 |
| 438 | 342 |
| 439 | 316 |
| 440 | 241 |
| 441 | 778 |
| 442 | 563 |
| 443 | 345 |
| 444 | 452 |
| 445 | 397 |
| 446 | 403 |
| 447 | 207 |
| 448 | 674 |
| 449 | 558 |
| 450 | 785 |
| 451 | 432 |
| 452 | 357 |
| 453 | 187 |
| 454 | 236 |
| 455 | 664 |
| 456 | 624 |
| 457 | 587 |
| 458 | 780 |
| 459 | 705 |
| 460 | 126 |
| 461 | 242 |
| 462 | 565 |
| 463 | 398 |
| 464 | 346 |
| 465 | 456 |
| 466 | 358 |
| 467 | 405 |
| 468 | 303 |
| 469 | 569 |
| 470 | 244 |
| 471 | 595 |
| 472 | 189 |
| 473 | 566 |
| 474 | 676 |
| 475 | 361 |
| 476 | 706 |
| 477 | 589 |
| 478 | 215 |
| 479 | 786 |
| 480 | 647 |
| 481 | 348 |
| 482 | 419 |
| 483 | 406 |
| 484 | 464 |
| 485 | 680 |
| 486 | 801 |
| 487 | 362 |
| 488 | 590 |
| 489 | 409 |
| 490 | 570 |
| 491 | 788 |
| 492 | 597 |
| 493 | 572 |
| 494 | 219 |
| 495 | 311 |
| 496 | 708 |
| 497 | 598 |
| 498 | 601 |
| 499 | 651 |
| 500 | 421 |
| 501 | 792 |
| 502 | 802 |
| 503 | 611 |
| 504 | 602 |
| 505 | 410 |
| 506 | 231 |
| 507 | 688 |
| 508 | 653 |
| 509 | 248 |
| 510 | 369 |
| 511 | 190 |
| 512 | 364 |
| 513 | 654 |
| 514 | 659 |
| 515 | 335 |
| 516 | 480 |
| 517 | 315 |
| 518 | 221 |
| 519 | 370 |
| 520 | 613 |
| 521 | 422 |
| 522 | 425 |
| 523 | 451 |
| 524 | 614 |
| 525 | 543 |
| 526 | 235 |
| 527 | 412 |
| 528 | 343 |
| 529 | 372 |
| 530 | 775 |
| 531 | 317 |
| 532 | 222 |
| 533 | 426 |
| 534 | 453 |
| 535 | 237 |
| 536 | 559 |
| 537 | 833 |
| 538 | 804 |
| 539 | 712 |
| 540 | 834 |
| 541 | 661 |
| 542 | 808 |
| 543 | 779 |
| 544 | 617 |
| 545 | 604 |
| 546 | 433 |
| 547 | 720 |
| 548 | 816 |
| 549 | 836 |
| 550 | 347 |
| 551 | 897 |
| 552 | 243 |
| 553 | 662 |
| 554 | 454 |
| 555 | 318 |
| 556 | 675 |
| 557 | 618 |
| 558 | 898 |
| 559 | 781 |
| 560 | 376 |
| 561 | 428 |
| 562 | 665 |
| 563 | 736 |
| 564 | 567 |
| 565 | 840 |
| 566 | 625 |
| 567 | 238 |
| 568 | 359 |
| 569 | 457 |
| 570 | 399 |
| 571 | 787 |
| 572 | 591 |
| 573 | 678 |
| 574 | 434 |
| 575 | 677 |
| 576 | 349 |
| 577 | 245 |
| 578 | 458 |
| 579 | 666 |
| 580 | 620 |
| 581 | 363 |
| 582 | 127 |
| 583 | 191 |
| 584 | 782 |
| 585 | 407 |
| 586 | 436 |
| 587 | 626 |
| 588 | 571 |
| 589 | 465 |
| 590 | 681 |
| 591 | 246 |
| 592 | 707 |
| 593 | 350 |
| 594 | 599 |
| 595 | 668 |
| 596 | 790 |
| 597 | 460 |
| 598 | 249 |
| 599 | 682 |
| 600 | 573 |
| 601 | 411 |
| 602 | 803 |
| 603 | 789 |
| 604 | 709 |
| 605 | 365 |
| 606 | 440 |
| 607 | 628 |
| 608 | 689 |
| 609 | 374 |
| 610 | 423 |
| 611 | 466 |
| 612 | 793 |
| 613 | 250 |
| 614 | 371 |
| 615 | 481 |
| 616 | 574 |
| 617 | 413 |
| 618 | 603 |
| 619 | 366 |
| 620 | 468 |
| 621 | 655 |
| 622 | 900 |
| 623 | 805 |
| 624 | 615 |
| 625 | 684 |
| 626 | 710 |
| 627 | 429 |
| 628 | 794 |
| 629 | 252 |
| 630 | 373 |
| 631 | 605 |
| 632 | 848 |
| 633 | 690 |
| 634 | 713 |
| 635 | 632 |
| 636 | 482 |
| 637 | 806 |
| 638 | 427 |
| 639 | 904 |
| 640 | 414 |
| 641 | 223 |
| 642 | 663 |
| 643 | 692 |
| 644 | 835 |
| 645 | 619 |
| 646 | 472 |
| 647 | 455 |
| 648 | 796 |
| 649 | 809 |
| 650 | 714 |
| 651 | 721 |
| 652 | 837 |
| 653 | 716 |
| 654 | 864 |
| 655 | 810 |
| 656 | 606 |
| 657 | 912 |
| 658 | 722 |
| 659 | 696 |
| 660 | 377 |
| 661 | 435 |
| 662 | 817 |
| 663 | 319 |
| 664 | 621 |
| 665 | 812 |
| 666 | 484 |
| 667 | 430 |
| 668 | 838 |
| 669 | 667 |
| 670 | 488 |
| 671 | 239 |
| 672 | 378 |
| 673 | 459 |
| 674 | 622 |
| 675 | 627 |
| 676 | 437 |
| 677 | 380 |
| 678 | 818 |
| 679 | 461 |
| 680 | 496 |
| 681 | 669 |
| 682 | 679 |
| 683 | 724 |
| 684 | 841 |
| 685 | 629 |
| 686 | 351 |
| 687 | 467 |
| 688 | 438 |
| 689 | 737 |
| 690 | 251 |
| 691 | 462 |
| 692 | 442 |
| 693 | 441 |
| 694 | 469 |
| 695 | 247 |
| 696 | 683 |
| 697 | 842 |
| 698 | 738 |
| 699 | 899 |
| 700 | 670 |
| 701 | 783 |
| 702 | 849 |
| 703 | 820 |
| 704 | 728 |
| 705 | 928 |
| 706 | 791 |
| 707 | 367 |
| 708 | 901 |
| 709 | 630 |
| 710 | 685 |
| 711 | 844 |
| 712 | 633 |
| 713 | 711 |
| 714 | 253 |
| 715 | 691 |
| 716 | 824 |
| 717 | 902 |
| 718 | 686 |
| 719 | 740 |
| 720 | 850 |
| 721 | 375 |
| 722 | 444 |
| 723 | 470 |
| 724 | 483 |
| 725 | 415 |
| 726 | 485 |
| 727 | 905 |
| 728 | 795 |
| 729 | 473 |
| 730 | 634 |
| 731 | 744 |
| 732 | 852 |
| 733 | 960 |
| 734 | 865 |
| 735 | 693 |
| 736 | 797 |
| 737 | 906 |
| 738 | 715 |
| 739 | 807 |
| 740 | 474 |
| 741 | 636 |
| 742 | 694 |
| 743 | 254 |
| 744 | 717 |
| 745 | 575 |
| 746 | 913 |
| 747 | 798 |
| 748 | 811 |
| 749 | 379 |
| 750 | 697 |
| 751 | 431 |
| 752 | 607 |
| 753 | 489 |
| 754 | 866 |
| 755 | 723 |
| 756 | 486 |
| 757 | 908 |
| 758 | 718 |
| 759 | 813 |
| 760 | 476 |
| 761 | 856 |
| 762 | 839 |
| 763 | 725 |
| 764 | 698 |
| 765 | 914 |
| 766 | 752 |
| 767 | 868 |
| 768 | 819 |
| 769 | 814 |
| 770 | 439 |
| 771 | 929 |
| 772 | 490 |
| 773 | 623 |
| 774 | 671 |
| 775 | 739 |
| 776 | 916 |
| 777 | 463 |
| 778 | 843 |
| 779 | 381 |
| 780 | 497 |
| 781 | 930 |
| 782 | 821 |
| 783 | 726 |
| 784 | 961 |
| 785 | 872 |
| 786 | 492 |
| 787 | 631 |
| 788 | 729 |
| 789 | 700 |
| 790 | 443 |
| 791 | 741 |
| 792 | 845 |
| 793 | 920 |
| 794 | 382 |
| 795 | 822 |
| 796 | 851 |
| 797 | 730 |
| 798 | 498 |
| 799 | 880 |
| 800 | 742 |
| 801 | 445 |
| 802 | 471 |
| 803 | 635 |
| 804 | 932 |
| 805 | 687 |
| 806 | 903 |
| 807 | 825 |
| 808 | 500 |
| 809 | 846 |
| 810 | 745 |
| 811 | 826 |
| 812 | 732 |
| 813 | 446 |
| 814 | 962 |
| 815 | 936 |
| 816 | 475 |
| 817 | 853 |
| 818 | 867 |
| 819 | 637 |
| 820 | 907 |
| 821 | 487 |
| 822 | 695 |
| 823 | 746 |
| 824 | 828 |
| 825 | 753 |
| 826 | 854 |
| 827 | 857 |
| 828 | 504 |
| 829 | 799 |
| 830 | 255 |
| 831 | 964 |
| 832 | 909 |
| 833 | 719 |
| 834 | 477 |
| 835 | 915 |
| 836 | 638 |
| 837 | 748 |
| 838 | 944 |
| 839 | 869 |
| 840 | 491 |
| 841 | 699 |
| 842 | 754 |
| 843 | 858 |
| 844 | 478 |
| 845 | 968 |
| 846 | 383 |
| 847 | 910 |
| 848 | 815 |
| 849 | 976 |
| 850 | 870 |
| 851 | 917 |
| 852 | 727 |
| 853 | 493 |
| 854 | 873 |
| 855 | 701 |
| 856 | 931 |
| 857 | 756 |
| 858 | 860 |
| 859 | 499 |
| 860 | 731 |
| 861 | 823 |
| 862 | 922 |
| 863 | 874 |
| 864 | 918 |
| 865 | 502 |
| 866 | 933 |
| 867 | 743 |
| 868 | 760 |
| 869 | 881 |
| 870 | 494 |
| 871 | 702 |
| 872 | 921 |
| 873 | 501 |
| 874 | 876 |
| 875 | 847 |
| 876 | 992 |
| 877 | 447 |
| 878 | 733 |
| 879 | 827 |
| 880 | 934 |
| 881 | 882 |
| 882 | 939 |
| 883 | 963 |
| 884 | 747 |
| 885 | 505 |
| 886 | 855 |
| 887 | 924 |
| 888 | 734 |
| 889 | 829 |
| 890 | 965 |
| 891 | 938 |
| 892 | 884 |
| 893 | 506 |
| 894 | 749 |
| 895 | 945 |
| 896 | 966 |
| 897 | 755 |
| 898 | 859 |
| 899 | 940 |
| 900 | 830 |
| 901 | 911 |
| 902 | 871 |
| 903 | 639 |
| 904 | 888 |
| 905 | 479 |
| 906 | 946 |
| 907 | 750 |
| 908 | 969 |
| 909 | 508 |
| 910 | 861 |
| 911 | 757 |
| 912 | 970 |
| 913 | 919 |
| 914 | 875 |
| 915 | 862 |
| 916 | 758 |
| 917 | 948 |
| 918 | 977 |
| 919 | 923 |
| 920 | 972 |
| 921 | 761 |
| 922 | 877 |
| 923 | 952 |
| 924 | 495 |
| 925 | 703 |
| 926 | 935 |
| 927 | 978 |
| 928 | 883 |
| 929 | 762 |
| 930 | 503 |
| 931 | 925 |
| 932 | 878 |
| 933 | 735 |
| 934 | 993 |
| 935 | 885 |
| 936 | 939 |
| 937 | 994 |
| 938 | 980 |
| 939 | 926 |
| 940 | 764 |
| 941 | 941 |
| 942 | 967 |
| 943 | 886 |
| 944 | 831 |
| 945 | 947 |
| 946 | 507 |
| 947 | 889 |
| 948 | 984 |
| 949 | 751 |
| 950 | 942 |
| 951 | 996 |
| 952 | 971 |
| 953 | 890 |
| 954 | 509 |
| 955 | 949 |
| 956 | 973 |
| 957 | 1000 |
| 958 | 892 |
| 959 | 950 |
| 960 | 863 |
| 961 | 759 |
| 962 | 1008 |
| 963 | 510 |
| 964 | 979 |
| 965 | 953 |
| 966 | 763 |
| 967 | 974 |
| 968 | 954 |
| 969 | 879 |
| 970 | 981 |
| 971 | 982 |
| 972 | 927 |
| 973 | 995 |
| 974 | 765 |
| 975 | 956 |
| 976 | 887 |
| 977 | 985 |
| 978 | 997 |
| 979 | 986 |
| 980 | 943 |
| 981 | 891 |
| 982 | 998 |
| 983 | 766 |
| 984 | 511 |
| 985 | 988 |
| 986 | 1001 |
| 987 | 951 |
| 988 | 1002 |
| 989 | 893 |
| 990 | 975 |
| 991 | 894 |
| 992 | 1009 |
| 993 | 955 |
| 994 | 1004 |
| 995 | 1010 |
| 996 | 957 |
| 997 | 983 |
| 998 | 958 |
| 999 | 987 |
| 1000 | 1012 |
| 1001 | 999 |
| 1002 | 1016 |
| 1003 | 767 |
| 1004 | 989 |
| 1005 | 1003 |
| 1006 | 990 |
| 1007 | 1005 |
| 1008 | 959 |
| 1009 | 1011 |
| 1010 | 1013 |
| 1011 | 895 |
| 1012 | 1006 |
| 1013 | 1014 |
| 1014 | 1017 |
| 1015 | 1018 |
| 1016 | 991 |
| 1017 | 1020 |
| 1018 | 1007 |
| 1019 | 1015 |
| 1020 | 1019 |
| 1021 | 1021 |
| 1022 | 1022 |
| 1023 | 1023 |

The above table shows a Polar sequence Q₀^{Nmax-1} and a reliability W(Qᵢ^{Nmax}) of the Polar sequence. In the above table, W denotes W(Qᵢ^{Nmax}) and I denotes Qᵢ^{Nmax} Namely, the Polar sequence Q₀^{Nmax-1}={Q₀^{Nmax}, Qᵢ^{Nmax}, . . . , Q_{Nmax-1}^{Nmax}} is given by the above table, where 0<=Qᵢ^{Nmax}<=Nmax−1 denotes a bit index (i.e., bit channel index) before Polar encoding for i=0, 1, . . . , Nmax−1. For 3GPP TS 38.212 Rel-15, Nmax=1024. The Polar sequence Q₀^{Nmax-1} is ascending order of reliability W(Q₀^{Nmax})<W(Q₁^{Nmax})< . . . <W(Q_{Nmax-1}^{Nmax}), where W(Qᵢ^{Nmax}) denotes the reliability of bit index Qᵢ^{Nmax} For example, referring to the above table, a reliability W(Qᵢ^{Nmax})=3 of a bit index Qᵢ^{Nmax}=4 is lower than a reliability W(Qᵢ^{Nmax})=7 of bit index Qᵢ^{Nmax}=3 That is, the above table lists, in ascending order of reliability, bit indexes 0 to 1023 which respectively indicate 1024 input positions of a Polar code of Nmax=1024.

For any information block encoded to N bits, a same Polar sequence Q₀^{N-1}={Q₀^{N}, Q₁^{N}, Q₂^{N}, . . . , Q_{N-1}^{N}} is used. The Polar sequence Q₀^{N-1} is a subset of Polar sequence Q₀^{Nmax-1} with all elements Qᵢ^{Nmax} of values less than N, ordered in ascending order of reliability W(Q₀^{N})<W(Q₁^{N})<W(Q₂^{N})< . . . <W(Q_{N-1}^{N}). For example, when N=8, a Polar sequence Q₀⁷ includes elements of Qᵢ^{Nmax}<₈ among elements of the Polar sequence Q₀^{Nmax-1} and the elements of Qᵢ^{Nmax}<8 are ordered in ascending order of reliability W(0)<W(1)<W(2)<W(4)<W(3)<W(5)<W(6).

For example, Table 3 lists input bit positions for an information block of size K (=10) input to a Polar code in a Polar sequence of N=512.

TABLE 3

| | Polar sequence |
|---|---|
| 1 | 505 |
| 2 | 506 |
| 3 | 479 |
| 4 | 508 |
| 5 | 495 |
| 6 | 503 |
| 7 | 507 |
| 8 | 509 |
| 9 | 510 |
| 10 | 511 |

Table 3 shows 10 elements for K=10 among elements of the Polar sequence of N=512 in ascending order of reliability. Referring to the above-described table of <Polar sequence>, values of I having 10 reliabilities W(Qᵢ^{Nmax}) among values of I (=Qᵢ^{Nmax}) less than N=512 are {479, 495, 503, 505, 506, 507, 508, 509, 510, 511}. If {479, 495, 503, 505, 506, 507, 508, 509, 510, 511} are arranged in ascending order of reliability W, {505, 506, 479, 508, 495, 503, 507, 509, 510, 511}, which is a set of bit indexes for K=10 in the Polar sequence of N=512 shown in Table 3, may be obtained.

If the bit sequence input to channel coding is denoted by c₀, c₁, c₂, c₃, . . . , c_{K-1}, the bits after encoding are denoted by d₀, d₁, d₂, d₃, . . . , d_{N-1}, where K is the number of bits to encode, where N=2ⁿ and the value of n is determined by the following table.

TABLE 4

```
If E ≤ (9 / 8)· 2^{(┌log}^{₂} E┐−1) and K / E < 9 / 16
  n₁ =┌log₂ E┐−1;
else
  n₁ =┌log₂ E┐;
end if
Rₘᵢₙ = 1/8;
n₂ =┌log₂(K / Rₘᵢₙ )┐;
n = max{min{n₁,n₂,nₘₐₓ },nₘᵢₙ }
where nₘᵢₙ = 5.
```

In Table 4, nₘₐₓ may be a value predetermined depending on the type of channel or control information and/or the number of information bits input into a channel coding block. For example, nₘₐₓ for a broadcast channel (BCH) may be predetermined as 9, nₘₐₓ for DCI may be predetermined as 9, and nₘₐₓ for UCI may be predetermined as 10.

In Table 4, E denotes a rate matching output sequence length. The rate matching output sequence length E may be predetermined depending on the type of channel, the type of control information, the amount of resources mapped to channel or control information, and/or the number of code blocks used for transmission of control information. For example, the rate matching output sequence length E for a BCH is 864, the rate matching output sequence length E for is 864, and the rate matching output sequence length E for UCI may be predetermined based on the number of OFDM symbols carrying the UCI, the number of RBs, a spreading factor, the number of code blocks for the UCI, and/or the type of UCI included in a UCI payload (e.g., HARQ-ACK, scheduling request (SR), channel state information (CSI), etc.).

For any information block encoded to N bits, a same Polar sequence Q₀^{N-1}={Q₀^{N}, Q₁^{N}, Q₂^{N}, . . . , Q_{N-1}^{N}} is used. The Polar sequence Q₀^{N-1} is a subset of Polar sequence Q₀^{Nmax-1} with all elements Qᵢ^{Nmax} of values less than N, ordered in ascending order of reliability W(Q₀^{N})<W(Q₁^{N})<W(Q₂N)< . . . <W(Q_{N-1}^{N}).

In the NR system, under specific conditions such as when 18<=polar code information size <=25, parity check bits are generated to improve performance (e.g., block error rate (BLER)) when using polar codes. Here, a polar code information size K refers to the number of information bits encoded through polar coding. For example, the sum of code block bits and code block CRC bit(s) may be equivalent to the polar code information size.

FIG. 12 illustrates a method of generating parity check bit(s) used in polar codes.

In some implementations, a parity check (PC) polar code may be used. The PC polar code refers to a polar code that places PC bit(s) generated using a portion of a data block (i.e., information block) in the input of a polar encoder. According to the currently published NR specifications, the PC polar code may be used when the data block size K is within a range of 18<=K<=25. In this case, the number of PC bits is 3, and the PC bits may be generated using a 5-bit shift register as illustrated in FIG. 12. In FIG. 12, the 5-bit shift register, i.e., y[0], y[1], y[2], y[3], and y[4], are all initialized to 0. That is, PC bit(s) may be generated for a data block [u₀, u₁, u₂, . . . , u_{N-1}] as follows.
The register is cyclically shifted to the left.
If uᵢ is an information bit, set y[0]=(uᵢ XOR y[0]),
If uᵢ is a PC bit, set uᵢ=y[0].

The generated PC bit(s) are assigned to input bit channels (i.e., the bit indices of the polar code) of the polar encoder as follows. When E−K+3 >192, n^{wm}_{PC}=1, and when E−K+3<=192, n^{wm}_{PC}=0. In this case, if a set of bit indices for the PC bits is denoted as Q^{N}_{PC}, and if a set of bit indices for other PC bits among Q^{N}_{PC} is denoted as Q^{N}_{PC_wm}, the size of the set Q^{N}_{PC} is |Q^{N}_{PC}|=n_{PC}, and the size of the set Q^{N}_{PC_wm} is |Q^{N}_{PC_wm}|=n^{wm}_{PC}. According to the NR specifications (e.g., 3GPP TS 38.212 Rel-15), Q^{N}_{PC} and Q^{N}_{PC_wm} may be calculated as follows. For a bit index j ranging from 0 to N−1 (i.e., j=0, 1, . . . , N−1), the j-th row of G_{N} is denoted as gⱼ, and the row weight of gⱼ is denoted as w(gⱼ), where w(gⱼ) is the count of ones within gⱼ. In this case, (n_{PC}−n^{wm}_{PC}) PC bits are placed on (n_{PC}−n^{wm}_{PC}) least reliable bit indices in

$${\overline{Q}}_{I}^{N} .$$

In addition, the remaining n^{Wm}_{PC} PC bits are placed on bit indices with the minimum row weight in

$${\overline{Q}}_{I}^{N} , where {\tilde{Q}}_{I}^{N} denotes ( \vert {\overline{Q}}_{I}^{N} \vert - {n}_{PC} )$$

most reliable bit indices. If there are more bit indices with the same minimum row weight in

$${\tilde{Q}}_{I}^{N}$$

than n^{wm}_{PC}, the remaining n^{wm}_{PC} PC bits are placed on n^{wm}_{PC} bit indices with the highest reliability and the minimum row weight in

$${\tilde{Q}}_{I}^{N} .$$

The input to polar encoding, u=[u₀ u₁ u₂ . . . u_{N-1}] may be generated according to Table 5 below.

TABLE 5

```
k = 0;
if n_{PC} > 0
  y₀ = 0; y₁ = 0; y₂ = 0; y₃ = 0; y₄ = 0;
  for a = 0 to N − 1
    y [symbol]   = y₀; y₀ = y₁; y₁ = y₂ = y₃; y₃ = y₄; y₄ = y [symbol]  ;
    $if n ∈ \overline{Q} \text{?}$
      $if n ∈ {Q}_{PC}^{N}$
        uₙ = y₀;
      else
        uₙ = [symbol]   ;
        k = k + 1;
        y₀ = y₀ ⊕ uₙ;
      end if
    else
      uₙ = 0;
    end if
  end for
else
  for n = 0 to N − 1
    $if n ∈ \overline{Q} \text{?}$
      uₙ = [symbol]   ;
      k = k + 1;
    else
      uₙ = 0;
    end if
  end for
end if
```

[symbol]

indicates data missing or illegible when filed

The output after encoding, d=[d₀ d₁ d₂ d₃ . . . d_{N-1}] is obtained from d=uG_{N}, and the encoding is performed by GF(2).

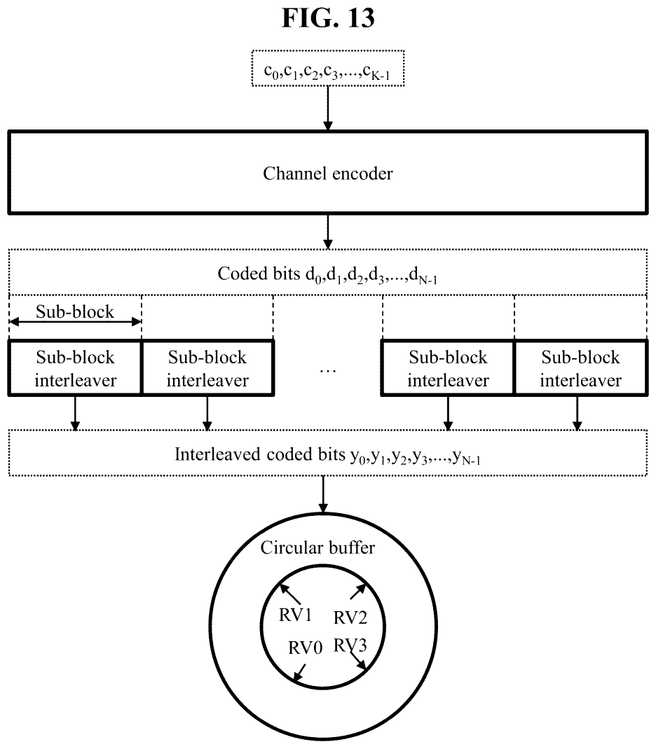

FIG. 13 is a diagram to explain a rate matching process according to some implementations of the present disclosure.

In some implementations, rate matching is performed after channel coding. In the NR specifications, rate matching for polar codes is defined for each code block, and the rate matching consists of sub-block interleaving, bit selection, and bit interleaving. In this specification, an input bit sequence before rate matching may be denoted as d₀, d₁, d₂, d₃, . . . , d_{N-1}, and an output bit sequence after rate matching may be denoted as f₀, f₁, f₂, f₃, . . . , f_{E-1}. Bits input to a sub-block interleaver are coded bits d₀, d₁, d₂, d₃, . . . , d_{N-1}. The coded bits d₀, d₁, d₂, d₃, . . . , d_{N-1} may be divided into 32 sub-blocks. Bits output from the sub-block interleaver may be denoted as y₀, yᵢ, y₂, y₃, . . . , y_{N-1}, which may be generated as follows: for n=0 to N−1: i=floor(32n/N); J(n)=P(i)*(N/32)+mod(n, N/32); yₙ=d_{J(n)}, where a sub-block interleaver pattern P(i) is determined according to Table 6 below.

TABLE 6

| i | P(i) |
|---|---|
| 0 | 0 |
| 1 | 1 |
| 2 | 2 |
| 3 | 4 |
| 4 | 3 |
| 5 | 5 |
| 6 | 6 |
| 7 | 7 |
| 8 | 8 |
| 9 | 16 |
| 10 | 9 |
| 11 | 17 |
| 12 | 10 |
| 13 | 18 |
| 14 | 11 |
| 15 | 19 |
| 16 | 12 |
| 17 | 20 |
| 18 | 13 |
| 19 | 21 |
| 20 | 14 |
| 21 | 22 |
| 22 | 15 |
| 23 | 23 |
| 24 | 24 |
| 25 | 25 |
| 26 | 26 |
| 27 | 28 |
| 28 | 27 |
| 29 | 29 |
| 30 | 30 |
| 31 | 31 |

G_{N}=(G₂)^{⊗}^{ₙ} denotes the n-th Kronecker power of the matrix G₂, where N is 2ⁿ and G₂ is the same as the basic matrix F shown in FIG. 6(b).

In some implementations, the bit sequence y₀, yᵢ, y₂, y₃, . . . , y_{N-1} after the sub-block interleaver is written into a cyclic buffer of length N. If the rate matching output sequence length is denoted as E, a bit selection output bit sequence eₖ (where k=0, 1, 2, . . . , E−1) may be generated as follows.

TABLE 7

```
if E ≥ N -- repetition
  for k = 0 to E − 1
    eₖ = y_{mod(k,N)} ;
  end for
else
  if K / E ≤ 7 / 16 -- puncturing
    for k = 0 to E − 1
      eₖ = y_{k+N-E} ;
    end for
  else -- shortening
    for k = 0 to E − 1
      eₖ = yₖ ;
    end for
  end if
end if
```

Puncturing or shortening is a technique where some of the encoded bits are not transmitted when resources allocated for transmission are not large enough to accommodate all the encoded bits. Repetition is a technique where some of the encoded bits are duplicated and transmitted when resources allocated for transmission are large enough to accommodate all the encoded bits.

Depending on the type of transport channel or control information or depending on the channel coding scheme, a bit sequence e₀, e₁, e₂, . . . , e_{E-1} may be interleaved into the bit sequence f₀, f₁, f₂, f₃, . . . , f_{E-1}. For example, in the case of polar coding for UCI, the bit sequence e₀, e₁, e₂, . . . , e_{E-1} may be interleaved into the bit sequence f₀, f₁, f₂, f₃, . . . , f_{E-1} as follows.

TABLE 8

```
  Denote T as the smallest integer such that T(T + 1)/ 2 ≥ E ;
  k = 0;
  for i = 0 to T − 1
    for j = 0 to T −1 − i
      if k > E
        v_{i,j} = eₖ ;
      else
        v_{i,j} =< NULL >;
      end if
      k = k + 1;
    end for
  end for
  k = 0;
  for j = 0 to T − 1
    for i = 0 to T − 1 − j
      if v_{i,j} ≠< NULL >
        fₖ = v_{i,j};
        k = k + 1
      end if
    end for
  end for
else
  for i = 0 to E − 1
    fⱼ = eᵢ;
  end for
```

A set of bit indices in the polar sequence Q₀^{N-1} is denoted as

$${\overline{Q}}_{I}^{N} ,$$

and a set of other bit indices in the polar sequence Q₀^{N-1} is denoted as

$${\overline{Q}}_{F}^{N} , where \vert {\overline{Q}}_{I}^{N} \vert = K + {n}_{PC ,} \vert {\overline{Q}}_{F}^{N} \vert = N - \vert {\overline{Q}}_{I}^{N} \vert ,$$

and n_{PC} is the number of PC bits. In the present disclosure, |S| denotes the number of elements in a set S.

$${\overline{Q}}_{I}^{N} and {\overline{Q}}_{F}^{N}$$

are given as follows.

TABLE 9

```
${\overline{Q}}_{F , tmp}^{N} = ∅$
if E < N
  if K/E ≤ 7/16 - puncturing
    for n = 0 to N − E − 1
      ${\overline{Q}}_{F , tmp}^{N} = {\overline{Q}}_{F , tmp}^{N} ⋃ \{ J ( n ) \} ;$
    end for
    if E ≥ 3N/4
      ${\overline{Q}}_{F , tmp}^{N} = {\overline{Q}}_{F , tmp}^{N} ⋃ \{ 0 , 1 , … , ⌈ 3 N / 4 - E / 2 ⌉ - 1 \} ;$
    else
      ${\overline{Q}}_{F , tmp}^{N} = {\overline{Q}}_{F , tmp}^{N} ⋃ \{ 0 , 1 , … , ⌈ 9 N / 16 - E / 4 ⌉ - 1 \} ;$
    end if
  else - shortening
    for n = E to N − 1
      ${\overline{Q}}_{F , tmp}^{N} = {\overline{Q}}_{F , tmp}^{N} ⋃ \{ J ( n ) \} ;$
    end for
  end if
end if
$\overline{Q} \text{?} = {Q}_{0}^{N - 1} \backslash {\overline{Q}}_{F , tmp}^{N} ;$
$\overline{Q} \text{?} comprises ( K + {n}_{PC} ) most reliable bit indices in \overline{Q} \text{?} ;$
${\overline{Q}}_{F}^{N} = {Q}_{0}^{N − 1} ∖ \overline{Q} \text{?} ;$
```

$\text{?} \text{indicates text missing or illegible when filed}$

In the present disclosure, A†B denotes the difference of set B from set A, i.e., A−B. In other words, A†B refers to a set of all elements of set A that do not belong to set B.

To improve the performance of polar encoding/decoding, polarization adjusted convolution (PAC) codes that adopt convolution transform as a precoding operation prior to polar transform have been considered. PAC codes may improve the error-correction performance of polar codes by concatenating the convolutional transform with the polar transform.

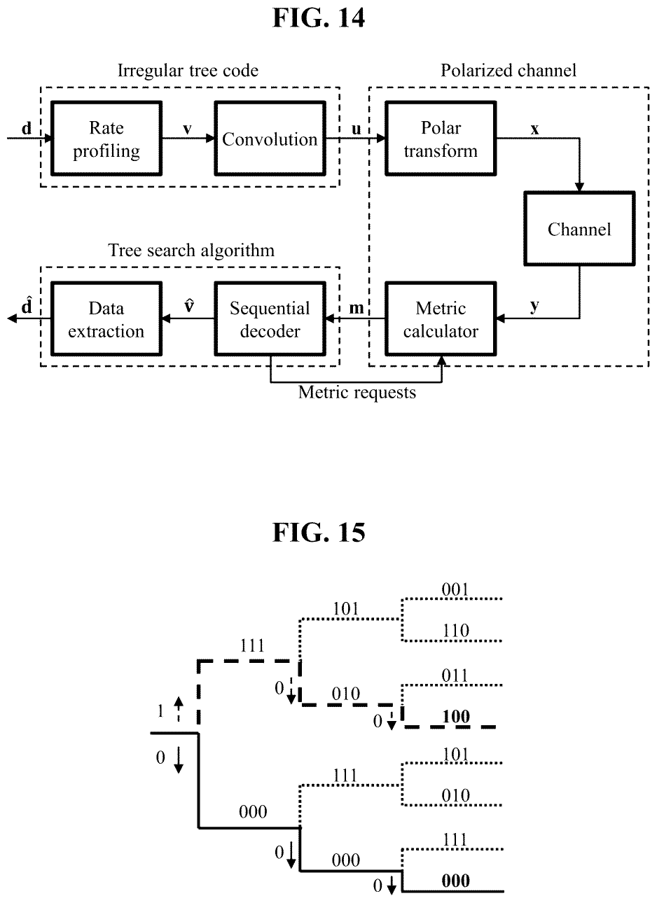

FIG. 14 illustrates one structure of encoders/decoders for PAC codes available for some implementations of the present disclosure.

Referring to FIG. 14, rate profiling in the PAC codes classifies user data into an information set and a frozen set. For example, assuming a PAC code with mother code size N=8, when a user data size K=4, d=[d₀, d₁, d₂, d₃]. In this case, assuming an allocation method of information/frozen bits according to the current NR standard, user data of size K is allocated to K bit channels in the order of bit channels 7, 6, 5, 3, 4, 2, 1, and 0, and thus the information set A={7, 6, 5, 3} and the frozen set A^{c}={4, 2, 1, 0}. The rate profiling maps user data d=[d₀, d₁, d₂, d₃] to v=[v₀, . . . , v₇], where vi is a value mapped to bit channel i. Accordingly, it may be expressed as v=[0, 0, 0, d₁, 0, d₂, d₃, d₄]. A convolution operation is performed by impulse response c=(c₀, . . . , cₘ), where c₀≠0 and cₘ≠0. A parameter m+1 is called a constraint length of convolution. m is a size of a memory used for a convolution, for example, the number of shift registers. Accordingly, an input-output relationship for a convolution with impulse response c=(c₀, . . . , cₘ) is

$${u}_{i} = {Σ}_{j = 0}^{m} {c}_{j} {v}_{i - j} ,$$

where vᵢ₋ⱼ=0 when i=0, . . . , N−1 and j>=i. When this is expressed as a matrix, it may be expressed in the form of an upper triangular matrix as follows.

$$T = [ \begin{matrix}{c}_{0} & {c}_{1} & {c}_{2} & ⋯ & {c}_{m} & 0 & ⋯ & 0 \\ 0 & {c}_{0} & {c}_{1} & {c}_{2} & ⋯ & {c}_{m} & ⋯ & ⋮ \\ 0 & 0 & {c}_{0} & {c}_{1} & {c}_{2} & ⋯ & {c}_{m} & ⋮ \\ ⋮ & 0 & ⋱ & ⋱ & ⋱ & ⋱ & ⋱ & ⋮ \\ ⋮ & ⋮ & ⋱ & ⋱ & ⋱ & ⋱ & 0 & ⋮ \\ ⋮ & ⋮ & ⋱ & ⋱ & 0 & {c}_{0} & {c}_{1} & {c}_{2} \\ ⋮ & ⋮ & ⋱ & ⋱ & 0 & 0 & {c}_{0} & {c}_{1} \\ 0 & ⋯ & ⋯ & ⋯ & ⋯ & 0 & 0 & {c}_{0}\end{matrix} ] \qquad [ Equation 14 ]$$

Polar variant P_{N} of mother code size N represents a polar code kernel matrix as shown in Equation 5. PAC codeword x may be expressed as follows:

κ=vTP_{N}=uP_{N} [Equation 15]

A decoding method of PAC codes may be broadly divided into two types. A first method performs sequential decoding by interpreting the convolution operation and polar transform as convolution encoding with a constraint length N. Sequential decoding is heuristic decoding, and various algorithms are known, and Fano decoding is known as an efficient method (see E. Arikan, “From sequential decoding to channel polarization and back again”).

FIG. 15 illustrates a codeword tree to explain a concept of sequential decoding. In an example of FIG. 15, it is assumed that input data is 100, a codeword resulting from encoding the input data 100 is 111 010 100, and the corresponding reception codeword at a receiver is 001 010 100.

Referring to FIG. 15, sequential decoding may be performed from left to right of a codeword tree. Referring to FIG. 15, for example, a decoder may perform decoding in a direction corresponding to 0 because 000 has a smaller (Hamming) distance value from among possible codewords 111 and 000 for a first codeword part 001 of the reception codeword 001 010 100. The decoder may perform decoding by comparing a second codeword part 010 of the reception codeword 001 010 100 with 111, 000 again to continue decoding in a direction of 0 corresponding to an input of 000, and comparing a third codeword part 100 with 111, 000 again to select 0, thereby obtaining a final value of 000. However, it is an error because the reception codeword is decoded as 000, which is a different value from input data 100. Therefore, it is possible to enable decoding without errors by generate a specific condition to allow a decoder to perform decoding again at a higher node. In the above example, when a first codeword part 001 is decoded, is then branched to the higher node, and decoding in a direction corresponding to 111 instead of 000 is performed, a decoding result of 100 may be obtained.

A brief description of Fano decoding for a convolutional encoder with the number of input bits λ, the number of output bits v, and constraint length L is as follows. When implementing decoding, a path metric may be expressed as follows:

$${Γ}_{l} = {\sum }_{n = 1}^{l} {\sum }_{i = 1}^{ν} ( log \frac{P ( {y}_{n}^{( i )} \vert {x}_{n}^{( i )} )}{w ( {y}_{n}^{( i )} )} - B ) \qquad [ Equation 16 ]$$

Here, l is a depth of a code tree and

$$w ( j ) = {Σ}_{k = 0}^{K - 1} Q ( k ) P ( j \vert k ) ,$$

Q(k) is a relative frequency of k. In this case, update of the path depth may be expressed as follows.

$${Γ}_{l + 1} = {Γ}_{l} + {\sum }_{i = 1}^{v} ( log \frac{P ( {y}_{n}^{( i )} \vert {x}_{n}^{( i )} )}{w ( {y}_{n}^{( i )} )} - B ) \qquad [ Equation 17 ]$$

The following table illustrates the Fano decoding algorithm.

TABLE 10

| | Node Conditions | | Action | |
|---|---|---|---|---|
| | Previous Move | Metric Comparison | Final Threshold | Move |
| 1 | F or L | Γₗ₋₁ < T + δ, Γₗ ≥ T | Raise* | F† |
| 2 | F or L | Γₗ₋₁ ≥ T + δ, Γₗ ≥ T | No change | F† |
| 3 | F or L | Γₗ < T | No change | L or B‡ |
| 4 | B | Γₗ₋₁ < T | Lower by Δ | F† |
| 5 | B | Γₗ₋₁ ≥ T | No change | L or B‡ |

In Table 10, * means adding jδ to a threshold, where j is chosen to satisfy: Γₗ−δ<T+jδ<Γₗ. In Table 10, † means move forward to a first node stemming from the current node. In Table 10, ‡ means moving laterally to a next node that is different from the current node only in the last branch. When the current node is the last, move backward.

A second method performs the SC or SLC decoding described above by interpreting the convolution operation and polar transform as a polar code with precoding T applied. In this case, SC/SCL decoding of PAC codes requires SC/SCL decoder for the existing polar codes, and storage of memory state after performing convolutional re-encoding during a decoding process. This is because in the PAC code, the input of the polar transform is the output of the convolutional encoder.

An example of an SCL decoding algorithm for PAC codes may be expressed as in the following table (Reference: M. Rowshan, A. Burg, and E. Viterbo, “Polarization-adjusted convolutional (PAC) codes: sequential decoding vs list decoding,” IEEE Tr. VT., vol. 70, no. 2, 2021).

TABLE 11

| $input : channel LLRs λ \text{?} , ℬ , L , g$ | |
|---|---|
| output: recovered message bits \hat{d} | |
| [symbol] ← {1} / / a single path in the list | |
| $[ λ , β ] ← [ λ \text{?} + \{ 0 \} , \{ 0 \} ]$ | |
| for i ← 0 to N − 1 do | |
| \| if i ∉ [symbol] then | |
| \| \| for l ← 1 to \| [symbol] \| do | |
| \| \| \| ${λ}_{0}^{i} [ l ] ← updateLLRs ( l , i , λ [ l ] , β [ l ] )$ | |
| \| \| \| \hat{v}ᵢ[l] ← 0 | |
| \| \| \| [ûᵢ][l], cState[l]] ← conv1bTrans(vᵢ, cState[l], g) | |
| \| \| \| $P {M}_{l}^{( i )} ← calcPM ( P {M}_{l}^{( i − 1 )} , {λ}_{0}^{i} [ l ] , {\hat{u}}_{i} [ l ] )$ | |
| \| \| └ β[l] ← updatePartialSums(ûᵢ[l], β[l]) | |
| \| else | |
| \| \| for l + 1 to \| [symbol] \| do | |
| \| \| └ [symbol] ← duplicatePath( [symbol] , l, i, g) | |
| \| \| If \| [symbol] \| > 1 then | |
| \| └ \| [symbol] ← prunePaths( C) | |
| └ | |
| $\hat{d} ← extractData ( \text{?} [ 0 ] )$ | |
| return \hat{d}; | |
| input: profiled information bits v, g | |
| outputs: the codeword x | |
| u ← convTrans(v, g) | |
| x ← polarTrans(u) | // Like polar encoder |
| return x; | |
| subroutine convTrans (v, g): | |
| \| cState[1, ... , \|g\| − 1] + [0 .... , 0] // currstate | |
| \| for i ← 0 to \|v\| − 1 do | |
| \| └ (uᵢ, cState) ← conv1bTrans(v), cState, g) | |
| └ return u; | |
| subroutine conv1bTrans (v, currState, g): | |
| \| u ← v · g₀ | |
| \| for j ← 1 to \|g\| do | |
| \| \| if gⱼ = 1 then | |
| \| └ \| u ← u ⊕ currState[j − 1] | |
| \| nextState ← [vᵢ] + currState[1, ... , \|g\| − 2] | |
| └ return (u, nextState): | |
| subroutine duplicatePath ( [symbol] , l, i, g): | |
| \| [symbol] ← [symbol] ∪ {l′} | // path l' is a copy of path l |

| ${λ}_{0}^{i} [ l ] ← updateLLRs ( l , i , λ [ l ] , β [ l ] )$
| (\hat{v}ᵢ[l], \hat{v}ᵢ[l′]) ← (0, 1)
| [ûᵢ[l], cState[l]] ← conv1bTrans(\hat{v}ᵢ[l], cState[l], g)
| [ûᵢ[l′], cState[l′]] ← conv1bTrans(\hat{v}ᵢ[l′], cState[l], g)
| $P {M}_{l}^{( i )} ← calcPM ( P {M}_{l}^{( i − 1 )} , {λ}_{0}^{i} [ l ] , {\hat{u}}_{i} [ l ] )$
| $P {M}_{{l}^{′}}^{( i )} ← calcPM ( P {M}_{l}^{( i − 1 )} , {λ}_{0}^{i} [ l ] , {\hat{u}}_{i} [ {l}^{′} ] )$
| β[l] ← updatePartialSums(ûᵢ[l], β[l])
| β[l′] ← updatePartialSums(ûᵢ[l], β[l])
└ return [symbol] ;
subroutine calcPM (PM, λ₀, û) ;
| $if \hat{u} = \frac{1}{2} ( 1 - sgn ( {λ}_{0} ) ) then$
| | PM = PM
| else
| └ PM = PM + |λ₀|
└ return PM;
$\text{?} \text{indicates text missing or illegible when filed}$

When PAC codes as in FIG. 14 are generalized a little more, it may be interpreted as precoding in which the convolution operation matrix T is in the form of an upper triangular matrix. It is known that these precoded polar codes may have improved minimum distance characteristics compared to non-precoded polar codes.

Hereinafter, design method(s) of PAC codes and PAC code(s) obtained using the corresponding design method(s) according to some implementations of the present disclosure are described. For example, with reference to a PAC system of FIG. 14, convolution operations and rate profiles according to some implementations of the present disclosure are described.

### <Design for Convolution Operation>

For the convolution operation, impulse response c=(c₀, . . . , cₘ) needs to be designed. In this case, the design of the impulse response may be divided into the design of cᵢ, i=0, . . . , m and the design of constraint length m+1.

By the rate profile operation of FIG. 14, bits of user data are located in input bit channels of convolution through information/frozen bit(s) allocation.

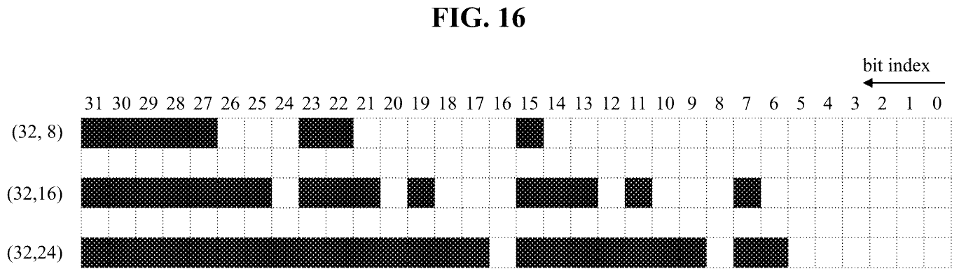

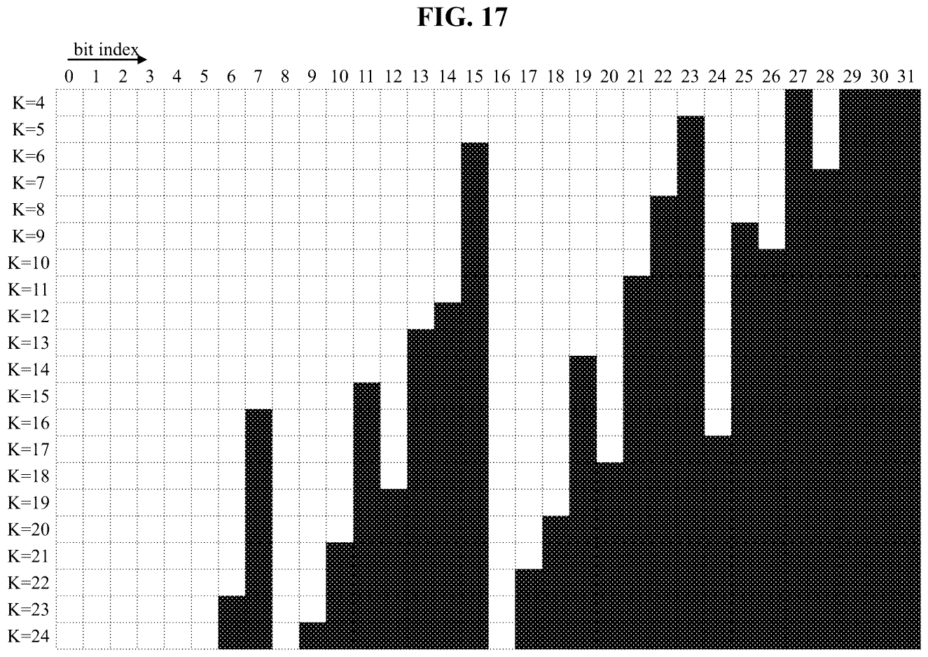

FIGS. 16 and 17 illustrate the results of a rate profile operation for a mother code size. In particular, FIG. 16 shows the results of the rate profile operation to which the information/frozen allocation scheme defined in the NR standard to date is applied, for mother code size N=32 and information sizes K=8, 16, and 24. User data is located at bit index(es) corresponding to a shaded portion in FIG. 16. Hereinafter, an index of the bit channel to which a bit of user data, i.e., an information bit, is allocated is called an information bit index.

The number of frozen bits between bit indices assigned to information (i.e., user data) and the constraint length may affect error protection. For example, when the constraint length is less than the number of information bits located between the information bit indices, the output of the convolution operation is 0. This makes the information bits assigned to the corresponding bit indices more susceptible to errors than other bits. Therefore, this may lead to a problem that the probability of error occurrence is not the same depending on the location of user data. To resolve this problem, the constraint length of the convolution operation may be determined to be larger than the number of frozen bits located between the information bits located as a result of the rate profile. For example, in the case of the PAC code (32, 8) in the examples of FIG. 16, the maximum number of frozen bits located between consecutive information bit indices is 6, and thus it may be preferable that the constraint length is configured to be a value greater than 6.

In the case of polar codes, information sizes obtained by starting from an information size corresponding to the minimum code rate (i.e., the minimum number of information bits) and increasing by 1 bit need to be supported. Referring to FIG. 17, FIG. 17 shows the result of a rate profile operation to which the information/prototype bit allocation method of the current NR standard when a mother code size N=32. FIG. 17 shows the number of frozen bits located between information bits of a PAC code supporting various information sizes. In the example of FIG. 17, the minimum coding rate is assumed to be ⅛. As illustrated in FIG. 17, when polar codes support various information sizes, if the constraint length is determined to be greater than the maximum number of frozen bits located between the information bits, the information bits may have the same error occurrence probability. For example, in the example of FIG. 17, the maximum number of frozen bits located between information bits is 7, and thus it may be preferable that the constraint length is configured to be a value greater than or equal to 8.

Like polar codes, PAC codes may also support various mother code sizes. The following table shows the maximum numbers of frozen bits located between information bits for various mother code sizes when applying the information/frozen bit allocation scheme of the current NR standard (e.g. 3GPP TS 38.212 Rel-15). In this case, the minimum coding rate is assumed to be ⅛.

TABLE 12

| | Maximum number of frozen bits located |
|---|---|
| Mother code size | between information bits |
| 32 | 7 |
| 64 | 15 |
| 128 | 31 |
| 256 | 59 |
| 512 | 95 |
| 1024 | 127 |

In some implementations of the present disclosure, the constraint length for the convolution operation of PAC codes supporting various mother code sizes may be determined as follows.
Method 1: The constraint length is determined based on the mother code size. In this case, a value greater than the maximum number of frozen bits located between the information bits according to the mother code size may be determined or configured as the constraint length. For example, referring to Table 12, constraint lengths greater than or equal to 8, 16, 32, 60, 96, and 128 may be determined/configured for mother code sizes N=32, 64, 128, 256, 512, and 1024, respectively.
   Method 1-1: Mother code sizes may be grouped into multiple mother code size groups, and the constraint length may be determined or configured for each mother code size group. In this case, a value greater than the maximum number of frozen bits located between information bits for the maximum mother code size within the mother code size group is configured as the constraint length. For example, for the mother code size groups {32, 64}, {128, 256}, and {512, 1024} obtained by sequentially grouping the mother code sizes in Table 12 into groups of two, values greater than or equal to 16, 60, and 128 may be determined/configured as constraint lengths, respectively.
Method 2: The same constraint length may be determined/configured for all mother code sizes supported by PAC codes. In this case, a value greater than the maximum number of frozen bits located between the information bits according to the supported maximum mother code size may be determined/configured as the constraint length. For example, referring to Table 12, the maximum mother code size is 1024, and thus a value greater than 127 may be determined/configured as the constraint length. In some implementations, there may be cases in which the constraint length determined/configured is greater than the mother code size, and in this regard, a constraint length greater than the mother code size is meaningless, and thus for some mother code sizes (e.g., mother code sizes less than the constraint length determined based on 1024), a value smaller less the mother code size may be determined/configured as the constraint length. For example, the mother code sizes N=32, 64, and 128 are less than the constraint length values determined/configured to be greater than 127, and thus constraint length(s) less than 32, 64, and 128 may be determined/configured, respectively.

The methods 1 and 2 described above may be applied to a case in which there is no feedback in the convolution operation, i.e., a non-recursive convolution operation. As seen from Table 12, as the mother code size increases, the constraint length also increases, which increases the amount of memory required for actual implementation. Therefore, the convolution operation may be implemented with a relatively small memory size by applying recursive convolution to PAC codes.

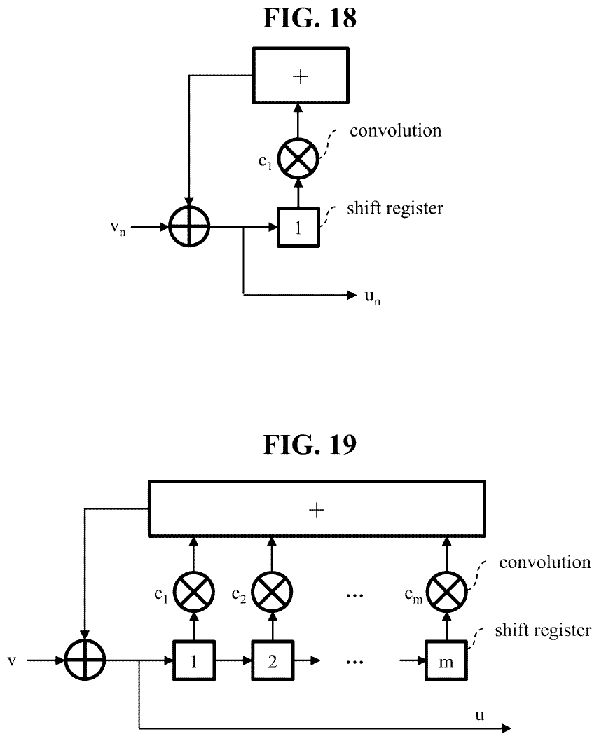

FIGS. 18 and 19 illustrate a recursive convolution operation. In particular, FIG. 18 illustrates a recursive convolution in which the number of shift registers is 1, i.e., the constraint length is 2, and FIG. 19 illustrates a recursive convolution in which the number of shift registers is m, i.e., the constraint length is m+1.

Referring to FIG. 18, uₙ may be determined by adding a convolution of uₙ₋₁ and c₁ stored in shift register 1 to vₙ. In FIG. 18, when c₁ is 0, the result of the convolution is always 0, and thus there is no constraint, which is the same as a case in which the convolution is not applied. Accordingly, c₁ may be 1 in the example of FIG. 18, and thus the recursive convolution operation of FIG. 18 may be expressed as uₙ=vₙ+uₙ₋₁.

FIG. 19 illustrates a recursive convolution operation with a constraint length of m+1. The output v=[v₁, v₂, . . . , v_{N}] obtained by performing a recursive convolution operation as in FIG. 19 on the input u=[u₁, u₂, . . . , u_{N}] of PAC codes with a mother code size N may be expressed as

$${u}_{n} = {ν}_{n} + {Σ}_{k = 1}^{m} {c}_{k} {u}_{n - k} .$$

For example, assuming mother code size N=16, information size K=5, and a rate profile according to information/frozen bit allocation method of the current NR standard, v=[0, 0, 0, 0, 0, 0, 0, d₀, 0, 0, 0, d₁, 0, d₂, d₃, d₄]. Assuming a recursive convolution operation uₙ=vₙ+uₙ₋₁ in which a memory size is 1, for example, the number of shift registers is 1, the output of the convolution operation is u=[0, 0, 0, 0, 0, 0, 0, d₀, d₀, d₀, d₀, d₀+d₁, d₀+d₁, d₀+d₁+d₂, d₀+d₁+d₂+d₃, d₀+d₁+d₂+d₃+d₄]. Therefore, for a mother code size N=16 and an information size K=5, the maximum number of frozen bits located between information bits is 3, and even if the constraint length is determined/configured to a value less than 3, the same error occurrence probability may be obtained between the information bits because there are no bits to which the convolution operation is not applied.

Even if a recursive convolution operation is introduced into the PAC code, a re-encoding operation and memory state storage operation required when performing SC/SCL decoding may be performed in the same manner.

### <Rate Profile>

A rate profile operation locates user data at bit index(es) by using a reference such as reliability. To this end, the information/frozen bit allocation method of polar codes may be applied. According to the paper “From sequential decoding to channel polarization and back again” of Arikan, when the Reed-Muller (RM) rate profile is used, higher capacity than the polar code rate profile for binary input AWGN channels may be obtained. In some implementations of the present disclosure, the polar code rate profile may be subject to a reliability ordering derived using the Battahcaryya parameter of Equation 13. The RM rate profile determines a reliability order in descending order of weight, which corresponds to the number of is when a bit index is expressed in binary. However, when supporting various information sizes, the reliability order of bit indices with the same weight needs to be determined. In this case, a partial order (PO) method that utilizes definition of stochastic degradation of bit indices may be applied (see: C. Schurch, “A partial order for the synthesized channels of a polar code”).

W₁ and W₂ may be uniform binary input channels, and a transmission system in which X₁→Y₁ through W₁ and X₂→Y₂ through W₂ may be assumed. In the transmission system, when there are probability distributions P(y₁|y₂) satisfying a relationship p(y₁|x)=Σ_{y}_{₂}P(y₁|y₂)p(Y₂|x), W₁ is defined as stochastically degraded with respect to W₂ and is denoted as W₁≤W₂. When the relationship W₁≤W₂ is satisfied, I(W₁)<=I(W₂), Pe(W₁)>=Pₑ(W₂). That is, when information is transmitted through W₂, a low error rate or transmission of a larger amount of information may be obtained. Therefore, when the stochastic degradation relationship between bit channels of the polar code is obtained, the reliability order of the bit channels of the polar code may be obtained. The following are examples of methods of obtaining stochastic degradation relationships between bit channels. Binary representation of bit channels i and j is i=(iₙ₋₁, . . . , and i₀) and j=(jₙ₋₁, . . . , and j₀).

PO1 may be explained as follows. When binary representation for bit channel j is to be obtained by swapping 1 in an upper position with 0 in a lower position in binary representation for bit channel i, bit channel j may be represented to be stochastically degraded with respect to bit channel i. For example, for a mother code size of 16, when a positions of the second 1 and the third 0 of ‘1100’ are swapped, such as i=12=(1100) and j=10=(1010), the result is ‘1010’. Thus, 10 and 12 satisfy a relationship of W₁₆⁽¹⁰⁾≤W₁₆⁽¹²⁾.

PO2 may be explained as follows. When bits at each position in the binary representation of bit channel i are greater than or equal to bits at each position in the binary representation of bit channel j, bit channel j may be expressed as being stochastically degraded with respect to bit channel i. For example, for mother code size 16, bits for each position of ‘1110’ are greater than or equal to bits for each position of ‘1100’ like i=14=(1110) and j=12=(1100). Thus, 12 and 14 satisfy a relationship of W₁₆⁽¹²⁾≤W₁₆⁽¹⁴⁾.

The following table illustrates a procedure of determining a rate profile by combining a weight of a bit index and a PO.

TABLE 13

| | |
|---|---|
| 1. Initialize | Mother code size N |
| 2. | Represent bit index in binary and find weight |
| | W = {0,1,...,n}: set of weight |
| | Gⱼ = {Bⱼ₁,Bⱼ₂,...,Bⱼₘ_{ⱼ}} : set of bit indices of weight j, |
| | where 0 ≤ j ≤ n and mⱼ is the number of elements of Gⱼ |
| 3. | For k=n to 0 |
| | Set reliability order for Gₖ according to PO |
| | Rₖ = {Rₖ₁,Rₖ₂,...,Rₖₘ_{ₖ} } where |
| | Rₖₘ_{ₖ} ≤ ··· ≤ Rₖ₂ ≤ Rₖ₁ |
| 4. | Find reliability order for all bit indices as follows: |
| | Rₙ₁,Rₙ₂,...,Rₙₘ_{ₙ},...,R₁₁,R₁₂,...,R₁ₘ_{₁},R₀₁,R₀₂,...,R₀ₘ_{₀} |

When the polar sequence Q^{N-1}₀={Q₀, Q₁, . . . , Q_{N-1}} with a length N is determined according to Table 13, the reliability of the bit indices of the polar sequence Q^{N-1}₀={Q₀, Q₁, . . . , Q_{N-1}} increases as the number of is increases when expressed in binary, and the bit indices Q^{N}ₓ and Q^{N}_{y} having the same number of is when expressed in binary satisfy W(Q^{N}ₓ)<W(Q^{N}_{y}) for Q^{N}ₓ<Q^{N}_{y}.

The following table shows a weight of a bit index for mother code size N=16. In the example in the following table, the bit indices, listed in order of weight, are 15, {7, 11, 13, 14}, {3, 5, 6, 9, 10, 12}, {1, 2, 4, 8}, and 0, where the bit indices within { } have the same weight value. Therefore, when the reliability order of weight indices with the same weight is obtained using a PO, the reliability order is 14, 13, 11, 7 in the case of a weight of 3, the reliability order is 12, 10, 9, 6, 5, 3 in the case of a weight of 2, and the reliability order is 8, 4, 2, 1 in the case of a weight of 1. A final reliability order of the bit indices, determined by combining weights of the bit indices and the PO, is 15, 14, 13, 11, 7, 12, 10, 9, 6, 5, 3, 8, 4, 2, 1, and 0.

TABLE 14

| Bit index | Binary | Weight |
|---|---|---|
| 0 | 0000 | 0 |
| 1 | 0001 | 1 |
| 2 | 0010 | 1 |
| 3 | 0011 | 2 |
| 4 | 0100 | 1 |
| 5 | 0101 | 2 |
| 6 | 0110 | 2 |
| 7 | 0111 | 3 |
| 8 | 1000 | 1 |
| 9 | 1001 | 2 |
| 10 | 1010 | 2 |
| 11 | 1011 | 3 |
| 12 | 1100 | 2 |
| 13 | 1101 | 3 |
| 14 | 1110 | 3 |
| 15 | 1111 | 4 |

A reliability order of bit indices may also be determined for larger mother code sizes by using the same method. When a reliability order of bit indices is determined in this way, excellent performance in terms of a minimum distance may be obtained, making it effective for applications requiring a low error rate.

The following W₄₀₉₆ is a list of bit indices 0 to 4095 in ascending order of reliability determined by considering the weight of the bit index and PO when mother code size N=4096.

W₄₀₉₆=[0, 1, 2, 4, 8, 16, 32, 64, 128, 256, 512, 1024, 2048, 3, 5, 6, 9, 10, 12, 17, 18, 20, 24, 33, 34, 36, 40, 48, 65, 66, 68, 72, 80, 96, 129, 130, 132, 136, 144, 160, 192, 257, 258, 260, 264, 272, 288, 320, 384, 513, 514, 516, 520, 528, 544, 576, 640, 768, 1025, 1026, 1028, 1032, 1040, 1056, 1088, 1152, 1280, 1536, 2049, 2050, 2052, 2056, 2064, 2080, 2112, 2176, 2304, 2560, 3072, 7, 11, 13, 14, 19, 21, 22, 25, 26, 28, 35, 37, 38, 41, 42, 44, 49, 50, 52, 56, 67, 69, 70, 73, 74, 76, 81, 82, 84, 88, 97, 98, 100, 104, 112, 131, 133, 134, 137, 138, 140, 145, 146, 148, 152, 161, 162, 164, 168, 176, 193, 194, 196, 200, 208, 224, 259, 261, 262, 265, 266, 268, 273, 274, 276, 280, 289, 290, 292, 296, 304, 321, 322, 324, 328, 336, 352, 385, 386, 388, 392, 400, 416, 448, 515, 517, 518, 521, 522, 524, 529, 530, 532, 536, 545, 546, 548, 552, 560, 577, 578, 580, 584, 592, 608, 641, 642, 644, 648, 656, 672, 704, 769, 770, 772, 776, 784, 800, 832, 896, 1027, 1029, 1030, 1033, 1034, 1036, 1041, 1042, 1044, 1048, 1057, 1058, 1060, 1064, 1072, 1089, 1090, 1092, 1096, 1104, 1120, 1153, 1154, 1156, 1160, 1168, 1184, 1216, 1281, 1282, 1284, 1288, 1296, 1312, 1344, 1408, 1537, 1538, 1540, 1544, 1552, 1568, 1600, 1664, 1792, 2051, 2053, 2054, 2057, 2058, 2060, 2065, 2066, 2068, 2072, 2081, 2082, 2084, 2088, 2096, 2113, 2114, 2116, 2120, 2128, 2144, 2177, 2178, 2180, 2184, 2192, 2208, 2240, 2305, 2306, 2308, 2312, 2320, 2336, 2368, 2432, 2561, 2562, 2564, 2568, 2576, 2592, 2624, 2688, 2816, 3073, 3074, 3076, 3080, 3088, 3104, 3136, 3200, 3328, 3584, 15, 23, 27, 29, 30, 39, 43, 45, 46, 51, 53, 54, 57, 58, 60, 71, 75, 77, 78, 83, 85, 86, 89, 90, 92, 99, 101, 102, 105, 106, 108, 113, 114, 116, 120, 135, 139, 141, 142, 147, 149, 150, 153, 154, 156, 163, 165, 166, 169, 170, 172, 177, 178, 180, 184, 195, 197, 198, 201, 202, 204, 209, 210, 212, 216, 225, 226, 228, 232, 240, 263, 267, 269, 270, 275, 277, 278, 281, 282, 284, 291, 293, 294, 297, 298, 300, 305, 306, 308, 312, 323, 325, 326, 329, 330, 332, 337, 338, 340, 344, 353, 354, 356, 360, 368, 387, 389, 390, 393, 394, 396, 401, 402, 404, 408, 417, 418, 420, 424, 432, 449, 450, 452, 456, 464, 480, 519, 523, 525, 526, 531, 533, 534, 537, 538, 540, 547, 549, 550, 553, 554, 556, 561, 562, 564, 568, 579, 581, 582, 585, 586, 588, 593, 594, 596, 600, 609, 610, 612, 616, 624, 643, 645, 646, 649, 650, 652, 657, 658, 660, 664, 673, 674, 676, 680, 688, 705, 706, 708, 712, 720, 736, 771, 773, 774, 777, 778, 780, 785, 786, 788, 792, 801, 802, 804, 808, 816, 833, 834, 836, 840, 848, 864, 897, 898, 900, 904, 912, 928, 960, 1031, 1035, 1037, 1038, 1043, 1045, 1046, 1049, 1050, 1052, 1059, 1061, 1062, 1065, 1066, 1068, 1073, 1074, 1076, 1080, 1091, 1093, 1094, 1097, 1098, 1100, 1105, 1106, 1108, 1112, 1121, 1122, 1124, 1128, 1136, 1155, 1157, 1158, 1161, 1162, 1164, 1169, 1170, 1172, 1176, 1185, 1186, 1188, 1192, 1200, 1217, 1218, 1220, 1224, 1232, 1248, 1283, 1285, 1286, 1289, 1290, 1292, 1297, 1298, 1300, 1304, 1313, 1314, 1316, 1320, 1328, 1345, 1346, 1348, 1352, 1360, 1376, 1409, 1410, 1412, 1416, 1424, 1440, 1472, 1539, 1541, 1542, 1545, 1546, 1548, 1553, 1554, 1556, 1560, 1569, 1570, 1572, 1576, 1584, 1601, 1602, 1604, 1608, 1616, 1632, 1665, 1666, 1668, 1672, 1680, 1696, 1728, 1793, 1794, 1796, 1800, 1808, 1824, 1856, 1920, 2055, 2059, 2061, 2062, 2067, 2069, 2070, 2073, 2074, 2076, 2083, 2085, 2086, 2089, 2090, 2092, 2097, 2098, 2100, 2104, 2115, 2117, 2118, 2121, 2122, 2124, 2129, 2130, 2132, 2136, 2145, 2146, 2148, 2152, 2160, 2179, 2181, 2182, 2185, 2186, 2188, 2193, 2194, 2196, 2200, 2209, 2210, 2212, 2216, 2224, 2241, 2242, 2244, 2248, 2256, 2272, 2307, 2309, 2310, 2313, 2314, 2316, 2321, 2322, 2324, 2328, 2337, 2338, 2340, 2344, 2352, 2369, 2370, 2372, 2376, 2384, 2400, 2433, 2434, 2436, 2440, 2448, 2464, 2496, 2563, 2565, 2566, 2569, 2570, 2572, 2577, 2578, 2580, 2584, 2593, 2594, 2596, 2600, 2608, 2625, 2626, 2628, 2632, 2640, 2656, 2689, 2690, 2692, 2696, 2704, 2720, 2752, 2817, 2818, 2820, 2824, 2832, 2848, 2880, 2944, 3075, 3077, 3078, 3081, 3082, 3084, 3089, 3090, 3092, 3096, 3105, 3106, 3108, 3112, 3120, 3137, 3138, 3140, 3144, 3152, 3168, 3201, 3202, 3204, 3208, 3216, 3232, 3264, 3329, 3330, 3332, 3336, 3344, 3360, 3392, 3456, 3585, 3586, 3588, 3592, 3600, 3616, 3648, 3712, 3840, 31, 47, 55, 59, 61, 62, 79, 87, 91, 93, 94, 103, 107, 109, 110, 115, 117, 118, 121, 122, 124, 143, 151, 155, 157, 158, 167, 171, 173, 174, 179, 181, 182, 185, 186, 188, 199, 203, 205, 206, 211, 213, 214, 217, 218, 220, 227, 229, 230, 233, 234, 236, 241, 242, 244, 248, 271, 279, 283, 285, 286, 295, 299, 301, 302, 307, 309, 310, 313, 314, 316, 327, 331, 333, 334, 339, 341, 342, 345, 346, 348, 355, 357, 358, 361, 362, 364, 369, 370, 372, 376, 391, 395, 397, 398, 403, 405, 406, 409, 410, 412, 419, 421, 422, 425, 426, 428, 433, 434, 436, 440, 451, 453, 454, 457, 458, 460, 465, 466, 468, 472, 481, 482, 484, 488, 496, 527, 535, 539, 541, 542, 551, 555, 557, 558, 563, 565, 566, 569, 570, 572, 583, 587, 589, 590, 595, 597, 598, 601, 602, 604, 611, 613, 614, 617, 618, 620, 625, 626, 628, 632, 647, 651, 653, 654, 659, 661, 662, 665, 666, 668, 675, 677, 678, 681, 682, 684, 689, 690, 692, 696, 707, 709, 710, 713, 714, 716, 721, 722, 724, 728, 737, 738, 740, 744, 752, 775, 779, 781, 782, 787, 789, 790, 793, 794, 796, 803, 805, 806, 809, 810, 812, 817, 818, 820, 824, 835, 837, 838, 841, 842, 844, 849, 850, 852, 856, 865, 866, 868, 872, 880, 899, 901, 902, 905, 906, 908, 913, 914, 916, 920, 929, 930, 932, 936, 944, 961, 962, 964, 968, 976, 992, 1039, 1047, 1051, 1053, 1054, 1063, 1067, 1069, 1070, 1075, 1077, 1078, 1081, 1082, 1084, 1095, 1099, 1101, 1102, 1107, 1109, 1110, 1113, 1114, 1116, 1123, 1125, 1126, 1129, 1130, 1132, 1137, 1138, 1140, 1144, 1159, 1163, 1165, 1166, 1171, 1173, 1174, 1177, 1178, 1180, 1187, 1189, 1190, 1193, 1194, 1196, 1201, 1202, 1204, 1208, 1219, 1221, 1222, 1225, 1226, 1228, 1233, 1234, 1236, 1240, 1249, 1250, 1252, 1256, 1264, 1287, 1291, 1293, 1294, 1299, 1301, 1302, 1305, 1306, 1308, 1315, 1317, 1318, 1321, 1322, 1324, 1329, 1330, 1332, 1336, 1347, 1349, 1350, 1353, 1354, 1356, 1361, 1362, 1364, 1368, 1377, 1378, 1380, 1384, 1392, 1411, 1413, 1414, 1417, 1418, 1420, 1425, 1426, 1428, 1432, 1441, 1442, 1444, 1448, 1456, 1473, 1474, 1476, 1480, 1488, 1504, 1543, 1547, 1549, 1550, 1555, 1557, 1558, 1561, 1562, 1564, 1571, 1573, 1574, 1577, 1578, 1580, 1585, 1586, 1588, 1592, 1603, 1605, 1606, 1609, 1610, 1612, 1617, 1618, 1620, 1624, 1633, 1634, 1636, 1640, 1648, 1667, 1669, 1670, 1673, 1674, 1676, 1681, 1682, 1684, 1688, 1697, 1698, 1700, 1704, 1712, 1729, 1730, 1732, 1736, 1744, 1760, 1795, 1797, 1798, 1801, 1802, 1804, 1809, 1810, 1812, 1816, 1825, 1826, 1828, 1832, 1840, 1857, 1858, 1860, 1864, 1872, 1888, 1921, 1922, 1924, 1928, 1936, 1952, 1984, 2063, 2071, 2075, 2077, 2078, 2087, 2091, 2093, 2094, 2099, 2101, 2102, 2105, 2106, 2108, 2119, 2123, 2125, 2126, 2131, 2133, 2134, 2137, 2138, 2140, 2147, 2149, 2150, 2153, 2154, 2156, 2161, 2162, 2164, 2168, 2183, 2187, 2189, 2190, 2195, 2197, 2198, 2201, 2202, 2204, 2211, 2213, 2214, 2217, 2218, 2220, 2225, 2226, 2228, 2232, 2243, 2245, 2246, 2249, 2250, 2252, 2257, 2258, 2260, 2264, 2273, 2274, 2276, 2280, 2288, 2311, 2315, 2317, 2318, 2323, 2325, 2326, 2329, 2330, 2332, 2339, 2341, 2342, 2345, 2346, 2348, 2353, 2354, 2356, 2360, 2371, 2373, 2374, 2377, 2378, 2380, 2385, 2386, 2388, 2392, 2401, 2402, 2404, 2408, 2416, 2435, 2437, 2438, 2441, 2442, 2444, 2449, 2450, 2452, 2456, 2465, 2466, 2468, 2472, 2480, 2497, 2498, 2500, 2504, 2512, 2528, 2567, 2571, 2573, 2574, 2579, 2581, 2582, 2585, 2586, 2588, 2595, 2597, 2598, 2601, 2602, 2604, 2609, 2610, 2612, 2616, 2627, 2629, 2630, 2633, 2634, 2636, 2641, 2642, 2644, 2648, 2657, 2658, 2660, 2664, 2672, 2691, 2693, 2694, 2697, 2698, 2700, 2705, 2706, 2708, 2712, 2721, 2722, 2724, 2728, 2736, 2753, 2754, 2756, 2760, 2768, 2784, 2819, 2821, 2822, 2825, 2826, 2828, 2833, 2834, 2836, 2840, 2849, 2850, 2852, 2856, 2864, 2881, 2882, 2884, 2888, 2896, 2912, 2945, 2946, 2948, 2952, 2960, 2976, 3008, 3079, 3083, 3085, 3086, 3091, 3093, 3094, 3097, 3098, 3100, 3107, 3109, 3110, 3113, 3114, 3116, 3121, 3122, 3124, 3128, 3139, 3141, 3142, 3145, 3146, 3148, 3153, 3154, 3156, 3160, 3169, 3170, 3172, 3176, 3184, 3203, 3205, 3206, 3209, 3210, 3212, 3217, 3218, 3220, 3224, 3233, 3234, 3236, 3240, 3248, 3265, 3266, 3268, 3272, 3280, 3296, 3331, 3333, 3334, 3337, 3338, 3340, 3345, 3346, 3348, 3352, 3361, 3362, 3364, 3368, 3376, 3393, 3394, 3396, 3400, 3408, 3424, 3457, 3458, 3460, 3464, 3472, 3488, 3520, 3587, 3589, 3590, 3593, 3594, 3596, 3601, 3602, 3604, 3608, 3617, 3618, 3620, 3624, 3632, 3649, 3650, 3652, 3656, 3664, 3680, 3713, 3714, 3716, 3720, 3728, 3744, 3776, 3841, 3842, 3844, 3848, 3856, 3872, 3904, 3968, 63, 95, 111, 119, 123, 125, 126, 159, 175, 183, 187, 189, 190, 207, 215, 219, 221, 222, 231, 235, 237, 238, 243, 245, 246, 249, 250, 252, 287, 303, 311, 315, 317, 318, 335, 343, 347, 349, 350, 359, 363, 365, 366, 371, 373, 374, 377, 378, 380, 399, 407, 411, 413, 414, 423, 427, 429, 430, 435, 437, 438, 441, 442, 444, 455, 459, 461, 462, 467, 469, 470, 473, 474, 476, 483, 485, 486, 489, 490, 492, 497, 498, 500, 504, 543, 559, 567, 571, 573, 574, 591, 599, 603, 605, 606, 615, 619, 621, 622, 627, 629, 630, 633, 634, 636, 655, 663, 667, 669, 670, 679, 683, 685, 686, 691, 693, 694, 697, 698, 700, 711, 715, 717, 718, 723, 725, 726, 729, 730, 732, 739, 741, 742, 745, 746, 748, 753, 754, 756, 760, 783, 791, 795, 797, 798, 807, 811, 813, 814, 819, 821, 822, 825, 826, 828, 839, 843, 845, 846, 851, 853, 854, 857, 858, 860, 867, 869, 870, 873, 874, 876, 881, 882, 884, 888, 903, 907, 909, 910, 915, 917, 918, 921, 922, 924, 931, 933, 934, 937, 938, 940, 945, 946, 948, 952, 963, 965, 966, 969, 970, 972, 977, 978, 980, 984, 993, 994, 996, 1000, 1008, 1055, 1071, 1079, 1083, 1085, 1086, 1103, 1111, 1115, 1117, 1118, 1127, 1131, 1133, 1134, 1139, 1141, 1142, 1145, 1146, 1148, 1167, 1175, 1179, 1181, 1182, 1191, 1195, 1197, 1198, 1203, 1205, 1206, 1209, 1210, 1212, 1223, 1227, 1229, 1230, 1235, 1237, 1238, 1241, 1242, 1244, 1251, 1253, 1254, 1257, 1258, 1260, 1265, 1266, 1268, 1272, 1295, 1303, 1307, 1309, 1310, 1319, 1323, 1325, 1326, 1331, 1333, 1334, 1337, 1338, 1340, 1351, 1355, 1357, 1358, 1363, 1365, 1366, 1369, 1370, 1372, 1379, 1381, 1382, 1385, 1386, 1388, 1393, 1394, 1396, 1400, 1415, 1419, 1421, 1422, 1427, 1429, 1430, 1433, 1434, 1436, 1443, 1445, 1446, 1449, 1450, 1452, 1457, 1458, 1460, 1464, 1475, 1477, 1478, 1481, 1482, 1484, 1489, 1490, 1492, 1496, 1505, 1506, 1508, 1512, 1520, 1551, 1559, 1563, 1565, 1566, 1575, 1579, 1581, 1582, 1587, 1589, 1590, 1593, 1594, 1596, 1607, 1611, 1613, 1614, 1619, 1621, 1622, 1625, 1626, 1628, 1635, 1637, 1638, 1641, 1642, 1644, 1649, 1650, 1652, 1656, 1671, 1675, 1677, 1678, 1683, 1685, 1686, 1689, 1690, 1692, 1699, 1701, 1702, 1705, 1706, 1708, 1713, 1714, 1716, 1720, 1731, 1733, 1734, 1737, 1738, 1740, 1745, 1746, 1748, 1752, 1761, 1762, 1764, 1768, 1776, 1799, 1803, 1805, 1806, 1811, 1813, 1814, 1817, 1818, 1820, 1827, 1829, 1830, 1833, 1834, 1836, 1841, 1842, 1844, 1848, 1859, 1861, 1862, 1865, 1866, 1868, 1873, 1874, 1876, 1880, 1889, 1890, 1892, 1896, 1904, 1923, 1925, 1926, 1929, 1930, 1932, 1937, 1938, 1940, 1944, 1953, 1954, 1956, 1960, 1968, 1985, 1986, 1988, 1992, 2000, 2016, 2079, 2095, 2103, 2107, 2109, 2110, 2127, 2135, 2139, 2141, 2142, 2151, 2155, 2157, 2158, 2163, 2165, 2166, 2169, 2170, 2172, 2191, 2199, 2203, 2205, 2206, 2215, 2219, 2221, 2222, 2227, 2229, 2230, 2233, 2234, 2236, 2247, 2251, 2253, 2254, 2259, 2261, 2262, 2265, 2266, 2268, 2275, 2277, 2278, 2281, 2282, 2284, 2289, 2290, 2292, 2296, 2319, 2327, 2331, 2333, 2334, 2343, 2347, 2349, 2350, 2355, 2357, 2358, 2361, 2362, 2364, 2375, 2379, 2381, 2382, 2387, 2389, 2390, 2393, 2394, 2396, 2403, 2405, 2406, 2409, 2410, 2412, 2417, 2418, 2420, 2424, 2439, 2443, 2445, 2446, 2451, 2453, 2454, 2457, 2458, 2460, 2467, 2469, 2470, 2473, 2474, 2476, 2481, 2482, 2484, 2488, 2499, 2501, 2502, 2505, 2506, 2508, 2513, 2514, 2516, 2520, 2529, 2530, 2532, 2536, 2544, 2575, 2583, 2587, 2589, 2590, 2599, 2603, 2605, 2606, 2611, 2613, 2614, 2617, 2618, 2620, 2631, 2635, 2637, 2638, 2643, 2645, 2646, 2649, 2650, 2652, 2659, 2661, 2662, 2665, 2666, 2668, 2673, 2674, 2676, 2680, 2695, 2699, 2701, 2702, 2707, 2709, 2710, 2713, 2714, 2716, 2723, 2725, 2726, 2729, 2730, 2732, 2737, 2738, 2740, 2744, 2755, 2757, 2758, 2761, 2762, 2764, 2769, 2770, 2772, 2776, 2785, 2786, 2788, 2792, 2800, 2823, 2827, 2829, 2830, 2835, 2837, 2838, 2841, 2842, 2844, 2851, 2853, 2854, 2857, 2858, 2860, 2865, 2866, 2868, 2872, 2883, 2885, 2886, 2889, 2890, 2892, 2897, 2898, 2900, 2904, 2913, 2914, 2916, 2920, 2928, 2947, 2949, 2950, 2953, 2954, 2956, 2961, 2962, 2964, 2968, 2977, 2978, 2980, 2984, 2992, 3009, 3010, 3012, 3016, 3024, 3040, 3087, 3095, 3099, 3101, 3102, 3111, 3115, 3117, 3118, 3123, 3125, 3126, 3129, 3130, 3132, 3143, 3147, 3149, 3150, 3155, 3157, 3158, 3161, 3162, 3164, 3171, 3173, 3174, 3177, 3178, 3180, 3185, 3186, 3188, 3192, 3207, 3211, 3213, 3214, 3219, 3221, 3222, 3225, 3226, 3228, 3235, 3237, 3238, 3241, 3242, 3244, 3249, 3250, 3252, 3256, 3267, 3269, 3270, 3273, 3274, 3276, 3281, 3282, 3284, 3288, 3297, 3298, 3300, 3304, 3312, 3335, 3339, 3341, 3342, 3347, 3349, 3350, 3353, 3354, 3356, 3363, 3365, 3366, 3369, 3370, 3372, 3377, 3378, 3380, 3384, 3395, 3397, 3398, 3401, 3402, 3404, 3409, 3410, 3412, 3416, 3425, 3426, 3428, 3432, 3440, 3459, 3461, 3462, 3465, 3466, 3468, 3473, 3474, 3476, 3480, 3489, 3490, 3492, 3496, 3504, 3521, 3522, 3524, 3528, 3536, 3552, 3591, 3595, 3597, 3598, 3603, 3605, 3606, 3609, 3610, 3612, 3619, 3621, 3622, 3625, 3626, 3628, 3633, 3634, 3636, 3640, 3651, 3653, 3654, 3657, 3658, 3660, 3665, 3666, 3668, 3672, 3681, 3682, 3684, 3688, 3696, 3715, 3717, 3718, 3721, 3722, 3724, 3729, 3730, 3732, 3736, 3745, 3746, 3748, 3752, 3760, 3777, 3778, 3780, 3784, 3792, 3808, 3843, 3845, 3846, 3849, 3850, 3852, 3857, 3858, 3860, 3864, 3873, 3874, 3876, 3880, 3888, 3905, 3906, 3908, 3912, 3920, 3936, 3969, 3970, 3972, 3976, 3984, 4000, 4032, 127, 191, 223, 239, 247, 251, 253, 254, 319, 351, 367, 375, 379, 381, 382, 415, 431, 439, 443, 445, 446, 463, 471, 475, 477, 478, 487, 491, 493, 494, 499, 501, 502, 505, 506, 508, 575, 607, 623, 631, 635, 637, 638, 671, 687, 695, 699, 701, 702, 719, 727, 731, 733, 734, 743, 747, 749, 750, 755, 757, 758, 761, 762, 764, 799, 815, 823, 827, 829, 830, 847, 855, 859, 861, 862, 871, 875, 877, 878, 883, 885, 886, 889, 890, 892, 911, 919, 923, 925, 926, 935, 939, 941, 942, 947, 949, 950, 953, 954, 956, 967, 971, 973, 974, 979, 981, 982, 985, 986, 988, 995, 997, 998, 1001, 1002, 1004, 1009, 1010, 1012, 1016, 1087, 1119, 1135, 1143, 1147, 1149, 1150, 1183, 1199, 1207, 1211, 1213, 1214, 1231, 1239, 1243, 1245, 1246, 1255, 1259, 1261, 1262, 1267, 1269, 1270, 1273, 1274, 1276, 1311, 1327, 1335, 1339, 1341, 1342, 1359, 1367, 1371, 1373, 1374, 1383, 1387, 1389, 1390, 1395, 1397, 1398, 1401, 1402, 1404, 1423, 1431, 1435, 1437, 1438, 1447, 1451, 1453, 1454, 1459, 1461, 1462, 1465, 1466, 1468, 1479, 1483, 1485, 1486, 1491, 1493, 1494, 1497, 1498, 1500, 1507, 1509, 1510, 1513, 1514, 1516, 1521, 1522, 1524, 1528, 1567, 1583, 1591, 1595, 1597, 1598, 1615, 1623, 1627, 1629, 1630, 1639, 1643, 1645, 1646, 1651, 1653, 1654, 1657, 1658, 1660, 1679, 1687, 1691, 1693, 1694, 1703, 1707, 1709, 1710, 1715, 1717, 1718, 1721, 1722, 1724, 1735, 1739, 1741, 1742, 1747, 1749, 1750, 1753, 1754, 1756, 1763, 1765, 1766, 1769, 1770, 1772, 1777, 1778, 1780, 1784, 1807, 1815, 1819, 1821, 1822, 1831, 1835, 1837, 1838, 1843, 1845, 1846, 1849, 1850, 1852, 1863, 1867, 1869, 1870, 1875, 1877, 1878, 1881, 1882, 1884, 1891, 1893, 1894, 1897, 1898, 1900, 1905, 1906, 1908, 1912, 1927, 1931, 1933, 1934, 1939, 1941, 1942, 1945, 1946, 1948, 1955, 1957, 1958, 1961, 1962, 1964, 1969, 1970, 1972, 1976, 1987, 1989, 1990, 1993, 1994, 1996, 2001, 2002, 2004, 2008, 2017, 2018, 2020, 2024, 2032, 2111, 2143, 2159, 2167, 2171, 2173, 2174, 2207, 2223, 2231, 2235, 2237, 2238, 2255, 2263, 2267, 2269, 2270, 2279, 2283, 2285, 2286, 2291, 2293, 2294, 2297, 2298, 2300, 2335, 2351, 2359, 2363, 2365, 2366, 2383, 2391, 2395, 2397, 2398, 2407, 2411, 2413, 2414, 2419, 2421, 2422, 2425, 2426, 2428, 2447, 2455, 2459, 2461, 2462, 2471, 2475, 2477, 2478, 2483, 2485, 2486, 2489, 2490, 2492, 2503, 2507, 2509, 2510, 2515, 2517, 2518, 2521, 2522, 2524, 2531, 2533, 2534, 2537, 2538, 2540, 2545, 2546, 2548, 2552, 2591, 2607, 2615, 2619, 2621, 2622, 2639, 2647, 2651, 2653, 2654, 2663, 2667, 2669, 2670, 2675, 2677, 2678, 2681, 2682, 2684, 2703, 2711, 2715, 2717, 2718, 2727, 2731, 2733, 2734, 2739, 2741, 2742, 2745, 2746, 2748, 2759, 2763, 2765, 2766, 2771, 2773, 2774, 2777, 2778, 2780, 2787, 2789, 2790, 2793, 2794, 2796, 2801, 2802, 2804, 2808, 2831, 2839, 2843, 2845, 2846, 2855, 2859, 2861, 2862, 2867, 2869, 2870, 2873, 2874, 2876, 2887, 2891, 2893, 2894, 2899, 2901, 2902, 2905, 2906, 2908, 2915, 2917, 2918, 2921, 2922, 2924, 2929, 2930, 2932, 2936, 2951, 2955, 2957, 2958, 2963, 2965, 2966, 2969, 2970, 2972, 2979, 2981, 2982, 2985, 2986, 2988, 2993, 2994, 2996, 3000, 3011, 3013, 3014, 3017, 3018, 3020, 3025, 3026, 3028, 3032, 3041, 3042, 3044, 3048, 3056, 3103, 3119, 3127, 3131, 3133, 3134, 3151, 3159, 3163, 3165, 3166, 3175, 3179, 3181, 3182, 3187, 3189, 3190, 3193, 3194, 3196, 3215, 3223, 3227, 3229, 3230, 3239, 3243, 3245, 3246, 3251, 3253, 3254, 3257, 3258, 3260, 3271, 3275, 3277, 3278, 3283, 3285, 3286, 3289, 3290, 3292, 3299, 3301, 3302, 3305, 3306, 3308, 3313, 3314, 3316, 3320, 3343, 3351, 3355, 3357, 3358, 3367, 3371, 3373, 3374, 3379, 3381, 3382, 3385, 3386, 3388, 3399, 3403, 3405, 3406, 3411, 3413, 3414, 3417, 3418, 3420, 3427, 3429, 3430, 3433, 3434, 3436, 3441, 3442, 3444, 3448, 3463, 3467, 3469, 3470, 3475, 3477, 3478, 3481, 3482, 3484, 3491, 3493, 3494, 3497, 3498, 3500, 3505, 3506, 3508, 3512, 3523, 3525, 3526, 3529, 3530, 3532, 3537, 3538, 3540, 3544, 3553, 3554, 3556, 3560, 3568, 3599, 3607, 3611, 3613, 3614, 3623, 3627, 3629, 3630, 3635, 3637, 3638, 3641, 3642, 3644, 3655, 3659, 3661, 3662, 3667, 3669, 3670, 3673, 3674, 3676, 3683, 3685, 3686, 3689, 3690, 3692, 3697, 3698, 3700, 3704, 3719, 3723, 3725, 3726, 3731, 3733, 3734, 3737, 3738, 3740, 3747, 3749, 3750, 3753, 3754, 3756, 3761, 3762, 3764, 3768, 3779, 3781, 3782, 3785, 3786, 3788, 3793, 3794, 3796, 3800, 3809, 3810, 3812, 3816, 3824, 3847, 3851, 3853, 3854, 3859, 3861, 3862, 3865, 3866, 3868, 3875, 3877, 3878, 3881, 3882, 3884, 3889, 3890, 3892, 3896, 3907, 3909, 3910, 3913, 3914, 3916, 3921, 3922, 3924, 3928, 3937, 3938, 3940, 3944, 3952, 3971, 3973, 3974, 3977, 3978, 3980, 3985, 3986, 3988, 3992, 4001, 4002, 4004, 4008, 4016, 4033, 4034, 4036, 4040, 4048, 4064, 255, 383, 447, 479, 495, 503, 507, 509, 510, 639, 703, 735, 751, 759, 763, 765, 766, 831, 863, 879, 887, 891, 893, 894, 927, 943, 951, 955, 957, 958, 975, 983, 987, 989, 990, 999, 1003, 1005, 1006, 1011, 1013, 1014, 1017, 1018, 1020, 1151, 1215, 1247, 1263, 1271, 1275, 1277, 1278, 1343, 1375, 1391, 1399, 1403, 1405, 1406, 1439, 1455, 1463, 1467, 1469, 1470, 1487, 1495, 1499, 1501, 1502, 1511, 1515, 1517, 1518, 1523, 1525, 1526, 1529, 1530, 1532, 1599, 1631, 1647, 1655, 1659, 1661, 1662, 1695, 1711, 1719, 1723, 1725, 1726, 1743, 1751, 1755, 1757, 1758, 1767, 1771, 1773, 1774, 1779, 1781, 1782, 1785, 1786, 1788, 1823, 1839, 1847, 1851, 1853, 1854, 1871, 1879, 1883, 1885, 1886, 1895, 1899, 1901, 1902, 1907, 1909, 1910, 1913, 1914, 1916, 1935, 1943, 1947, 1949, 1950, 1959, 1963, 1965, 1966, 1971, 1973, 1974, 1977, 1978, 1980, 1991, 1995, 1997, 1998, 2003, 2005, 2006, 2009, 2010, 2012, 2019, 2021, 2022, 2025, 2026, 2028, 2033, 2034, 2036, 2040, 2175, 2239, 2271, 2287, 2295, 2299, 2301, 2302, 2367, 2399, 2415, 2423, 2427, 2429, 2430, 2463, 2479, 2487, 2491, 2493, 2494, 2511, 2519, 2523, 2525, 2526, 2535, 2539, 2541, 2542, 2547, 2549, 2550, 2553, 2554, 2556, 2623, 2655, 2671, 2679, 2683, 2685, 2686, 2719, 2735, 2743, 2747, 2749, 2750, 2767, 2775, 2779, 2781, 2782, 2791, 2795, 2797, 2798, 2803, 2805, 2806, 2809, 2810, 2812, 2847, 2863, 2871, 2875, 2877, 2878, 2895, 2903, 2907, 2909, 2910, 2919, 2923, 2925, 2926, 2931, 2933, 2934, 2937, 2938, 2940, 2959, 2967, 2971, 2973, 2974, 2983, 2987, 2989, 2990, 2995, 2997, 2998, 3001, 3002, 3004, 3015, 3019, 3021, 3022, 3027, 3029, 3030, 3033, 3034, 3036, 3043, 3045, 3046, 3049, 3050, 3052, 3057, 3058, 3060, 3064, 3135, 3167, 3183, 3191, 3195, 3197, 3198, 3231, 3247, 3255, 3259, 3261, 3262, 3279, 3287, 3291, 3293, 3294, 3303, 3307, 3309, 3310, 3315, 3317, 3318, 3321, 3322, 3324, 3359, 3375, 3383, 3387, 3389, 3390, 3407, 3415, 3419, 3421, 3422, 3431, 3435, 3437, 3438, 3443, 3445, 3446, 3449, 3450, 3452, 3471, 3479, 3483, 3485, 3486, 3495, 3499, 3501, 3502, 3507, 3509, 3510, 3513, 3514, 3516, 3527, 3531, 3533, 3534, 3539, 3541, 3542, 3545, 3546, 3548, 3555, 3557, 3558, 3561, 3562, 3564, 3569, 3570, 3572, 3576, 3615, 3631, 3639, 3643, 3645, 3646, 3663, 3671, 3675, 3677, 3678, 3687, 3691, 3693, 3694, 3699, 3701, 3702, 3705, 3706, 3708, 3727, 3735, 3739, 3741, 3742, 3751, 3755, 3757, 3758, 3763, 3765, 3766, 3769, 3770, 3772, 3783, 3787, 3789, 3790, 3795, 3797, 3798, 3801, 3802, 3804, 3811, 3813, 3814, 3817, 3818, 3820, 3825, 3826, 3828, 3832, 3855, 3863, 3867, 3869, 3870, 3879, 3883, 3885, 3886, 3891, 3893, 3894, 3897, 3898, 3900, 3911, 3915, 3917, 3918, 3923, 3925, 3926, 3929, 3930, 3932, 3939, 3941, 3942, 3945, 3946, 3948, 3953, 3954, 3956, 3960, 3975, 3979, 3981, 3982, 3987, 3989, 3990, 3993, 3994, 3996, 4003, 4005, 4006, 4009, 4010, 4012, 4017, 4018, 4020, 4024, 4035, 4037, 4038, 4041, 4042, 4044, 4049, 4050, 4052, 4056, 4065, 4066, 4068, 4072, 4080, 511, 767, 895, 959, 991, 1007, 1015, 1019, 1021, 1022, 1279, 1407, 1471, 1503, 1519, 1527, 1531, 1533, 1534, 1663, 1727, 1759, 1775, 1783, 1787, 1789, 1790, 1855, 1887, 1903, 1911, 1915, 1917, 1918, 1951, 1967, 1975, 1979, 1981, 1982, 1999, 2007, 2011, 2013, 2014, 2023, 2027, 2029, 2030, 2035, 2037, 2038, 2041, 2042, 2044, 2303, 2431, 2495, 2527, 2543, 2551, 2555, 2557, 2558, 2687, 2751, 2783, 2799, 2807, 2811, 2813, 2814, 2879, 2911, 2927, 2935, 2939, 2941, 2942, 2975, 2991, 2999, 3003, 3005, 3006, 3023, 3031, 3035, 3037, 3038, 3047, 3051, 3053, 3054, 3059, 3061, 3062, 3065, 3066, 3068, 3199, 3263, 3295, 3311, 3319, 3323, 3325, 3326, 3391, 3423, 3439, 3447, 3451, 3453, 3454, 3487, 3503, 3511, 3515, 3517, 3518, 3535, 3543, 3547, 3549, 3550, 3559, 3563, 3565, 3566, 3571, 3573, 3574, 3577, 3578, 3580, 3647, 3679, 3695, 3703, 3707, 3709, 3710, 3743, 3759, 3767, 3771, 3773, 3774, 3791, 3799, 3803, 3805, 3806, 3815, 3819, 3821, 3822, 3827, 3829, 3830, 3833, 3834, 3836, 3871, 3887, 3895, 3899, 3901, 3902, 3919, 3927, 3931, 3933, 3934, 3943, 3947, 3949, 3950, 3955, 3957, 3958, 3961, 3962, 3964, 3983, 3991, 3995, 3997, 3998, 4007, 4011, 4013, 4014, 4019, 4021, 4022, 4025, 4026, 4028, 4039, 4043, 4045, 4046, 4051, 4053, 4054, 4057, 4058, 4060, 4067, 4069, 4070, 4073, 4074, 4076, 4081, 4082, 4084, 4088, 1023, 1535, 1791, 1919, 1983, 2015, 2031, 2039, 2043, 2045, 2046, 2559, 2815, 2943, 3007, 3039, 3055, 3063, 3067, 3069, 3070, 3327, 3455, 3519, 3551, 3567, 3575, 3579, 3581, 3582, 3711, 3775, 3807, 3823, 3831, 3835, 3837, 3838, 3903, 3935, 3951, 3959, 3963, 3965, 3966, 3999, 4015, 4023, 4027, 4029, 4030, 4047, 4055, 4059, 4061, 4062, 4071, 4075, 4077, 4078, 4083, 4085, 4086, 4089, 4090, 4092, 2047, 3071, 3583, 3839, 3967, 4031, 4063, 4079, 4087, 4091, 4093, 4094, 4095]

According to some implementations of the present disclosure, information/frozen bits may be determined by applying the PO method for bit channels with the same weight based on an RM profile method. Through this, the performance of channel coding based on polar codes may be improved by maximizing the minimum distance between codewords. According to some implementations of the present disclosure, various information sizes may be supported in PAC codes while maximizing the minimum distance between codewords.

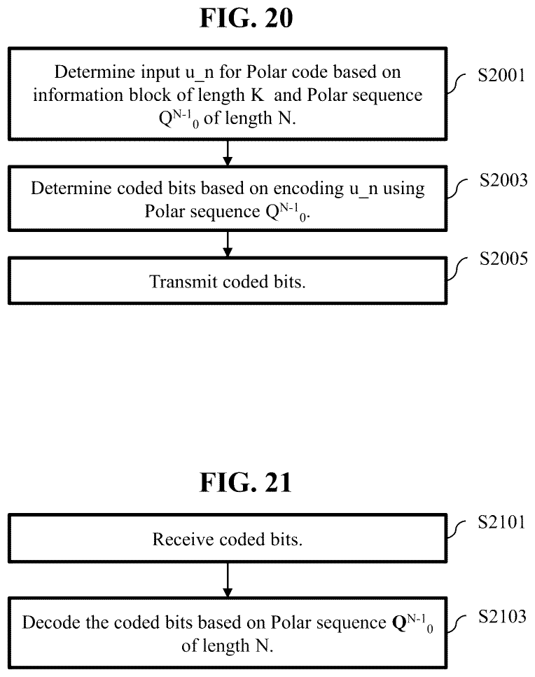

FIG. 20 illustrates a channel encoding process according to some implementations of the present disclosure.

A communication device or encoder may perform operations related to channel encoding according to some implementations of the present disclosure. The communication device may include: at least one transceiver; at least one processor; and at least one computer memory operably connected to the at least one processor and storing instructions that, when executed, cause the at least one processor to perform operations according to some implementations of the present disclosure. A processing device for the communication device or encoder may include: at least one processor; and at least one computer memory operably connected to the at least one processor and storing instructions that, when executed, cause the at least one processor to perform the operations according to some implementations of the present disclosure. A computer-readable (non-volatile) storage medium may store at least one computer program including instructions that, when executed by at least one processor, cause the at least one processor to perform the operations according to some implementations of the present disclosure. A computer program or computer program product may include instructions that are recorded in at least one computer-readable (non-volatile) storage medium and cause, when executed, (at least one processor) to perform the operations according to some implementations of the present disclosure. Referring to FIG. 20, in the communication device, the encoder, the processing device, the computer-readable (non-volatile) storage medium, and/or the computer program product, the operations include determining an input u_n to a polar based on a length N of the polar code, a length K of the information block, and a polar sequence Q^{N-1}₀={Q₀, Q₁, . . . , Q_{N-1}} of length N (S2001), determining coded bits based on the input u_n being encoded based on the polar code of length N and the polar sequence Q^{N-1}₀={Q₀, Q₁, . . . , Q_{N-1}} of length N (S2003), and transmitting the coded bits to another communication device (S2005). The polar sequence Q^{N-1}₀={Q₀, Q₁, . . . , Q_{N-1}} of length N is defined in ascending order of reliability W(Q^{N}₀)<W(Q^{N}ᵢ)< . . . <W(Q^{N}_{N-1}), where 0<=Q^{N}ᵢ<=N−1 is a bit index for i=0, 1, . . . , N−1 and W(Q^{N}ᵢ) is the reliability of bit index Q^{N}ᵢ. bit indices of the polar sequence Q^{N-1}₀={Q₀, Q₁, . . . , Q_{N-1}} of length N satisfy i) a reliability increases as a number of is when expressed in binary increases, and ii) bit indices having the same number of is when expressed in binary are W(Q^{N}ₓ)<W(Q^{N}_{y}) for Q^{N}ₓ<Q^{N}_{y}. Here, v_n and u_n are sequences or vectors of length N, respectively.

In some implementations, the polar sequence Q^{N-1}₀={Q₀, Q₁, . . . , Q_{N-1}} of length N may be a subset of the polar sequence W₄₀₉₆ described above.

In some implementations, determining the input u_n may include determining an input v_n for convolution based on the length N of the polar code, the length K of the information block, and the polar sequence Q^{N-1}₀={Q₀, Q₁, . . . , Q_{N-1}} of length N, and determining the input u_n based on performing the convolution on the input v_n. Here, determining the input v_n may include determining K input indices at which K bits of the information block are to be located and input indices to be frozen from among input indices 0 to N−1 of the polar code of length N.

In some implementations, determining the input u_n includes determining K input indices at which K bits of the information block are to be located and input indices to be frozen from among input indices 0 to N−1 of the polar code of length N, based on the polar sequence Q^{N-1}₀={Q₀, Q₁, . . . , Q_{N-1}} of length N.

In some implementations, performing the convolution may include determining a number of shift registers based on the length N of the polar code from among predetermined numbers of shift registers for mother code sizes, and performing a convolution on the input v_n based on the determined number of shift registers.

In some implementations, the predetermined numbers of shift registers may be greater than or equal to the respective maximum numbers of consecutive frozen bits for the mother code sizes.

In some implementations, performing the convolution may include determining the input u_n based on

$${u}_{n} = {v}_{n} + {Σ}_{k = 1}^{m} {c}_{k} {u}_{n - k} .$$

Here, uₙ=u_n and vₙ=v_n. For example, the performing the convolution may include determining the second input u_n based on v_n+u_(n−1), where u_(n−1) may be a sequence of values stored in shift registers based on a previous convolution of the convolution.

In some implementations, the same number of shift registers may be used for different mother code sizes.

FIG. 21 illustrates a channel decoding process according to some implementations of the present disclosure.

A communication device or decoder may perform operations related to channel decoding according to some implementations of the present disclosure. The communication device may include: at least one transceiver; at least one processor; and at least one computer memory operably connected to the at least one processor and storing instructions that, when executed, cause the at least one processor to perform operations according to some implementations of the present disclosure. A processing device for the communication device or decoder may include: at least one processor; and at least one computer memory operably connected to the at least one processor and storing instructions that, when executed, cause the at least one processor to perform the operations according to some implementations of the present disclosure. A computer-readable (non-volatile) storage medium may store at least one computer program including instructions that, when executed by at least one processor, cause the at least one processor to perform the operations according to some implementations of the present disclosure. A computer program or computer program product may include instructions that are recorded in at least one computer-readable (non-volatile) storage medium and cause, when executed, (at least one processor) to perform the operations according to some implementations of the present disclosure. Referring to FIG. 18, in the communication device, the decoder, the processing device, the computer-readable (non-volatile) storage medium, and/or the computer program product, the operations include receiving coded bits from another communication device (S2101), and decoding the coded bits based on a polar sequence Q^{N-1}₀={Q₀, Q₁, . . . , Q_{N-1}} of length N (2103) to determine an information block.

In some implementations, the polar sequence Q^{N-1}₀={Q₀, Q₁, . . . , Q_{N-1}} of length N may be a subset of the polar sequence W₄₀₉₆ described above.

The examples of the present disclosure as described above have been presented to enable any person of ordinary skill in the art to implement and practice the present disclosure. Although the present disclosure has been described with reference to the examples, those skilled in the art may make various modifications and variations in the example of the present disclosure. Thus, the present disclosure is not intended to be limited to the examples set for the herein, but is to be accorded the broadest scope consistent with the principles and features disclosed herein.

The implementations of the present disclosure may be used in a BS, a UE, or other equipment in a wireless communication system.

1. A method performed by a communication device, the method comprising:
determining an input u_n to a polar code based on a length N of the polar code, a length K of an information block, and a polar sequence Q^{N-1}₀={Q₀, Q₁, . . . , Q_{N-1}} of length N;
determining coded bits based on the input u_n being encoded based on the polar code of length N and the polar sequence Q^{N-1}₀={Q₀, Q₁, . . . , Q_{N-1}} of length N; and
transmitting the coded bits to another communication device,
wherein the polar sequence Q^{N-1}₀={Q₀, Q₁, . . . , Q_{N-1}} of length N is defined in ascending order of a reliability W(Q^{N}₀)<W(Q^{N}₁)< . . . <W(Q^{N}_{N-1}), and 0<=Q^{N}<=N−1 is a bit index for i=0, 1, . . . , N−1 and W(Q^{N}ᵢ) is a reliability of the bit index Q^{N}ᵢ,
wherein determining the input u_n includes determining K input indices at which K bits of the information block are to be located and input indices to be frozen from among input indices 0 to N−1 of the polar code of length N, based on the polar sequence Q^{N-1}₀={Q₀, Q₁, . . . , Q_{N-1}} of length N, and
wherein bit indices of the polar sequence Q^{N-1}₀={Q₀, Q₁, . . . , Q_{N-1}} of length N satisfy: i) a reliability increases as a number of is when expressed in binary increases, and ii) bit indices having the same number of is when expressed in binary are W(Q^{N}ₓ)<W(Q^{N}_{y}) for Q^{N}ₓ<Q^{N}_{y}.

2. The method of claim 1, wherein the polar sequence Q^{N-1}₀={Q₀ Q₁, . . . , Q_{N-1}} of length N is a subset of a following polar sequence with a length of 4096:
0, 1, 2, 4, 8, 16, 32, 64, 128, 256, 512, 1024, 2048, 3, 5, 6, 9, 10, 12, 17, 18, 20, 24, 33, 34, 36, 40, 48, 65, 66, 68, 72, 80, 96, 129, 130, 132, 136, 144, 160, 192, 257, 258, 260, 264, 272, 288, 320, 384, 513, 514, 516, 520, 528, 544, 576, 640, 768, 1025, 1026, 1028, 1032, 1040, 1056, 1088, 1152, 1280, 1536, 2049, 2050, 2052, 2056, 2064, 2080, 2112, 2176, 2304, 2560,3072,7, 11, 13, 14, 19, 21, 22, 25, 26, 28, 35, 37, 38, 41, 42, 44, 49, 50, 52, 56, 67, 69, 70, 73, 74, 76, 81, 82, 84, 88, 97, 98, 100, 104, 112, 131, 133, 134, 137, 138, 140, 145, 146, 148, 152, 161, 162, 164, 168, 176, 193, 194, 196, 200, 208, 224, 259, 261, 262, 265, 266, 268, 273, 274, 276, 280, 289, 290, 292, 296, 304, 321, 322, 324, 328, 336, 352, 385, 386, 388, 392, 400, 416, 448, 515, 517, 518, 521, 522, 524, 529, 530, 532, 536, 545, 546, 548, 552, 560, 577, 578, 580, 584, 592, 608, 641, 642, 644, 648, 656, 672, 704, 769, 770, 772, 776, 784, 800, 832, 896, 1027, 1029, 1030, 1033, 1034, 1036, 1041, 1042, 1044, 1048, 1057, 1058, 1060, 1064, 1072, 1089, 1090, 1092, 1096, 1104, 1120, 1153, 1154, 1156, 1160, 1168, 1184, 1216, 1281, 1282, 1284, 1288, 1296, 1312, 1344, 1408, 1537, 1538, 1540, 1544, 1552, 1568, 1600, 1664, 1792, 2051, 2053, 2054, 2057, 2058, 2060, 2065, 2066, 2068, 2072, 2081, 2082, 2084, 2088, 2096, 2113, 2114, 2116, 2120, 2128, 2144, 2177, 2178, 2180, 2184, 2192, 2208, 2240, 2305, 2306, 2308, 2312, 2320, 2336, 2368, 2432, 2561, 2562, 2564, 2568, 2576, 2592, 2624, 2688, 2816, 3073, 3074, 3076, 3080, 3088, 3104, 3136, 3200, 3328, 3584, 15, 23, 27, 29, 30, 39, 43, 45, 46, 51, 53, 54, 57, 58, 60, 71, 75, 77, 78, 83, 85, 86, 89, 90, 92, 99, 101, 102, 105, 106, 108, 113, 114, 116, 120, 135, 139, 141, 142, 147, 149, 150, 153, 154, 156, 163, 165, 166, 169, 170, 172, 177, 178, 180, 184, 195, 197, 198, 201, 202, 204, 209, 210, 212, 216, 225, 226, 228, 232, 240, 263, 267, 269, 270, 275, 277, 278, 281, 282, 284, 291, 293, 294, 297, 298, 300, 305, 306, 308, 312, 323, 325, 326, 329, 330, 332, 337, 338, 340, 344, 353, 354, 356, 360, 368, 387, 389, 390, 393, 394, 396, 401, 402, 404, 408, 417, 418, 420, 424, 432, 449, 450, 452, 456, 464, 480, 519, 523, 525, 526, 531, 533, 534, 537, 538, 540, 547, 549, 550, 553, 554, 556, 561, 562, 564, 568, 579, 581, 582, 585, 586, 588, 593, 594, 596, 600, 609, 610, 612, 616, 624, 643, 645, 646, 649, 650, 652, 657, 658, 660, 664, 673, 674, 676, 680, 688, 705, 706, 708, 712, 720, 736, 771, 773, 774, 777, 778, 780, 785, 786, 788, 792, 801, 802, 804, 808, 816, 833, 834, 836, 840, 848, 864, 897, 898, 900, 904, 912, 928, 960, 1031, 1035, 1037, 1038, 1043, 1045, 1046, 1049, 1050, 1052, 1059, 1061, 1062, 1065, 1066, 1068, 1073, 1074, 1076, 1080, 1091, 1093, 1094, 1097, 1098, 1100, 1105, 1106, 1108, 1112, 1121, 1122, 1124, 1128, 1136, 1155, 1157, 1158, 1161, 1162, 1164, 1169, 1170, 1172, 1176, 1185, 1186, 1188, 1192, 1200, 1217, 1218, 1220, 1224, 1232, 1248, 1283, 1285, 1286, 1289, 1290, 1292, 1297, 1298, 1300, 1304, 1313, 1314, 1316, 1320, 1328, 1345, 1346, 1348, 1352, 1360, 1376, 1409, 1410, 1412, 1416, 1424, 1440, 1472, 1539, 1541, 1542, 1545, 1546, 1548, 1553, 1554, 1556, 1560, 1569, 1570, 1572, 1576, 1584, 1601, 1602, 1604, 1608, 1616, 1632, 1665, 1666, 1668, 1672, 1680, 1696, 1728, 1793, 1794, 1796, 1800, 1808, 1824, 1856, 1920, 2055, 2059, 2061, 2062, 2067, 2069, 2070, 2073, 2074, 2076, 2083, 2085, 2086, 2089, 2090, 2092, 2097, 2098, 2100, 2104, 2115, 2117, 2118, 2121,2122,2124,2129,2130,2132,2136,2145,2146,2148,2152,2160,2179,2181,2182, 2185, 2186, 2188, 2193, 2194, 2196, 2200, 2209, 2210, 2212, 2216, 2224, 2241, 2242, 2244, 2248, 2256, 2272, 2307, 2309, 2310, 2313, 2314, 2316, 2321, 2322, 2324, 2328, 2337, 2338, 2340, 2344, 2352, 2369, 2370, 2372, 2376, 2384, 2400, 2433, 2434, 2436, 2440, 2448, 2464, 2496, 2563, 2565, 2566, 2569, 2570, 2572, 2577, 2578, 2580, 2584, 2593, 2594, 2596, 2600, 2608, 2625, 2626, 2628, 2632, 2640, 2656, 2689, 2690, 2692, 2696, 2704, 2720, 2752, 2817, 2818, 2820, 2824, 2832, 2848, 2880, 2944, 3075, 3077, 3078, 3081, 3082, 3084, 3089, 3090, 3092, 3096, 3105, 3106, 3108, 3112, 3120, 3137, 3138, 3140, 3144, 3152, 3168, 3201, 3202, 3204, 3208, 3216, 3232, 3264, 3329, 3330, 3332, 3336, 3344, 3360, 3392, 3456, 3585, 3586, 3588, 3592, 3600, 3616, 3648, 3712, 3840, 31, 47, 55, 59, 61, 62, 79, 87, 91, 93, 94, 103, 107, 109, 110, 115, 117, 118, 121, 122, 124, 143, 151, 155, 157, 158, 167, 171, 173, 174, 179, 181, 182, 185, 186, 188, 199, 203, 205, 206, 211, 213, 214, 217, 218, 220, 227, 229, 230, 233, 234, 236, 241, 242, 244, 248, 271, 279, 283, 285, 286, 295, 299, 301, 302, 307, 309, 310, 313, 314, 316, 327, 331, 333, 334, 339, 341, 342, 345, 346, 348, 355, 357, 358, 361, 362, 364, 369, 370, 372, 376, 391, 395, 397, 398, 403, 405, 406, 409, 410, 412, 419, 421, 422, 425, 426, 428, 433, 434, 436, 440, 451, 453, 454, 457, 458, 460, 465, 466, 468, 472, 481, 482, 484, 488, 496, 527, 535, 539, 541, 542, 551, 555, 557, 558, 563, 565, 566, 569, 570, 572, 583, 587, 589, 590, 595, 597, 598, 601, 602, 604, 611, 613, 614, 617, 618, 620, 625, 626, 628, 632, 647, 651, 653, 654, 659, 661, 662, 665, 666, 668, 675, 677, 678, 681, 682, 684, 689, 690, 692, 696, 707, 709, 710, 713, 714, 716, 721, 722, 724, 728, 737, 738, 740, 744, 752, 775, 779, 781, 782, 787, 789, 790, 793, 794, 796, 803, 805, 806, 809, 810, 812, 817, 818, 820, 824, 835, 837, 838, 841, 842, 844, 849, 850, 852, 856, 865, 866, 868, 872, 880, 899, 901, 902, 905, 906, 908, 913, 914, 916, 920, 929, 930, 932, 936, 944, 961, 962, 964, 968, 976, 992, 1039, 1047, 1051, 1053, 1054, 1063, 1067, 1069, 1070, 1075, 1077, 1078, 1081, 1082, 1084, 1095, 1099, 1101, 1102, 1107, 1109, 1110, 1113, 1114, 1116, 1123, 1125, 1126, 1129, 1130, 1132, 1137, 1138, 1140, 1144, 1159, 1163, 1165, 1166, 1171, 1173, 1174, 1177, 1178, 1180, 1187, 1189, 1190, 1193, 1194, 1196, 1201, 1202, 1204, 1208, 1219, 1221, 1222, 1225, 1226, 1228, 1233, 1234, 1236, 1240, 1249, 1250, 1252, 1256, 1264, 1287, 1291, 1293, 1294, 1299, 1301, 1302, 1305, 1306, 1308, 1315, 1317, 1318, 1321, 1322, 1324, 1329, 1330, 1332, 1336, 1347, 1349, 1350, 1353, 1354, 1356, 1361, 1362, 1364, 1368, 1377, 1378, 1380, 1384, 1392, 1411, 1413, 1414, 1417, 1418, 1420, 1425, 1426, 1428, 1432, 1441, 1442, 1444, 1448, 1456, 1473, 1474, 1476, 1480, 1488, 1504, 1543, 1547, 1549, 1550, 1555, 1557, 1558, 1561, 1562, 1564, 1571, 1573, 1574, 1577, 1578, 1580, 1585, 1586, 1588, 1592, 1603, 1605, 1606, 1609, 1610, 1612, 1617, 1618, 1620, 1624, 1633, 1634, 1636, 1640, 1648, 1667, 1669, 1670, 1673, 1674, 1676, 1681, 1682, 1684, 1688, 1697, 1698, 1700, 1704, 1712, 1729, 1730, 1732, 1736, 1744, 1760, 1795, 1797, 1798, 1801, 1802, 1804, 1809, 1810, 1812, 1816, 1825, 1826, 1828, 1832, 1840, 1857, 1858, 1860, 1864, 1872, 1888, 1921, 1922, 1924, 1928, 1936, 1952, 1984, 2063, 2071, 2075, 2077, 2078, 2087, 2091, 2093, 2094, 2099, 2101, 2102, 2105, 2106, 2108, 2119, 2123, 2125, 2126, 2131, 2133, 2134,2137,2138,2140,2147,2149,2150,2153,2154,2156,2161,2162,2164,2168,2183, 2187, 2189, 2190, 2195, 2197, 2198, 2201, 2202, 2204, 2211, 2213, 2214, 2217, 2218, 2220, 2225, 2226, 2228, 2232, 2243, 2245, 2246, 2249, 2250, 2252, 2257, 2258, 2260, 2264, 2273, 2274, 2276, 2280, 2288, 2311, 2315, 2317, 2318, 2323, 2325, 2326, 2329, 2330, 2332, 2339, 2341, 2342, 2345, 2346, 2348, 2353, 2354, 2356, 2360, 2371, 2373, 2374, 2377, 2378, 2380, 2385, 2386, 2388, 2392, 2401, 2402, 2404, 2408, 2416, 2435, 2437, 2438, 2441, 2442, 2444, 2449, 2450, 2452, 2456, 2465, 2466, 2468, 2472, 2480, 2497, 2498, 2500, 2504, 2512, 2528, 2567, 2571, 2573, 2574, 2579, 2581, 2582, 2585, 2586, 2588, 2595, 2597, 2598, 2601, 2602, 2604, 2609, 2610, 2612, 2616, 2627, 2629, 2630, 2633, 2634, 2636, 2641, 2642, 2644, 2648, 2657, 2658, 2660, 2664, 2672, 2691, 2693, 2694, 2697, 2698, 2700, 2705, 2706, 2708, 2712, 2721, 2722, 2724, 2728, 2736, 2753, 2754, 2756, 2760, 2768, 2784, 2819, 2821, 2822, 2825, 2826, 2828, 2833, 2834, 2836, 2840, 2849, 2850, 2852, 2856, 2864, 2881, 2882, 2884, 2888, 2896, 2912, 2945, 2946, 2948, 2952, 2960, 2976, 3008, 3079, 3083, 3085, 3086, 3091, 3093, 3094, 3097, 3098, 3100, 3107, 3109, 3110, 3113, 3114, 3116, 3121, 3122, 3124, 3128, 3139, 3141, 3142, 3145, 3146, 3148, 3153, 3154, 3156, 3160, 3169, 3170, 3172, 3176, 3184, 3203, 3205, 3206, 3209, 3210, 3212, 3217, 3218, 3220, 3224, 3233, 3234, 3236, 3240, 3248, 3265, 3266, 3268, 3272, 3280, 3296, 3331, 3333, 3334, 3337, 3338, 3340, 3345, 3346, 3348, 3352, 3361, 3362, 3364, 3368, 3376, 3393, 3394, 3396, 3400, 3408, 3424, 3457, 3458, 3460, 3464, 3472, 3488, 3520, 3587, 3589, 3590, 3593, 3594, 3596, 3601, 3602, 3604, 3608, 3617, 3618, 3620, 3624, 3632, 3649, 3650, 3652, 3656, 3664, 3680, 3713, 3714, 3716, 3720, 3728, 3744, 3776, 3841, 3842, 3844, 3848, 3856, 3872, 3904, 3968, 63, 95, 111, 119, 123, 125, 126, 159, 175, 183, 187, 189, 190, 207, 215, 219, 221, 222, 231, 235, 237, 238, 243, 245, 246, 249, 250, 252, 287, 303, 311, 315, 317, 318, 335, 343, 347, 349, 350, 359, 363, 365, 366, 371, 373, 374, 377, 378, 380, 399, 407, 411, 413, 414, 423, 427, 429, 430, 435, 437, 438, 441, 442, 444, 455, 459, 461, 462, 467, 469, 470, 473, 474, 476, 483, 485, 486, 489, 490, 492, 497, 498, 500, 504, 543, 559, 567, 571, 573, 574, 591, 599, 603, 605, 606, 615, 619, 621, 622, 627, 629, 630, 633, 634, 636, 655, 663, 667, 669, 670, 679, 683, 685, 686, 691, 693, 694, 697, 698, 700, 711, 715, 717, 718, 723, 725, 726, 729, 730, 732, 739, 741, 742, 745, 746, 748, 753, 754, 756, 760, 783, 791, 795, 797, 798, 807, 811, 813, 814, 819, 821, 822, 825, 826, 828, 839, 843, 845, 846, 851, 853, 854, 857, 858, 860, 867, 869, 870, 873, 874, 876, 881, 882, 884, 888, 903, 907, 909, 910, 915, 917, 918, 921, 922, 924, 931, 933, 934, 937, 938, 940, 945, 946, 948, 952, 963, 965, 966, 969, 970, 972, 977, 978, 980, 984, 993, 994, 996, 1000, 1008, 1055, 1071, 1079, 1083, 1085, 1086, 1103, 1111, 1115, 1117, 1118, 1127, 1131, 1133, 1134, 1139, 1141, 1142, 1145, 1146, 1148, 1167, 1175, 1179, 1181, 1182, 1191, 1195, 1197, 1198, 1203, 1205, 1206, 1209, 1210, 1212, 1223, 1227, 1229, 1230, 1235, 1237, 1238, 1241, 1242, 1244, 1251, 1253, 1254, 1257, 1258, 1260, 1265, 1266, 1268, 1272, 1295, 1303, 1307, 1309, 1310, 1319, 1323, 1325, 1326, 1331, 1333, 1334, 1337, 1338, 1340, 1351, 1355, 1357, 1358, 1363, 1365, 1366, 1369, 1370, 1372, 1379, 1381, 1382, 1385, 1386, 1388, 1393, 1394, 1396, 1400, 1415, 1419, 1421, 1422, 1427, 1429, 1430, 1433, 1434, 1436, 1443, 1445, 1446, 1449, 1450, 1452, 1457, 1458, 1460, 1464, 1475, 1477, 1478, 1481, 1482, 1484, 1489, 1490, 1492, 1496, 1505, 1506, 1508, 1512, 1520, 1551, 1559, 1563, 1565, 1566, 1575, 1579, 1581, 1582, 1587, 1589, 1590, 1593, 1594, 1596, 1607, 1611, 1613, 1614, 1619, 1621, 1622, 1625, 1626, 1628, 1635, 1637, 1638, 1641, 1642, 1644, 1649, 1650, 1652, 1656, 1671, 1675, 1677, 1678, 1683, 1685, 1686, 1689, 1690, 1692, 1699, 1701, 1702, 1705, 1706, 1708, 1713, 1714, 1716, 1720, 1731, 1733, 1734, 1737, 1738, 1740, 1745, 1746, 1748, 1752, 1761, 1762, 1764, 1768, 1776, 1799, 1803, 1805, 1806, 1811, 1813, 1814, 1817, 1818, 1820, 1827, 1829, 1830, 1833, 1834, 1836, 1841, 1842, 1844, 1848, 1859, 1861, 1862, 1865, 1866, 1868, 1873, 1874, 1876, 1880, 1889, 1890, 1892, 1896, 1904, 1923, 1925, 1926, 1929, 1930, 1932, 1937, 1938, 1940, 1944, 1953, 1954, 1956, 1960, 1968, 1985, 1986, 1988, 1992, 2000, 2016, 2079, 2095, 2103, 2107, 2109, 2110, 2127, 2135, 2139, 2141, 2142, 2151, 2155, 2157, 2158, 2163, 2165, 2166, 2169, 2170, 2172, 2191, 2199, 2203, 2205, 2206, 2215, 2219, 2221, 2222, 2227, 2229, 2230, 2233, 2234, 2236, 2247, 2251, 2253, 2254, 2259, 2261, 2262, 2265, 2266, 2268, 2275, 2277, 2278, 2281, 2282, 2284, 2289, 2290, 2292, 2296, 2319, 2327, 2331, 2333, 2334, 2343, 2347, 2349, 2350, 2355, 2357, 2358, 2361, 2362, 2364, 2375, 2379, 2381, 2382, 2387, 2389, 2390, 2393, 2394, 2396, 2403, 2405, 2406, 2409, 2410, 2412, 2417, 2418, 2420, 2424, 2439, 2443, 2445, 2446, 2451, 2453, 2454, 2457, 2458, 2460, 2467, 2469, 2470, 2473, 2474, 2476, 2481, 2482, 2484, 2488, 2499, 2501, 2502, 2505, 2506, 2508, 2513, 2514, 2516, 2520, 2529, 2530, 2532, 2536, 2544, 2575, 2583, 2587, 2589, 2590, 2599, 2603, 2605, 2606, 2611, 2613, 2614, 2617, 2618, 2620, 2631, 2635, 2637, 2638, 2643, 2645, 2646, 2649, 2650, 2652, 2659, 2661, 2662, 2665, 2666, 2668, 2673, 2674, 2676, 2680, 2695, 2699, 2701, 2702, 2707, 2709, 2710, 2713, 2714, 2716, 2723, 2725, 2726, 2729, 2730, 2732, 2737, 2738, 2740, 2744, 2755, 2757, 2758, 2761, 2762, 2764, 2769, 2770, 2772, 2776, 2785, 2786, 2788, 2792, 2800, 2823, 2827, 2829, 2830, 2835, 2837, 2838, 2841, 2842, 2844, 2851, 2853, 2854, 2857, 2858, 2860, 2865, 2866, 2868, 2872, 2883, 2885, 2886, 2889, 2890, 2892, 2897, 2898, 2900, 2904, 2913, 2914, 2916, 2920, 2928, 2947, 2949, 2950, 2953, 2954, 2956, 2961, 2962, 2964, 2968, 2977, 2978, 2980, 2984, 2992, 3009, 3010, 3012, 3016, 3024, 3040, 3087, 3095, 3099, 3101, 3102, 3111, 3115, 3117, 3118, 3123, 3125, 3126,3129,3130,3132,3143,3147,3149,3150,3155,3157,3158,3161,3162,3164,3171, 3173, 3174, 3177, 3178, 3180, 3185, 3186, 3188, 3192, 3207, 3211, 3213, 3214, 3219, 3221, 3222, 3225, 3226, 3228, 3235, 3237, 3238, 3241, 3242, 3244, 3249, 3250, 3252, 3256, 3267, 3269, 3270, 3273, 3274, 3276, 3281, 3282, 3284, 3288, 3297, 3298, 3300, 3304, 3312, 3335, 3339, 3341, 3342, 3347, 3349, 3350, 3353, 3354, 3356, 3363, 3365, 3366, 3369, 3370, 3372, 3377, 3378, 3380, 3384, 3395, 3397, 3398, 3401, 3402, 3404, 3409, 3410, 3412, 3416, 3425, 3426, 3428, 3432, 3440, 3459, 3461, 3462, 3465, 3466, 3468, 3473, 3474, 3476, 3480, 3489, 3490, 3492, 3496, 3504, 3521, 3522, 3524, 3528, 3536, 3552, 3591, 3595, 3597, 3598, 3603, 3605, 3606, 3609, 3610, 3612, 3619, 3621, 3622, 3625, 3626, 3628, 3633, 3634, 3636, 3640, 3651, 3653, 3654, 3657, 3658, 3660, 3665, 3666, 3668, 3672, 3681, 3682, 3684, 3688, 3696, 3715, 3717, 3718, 3721, 3722, 3724, 3729, 3730, 3732, 3736, 3745, 3746, 3748, 3752, 3760, 3777, 3778, 3780, 3784, 3792, 3808, 3843, 3845, 3846, 3849, 3850, 3852, 3857, 3858, 3860, 3864, 3873, 3874, 3876, 3880, 3888, 3905, 3906, 3908, 3912, 3920, 3936, 3969, 3970, 3972, 3976, 3984, 4000, 4032, 127, 191, 223, 239, 247, 251, 253, 254, 319, 351, 367, 375, 379, 381, 382, 415, 431, 439, 443, 445, 446, 463, 471, 475, 477, 478, 487, 491, 493, 494, 499, 501, 502, 505, 506, 508, 575, 607, 623, 631, 635, 637, 638, 671, 687, 695, 699, 701, 702, 719, 727, 731, 733, 734, 743, 747, 749, 750, 755, 757, 758, 761, 762, 764, 799, 815, 823, 827, 829, 830, 847, 855, 859, 861, 862, 871, 875, 877, 878, 883, 885, 886, 889, 890, 892, 911, 919, 923, 925, 926, 935, 939, 941, 942, 947, 949, 950, 953, 954, 956, 967, 971, 973, 974, 979, 981, 982, 985, 986, 988, 995, 997, 998, 1001, 1002, 1004, 1009, 1010, 1012, 1016, 1087, 1119, 1135, 1143, 1147, 1149, 1150, 1183, 1199, 1207, 1211, 1213, 1214, 1231, 1239, 1243, 1245, 1246, 1255, 1259, 1261, 1262, 1267, 1269, 1270, 1273, 1274, 1276, 1311, 1327, 1335, 1339, 1341, 1342, 1359, 1367, 1371, 1373, 1374, 1383, 1387, 1389, 1390, 1395, 1397, 1398, 1401, 1402, 1404, 1423, 1431, 1435, 1437, 1438, 1447, 1451, 1453, 1454, 1459, 1461, 1462, 1465, 1466, 1468, 1479, 1483, 1485, 1486, 1491, 1493, 1494, 1497, 1498, 1500, 1507, 1509, 1510, 1513, 1514, 1516, 1521, 1522, 1524, 1528, 1567, 1583, 1591, 1595, 1597, 1598, 1615, 1623, 1627, 1629, 1630, 1639, 1643, 1645, 1646, 1651, 1653, 1654, 1657, 1658, 1660, 1679, 1687, 1691, 1693, 1694, 1703, 1707, 1709, 1710, 1715, 1717, 1718, 1721, 1722, 1724, 1735, 1739, 1741, 1742, 1747, 1749, 1750, 1753, 1754, 1756, 1763, 1765, 1766, 1769, 1770, 1772, 1777, 1778, 1780, 1784, 1807, 1815, 1819, 1821, 1822, 1831, 1835, 1837, 1838, 1843, 1845, 1846, 1849, 1850, 1852, 1863, 1867, 1869, 1870, 1875, 1877, 1878, 1881, 1882, 1884, 1891, 1893, 1894, 1897, 1898, 1900, 1905, 1906, 1908, 1912, 1927, 1931, 1933, 1934, 1939, 1941, 1942, 1945, 1946, 1948, 1955, 1957, 1958, 1961, 1962, 1964, 1969, 1970, 1972, 1976, 1987, 1989, 1990, 1993, 1994, 1996, 2001, 2002, 2004, 2008, 2017, 2018, 2020, 2024, 2032, 2111, 2143, 2159, 2167, 2171, 2173, 2174, 2207, 2223, 2231, 2235, 2237, 2238, 2255, 2263, 2267, 2269, 2270, 2279, 2283, 2285, 2286, 2291, 2293, 2294, 2297, 2298, 2300, 2335, 2351, 2359, 2363, 2365, 2366, 2383, 2391, 2395, 2397, 2398, 2407, 2411, 2413, 2414, 2419, 2421, 2422, 2425, 2426, 2428, 2447, 2455, 2459, 2461, 2462, 2471, 2475, 2477, 2478, 2483, 2485, 2486, 2489, 2490, 2492, 2503, 2507, 2509, 2510, 2515, 2517, 2518, 2521, 2522, 2524, 2531, 2533, 2534, 2537, 2538, 2540, 2545, 2546, 2548, 2552, 2591, 2607, 2615, 2619, 2621, 2622, 2639, 2647, 2651, 2653, 2654, 2663, 2667, 2669, 2670, 2675, 2677, 2678, 2681, 2682, 2684, 2703, 2711, 2715, 2717, 2718, 2727, 2731, 2733, 2734, 2739, 2741, 2742, 2745, 2746, 2748, 2759, 2763, 2765, 2766, 2771, 2773, 2774, 2777, 2778, 2780, 2787, 2789, 2790, 2793, 2794, 2796, 2801, 2802, 2804, 2808, 2831, 2839, 2843, 2845, 2846, 2855, 2859, 2861, 2862, 2867, 2869, 2870, 2873, 2874, 2876, 2887, 2891, 2893, 2894, 2899, 2901, 2902, 2905, 2906, 2908, 2915, 2917, 2918, 2921, 2922, 2924, 2929, 2930, 2932, 2936, 2951, 2955, 2957, 2958, 2963, 2965, 2966, 2969, 2970, 2972, 2979, 2981, 2982, 2985, 2986, 2988, 2993, 2994, 2996, 3000, 3011, 3013, 3014, 3017, 3018, 3020, 3025, 3026, 3028, 3032, 3041, 3042, 3044, 3048, 3056, 3103, 3119, 3127, 3131, 3133, 3134, 3151, 3159, 3163, 3165, 3166, 3175, 3179, 3181, 3182, 3187, 3189, 3190, 3193, 3194, 3196, 3215, 3223, 3227, 3229, 3230, 3239, 3243, 3245, 3246, 3251, 3253, 3254, 3257, 3258, 3260, 3271, 3275, 3277, 3278, 3283, 3285, 3286, 3289, 3290, 3292, 3299, 3301, 3302, 3305, 3306, 3308, 3313, 3314, 3316, 3320, 3343, 3351, 3355, 3357, 3358, 3367, 3371, 3373, 3374, 3379, 3381, 3382, 3385, 3386, 3388, 3399, 3403, 3405, 3406, 3411, 3413, 3414, 3417, 3418, 3420, 3427, 3429, 3430, 3433, 3434, 3436, 3441, 3442, 3444, 3448, 3463, 3467, 3469, 3470, 3475, 3477, 3478, 3481, 3482, 3484, 3491, 3493, 3494, 3497, 3498, 3500, 3505, 3506, 3508, 3512, 3523, 3525, 3526, 3529, 3530, 3532, 3537, 3538, 3540, 3544, 3553, 3554, 3556, 3560, 3568, 3599, 3607, 3611, 3613, 3614, 3623, 3627, 3629, 3630, 3635, 3637, 3638, 3641, 3642, 3644, 3655, 3659, 3661, 3662, 3667, 3669, 3670, 3673, 3674, 3676, 3683, 3685, 3686, 3689, 3690, 3692, 3697, 3698, 3700, 3704, 3719, 3723, 3725, 3726, 3731, 3733, 3734, 3737, 3738, 3740, 3747, 3749, 3750, 3753, 3754, 3756, 3761, 3762, 3764, 3768, 3779, 3781, 3782, 3785, 3786, 3788, 3793, 3794, 3796, 3800, 3809, 3810, 3812, 3816, 3824, 3847, 3851, 3853, 3854, 3859, 3861, 3862, 3865, 3866, 3868, 3875, 3877, 3878, 3881, 3882, 3884, 3889, 3890, 3892, 3896, 3907, 3909, 3910, 3913, 3914, 3916, 3921, 3922, 3924, 3928, 3937, 3938, 3940, 3944, 3952, 3971, 3973, 3974, 3977, 3978, 3980, 3985, 3986, 3988, 3992, 4001, 4002, 4004, 4008, 4016, 4033, 4034, 4036, 4040, 4048, 4064, 255, 383, 447, 479, 495, 503, 507, 509, 510, 639, 703, 735, 751, 759, 763, 765, 766, 831, 863, 879, 887, 891, 893, 894, 927, 943, 951, 955, 957, 958, 975, 983, 987, 989, 990, 999, 1003, 1005, 1006, 1011, 1013, 1014, 1017, 1018, 1020, 1151, 1215, 1247, 1263, 1271, 1275, 1277, 1278, 1343, 1375, 1391, 1399, 1403, 1405, 1406, 1439, 1455, 1463, 1467, 1469, 1470, 1487, 1495, 1499, 1501, 1502, 1511, 1515, 1517, 1518, 1523, 1525, 1526, 1529, 1530, 1532, 1599, 1631, 1647, 1655, 1659, 1661, 1662, 1695, 1711, 1719, 1723, 1725, 1726, 1743, 1751, 1755, 1757, 1758, 1767, 1771, 1773, 1774, 1779, 1781, 1782, 1785, 1786, 1788, 1823, 1839, 1847, 1851, 1853, 1854, 1871, 1879, 1883, 1885, 1886, 1895, 1899, 1901, 1902, 1907, 1909, 1910, 1913, 1914, 1916, 1935, 1943, 1947, 1949, 1950, 1959, 1963, 1965, 1966, 1971, 1973, 1974, 1977, 1978, 1980, 1991, 1995, 1997, 1998, 2003, 2005, 2006, 2009, 2010, 2012, 2019, 2021, 2022, 2025, 2026, 2028, 2033, 2034, 2036, 2040, 2175, 2239, 2271, 2287, 2295, 2299, 2301, 2302, 2367, 2399, 2415, 2423, 2427, 2429, 2430, 2463, 2479, 2487, 2491, 2493, 2494, 2511, 2519, 2523, 2525, 2526, 2535, 2539, 2541, 2542, 2547, 2549, 2550, 2553, 2554, 2556, 2623, 2655, 2671, 2679, 2683, 2685, 2686, 2719, 2735, 2743, 2747, 2749, 2750, 2767, 2775, 2779, 2781, 2782, 2791, 2795, 2797, 2798, 2803, 2805, 2806, 2809, 2810, 2812, 2847, 2863, 2871, 2875, 2877, 2878, 2895, 2903, 2907, 2909, 2910, 2919, 2923, 2925, 2926, 2931, 2933, 2934, 2937, 2938, 2940, 2959, 2967, 2971, 2973, 2974, 2983, 2987, 2989, 2990, 2995, 2997, 2998, 3001, 3002, 3004, 3015, 3019, 3021, 3022, 3027, 3029, 3030, 3033, 3034, 3036, 3043, 3045, 3046, 3049, 3050, 3052, 3057, 3058, 3060, 3064, 3135, 3167, 3183, 3191, 3195, 3197, 3198, 3231, 3247, 3255, 3259, 3261, 3262, 3279, 3287, 3291, 3293, 3294, 3303, 3307, 3309, 3310, 3315, 3317, 3318, 3321, 3322, 3324, 3359, 3375, 3383, 3387, 3389, 3390, 3407, 3415, 3419, 3421, 3422, 3431, 3435, 3437, 3438, 3443, 3445, 3446, 3449, 3450, 3452, 3471, 3479, 3483, 3485, 3486, 3495, 3499, 3501, 3502, 3507, 3509, 3510, 3513, 3514, 3516, 3527, 3531, 3533, 3534, 3539, 3541, 3542, 3545, 3546, 3548, 3555, 3557, 3558, 3561, 3562, 3564, 3569, 3570, 3572, 3576, 3615, 3631, 3639, 3643, 3645, 3646, 3663, 3671, 3675, 3677, 3678, 3687, 3691, 3693, 3694, 3699, 3701, 3702, 3705, 3706, 3708, 3727, 3735, 3739, 3741, 3742, 3751, 3755, 3757, 3758, 3763, 3765, 3766, 3769, 3770, 3772, 3783, 3787, 3789, 3790, 3795, 3797, 3798, 3801, 3802, 3804, 3811, 3813, 3814, 3817, 3818, 3820, 3825, 3826, 3828, 3832, 3855, 3863, 3867, 3869, 3870, 3879, 3883, 3885, 3886, 3891, 3893, 3894, 3897, 3898, 3900, 3911, 3915, 3917, 3918, 3923, 3925, 3926, 3929, 3930, 3932, 3939, 3941, 3942, 3945, 3946, 3948, 3953, 3954, 3956, 3960, 3975, 3979, 3981, 3982, 3987, 3989, 3990, 3993, 3994, 3996, 4003, 4005, 4006, 4009, 4010, 4012, 4017, 4018, 4020, 4024, 4035, 4037, 4038, 4041, 4042, 4044, 4049, 4050, 4052, 4056, 4065, 4066, 4068, 4072, 4080, 511, 767, 895, 959, 991, 1007, 1015, 1019, 1021, 1022, 1279, 1407, 1471, 1503, 1519, 1527, 1531, 1533, 1534, 1663, 1727, 1759, 1775, 1783, 1787, 1789, 1790, 1855, 1887, 1903, 1911, 1915, 1917, 1918, 1951, 1967, 1975, 1979, 1981, 1982, 1999, 2007, 2011, 2013, 2014, 2023, 2027, 2029, 2030, 2035, 2037, 2038, 2041, 2042, 2044, 2303, 2431, 2495, 2527, 2543, 2551, 2555, 2557, 2558, 2687, 2751, 2783, 2799, 2807, 2811, 2813, 2814, 2879, 2911, 2927, 2935, 2939, 2941, 2942, 2975, 2991, 2999, 3003, 3005, 3006, 3023, 3031, 3035, 3037, 3038, 3047, 3051, 3053, 3054, 3059, 3061, 3062, 3065, 3066, 3068, 3199, 3263, 3295, 3311, 3319, 3323, 3325, 3326, 3391, 3423, 3439, 3447, 3451, 3453, 3454, 3487, 3503, 3511, 3515, 3517, 3518, 3535, 3543, 3547, 3549, 3550, 3559, 3563, 3565, 3566, 3571, 3573, 3574, 3577, 3578, 3580, 3647, 3679, 3695, 3703, 3707, 3709, 3710, 3743, 3759, 3767, 3771, 3773, 3774, 3791, 3799, 3803, 3805, 3806, 3815, 3819, 3821, 3822, 3827, 3829, 3830, 3833, 3834, 3836, 3871, 3887, 3895, 3899, 3901, 3902, 3919, 3927, 3931, 3933, 3934, 3943, 3947, 3949, 3950, 3955, 3957, 3958, 3961, 3962, 3964, 3983, 3991, 3995, 3997, 3998, 4007, 4011, 4013, 4014, 4019, 4021, 4022, 4025, 4026, 4028, 4039, 4043, 4045, 4046, 4051, 4053, 4054, 4057, 4058, 4060, 4067, 4069, 4070, 4073, 4074, 4076, 4081, 4082, 4084, 4088, 1023, 1535, 1791, 1919, 1983, 2015, 2031, 2039, 2043, 2045, 2046, 2559, 2815, 2943, 3007, 3039, 3055, 3063, 3067, 3069, 3070, 3327, 3455, 3519, 3551, 3567, 3575, 3579, 3581, 3582, 3711, 3775, 3807, 3823, 3831, 3835, 3837, 3838, 3903, 3935, 3951, 3959, 3963, 3965, 3966, 3999, 4015, 4023, 4027, 4029, 4030, 4047, 4055, 4059, 4061, 4062, 4071, 4075, 4077, 4078, 4083, 4085, 4086, 4089, 4090, 4092, 2047, 3071, 3583, 3839, 3967, 4031, 4063, 4079, 4087, 4091, 4093, 4094, 4095].

3. The method of claim 1, wherein determining the input u_n includes:
determining an input v_n for a convolution based on the length N of the polar code, the length K of the information block, and the polar sequence Q^{N-1}₀={Q₀, Q₁, . . . , Q_{N-1}} of length N; and
determining the input u_n based on performing the convolution on the input v_n.

4. The method of claim 3, wherein performing the convolution includes:
determining a number of shift registers based on the length N of the polar code from among predetermined numbers of shift registers for mother code sizes; and
performing the convolution on the input v_n based on the determined number of shift registers.

5. The method of claim 4, wherein the predetermined numbers of the shift registers are greater than or equal to respective maximum numbers of consecutive frozen bits for the mother code sizes.

6. The method of claim 3, wherein performing the convolution includes determining the input u_n based on
$${u}_{n} = {v}_{n} + {Σ}_{k = 1}^{m} {c}_{k} {u}_{n - k} .$$

7. The method of claim 6, wherein the same number of shift registers are used for different mother code sizes.

8. A communication device comprising:
at least one transceiver;
at least one processor; and
at least one computer memory operably connected to the at least one processor and storing instructions that, when executed, cause the at least one processor to perform operations including:
determining an input u_n to a polar code based on a length N of the polar code, a length K of an information block, and a polar sequence Q^{N-1}₀={Q₀, Q₁, . . . , Q_{N-1}} of length N;
determining coded bits based on the input u_n being encoded based on the polar code of length N and the polar sequence Q^{N-1}₀={Q₀, Q₁, . . . , Q_{N-1}} of length N; and
transmitting the coded bits to another communication device,
wherein the polar sequence Q^{N-1}₀={Q₀, Q₁, . . . , Q_{N-1}} of length N is defined in ascending order of a reliability W(Q^{N}₀)<W(Q^{N}₁)< . . . <W(Q^{N}_{N-1}), where 0<=Q^{N}ᵢ<=N−1 is a bit index for i=0, 1, . . . , N−1 and W(Q^{N}ᵢ) is a reliability of bit index Q^{N}ᵢ,
wherein determining the input u_n includes determining K input indices at which K bits of the information block are to be located and input indices to be frozen from among input indices 0 to N−1 of the polar code of length N, based on the polar sequence Q^{N-1}₀={Q₀, Q₁, . . . , Q_{N-1}} of length N, and
wherein bit indices of the polar sequence Q^{N-1}₀={Q₀, Q₁, . . . , Q_{N-1}} of length N satisfy: i) a reliability increases as a number of is when expressed in binary increases, and ii) bit indices having the same number of is when expressed in binary are W(Q^{N}ₓ)<W(Q^{N}_{y}) for Q^{N}ₓ<Q^{N}_{y}.

9. (canceled)

10. A non-transitory computer-readable storage medium, the storage medium storing at least one processor code including instructions that, when executed, cause at least one processor to perform operations comprising:
determining an input u_n to a polar code based on a length N of the polar code, a length K of an information block, and a polar sequence Q^{N-1}₀={Q₀, Q₁, . . . , Q_{N-1}} of length N;
determining coded bits based on the input u_n being encoded based on the polar code of length N and the polar sequence Q^{N-1}₀={Q₀, Q₁, . . . , Q_{N-1}} of length N; and
transmitting the coded bits to another communication device,
wherein the polar sequence Q^{N-1}₀={Q₀, Q₁, . . . , Q_{N-1}} of length N is defined in ascending order of reliability W(Q^{N}₀)<W(Q^{N}₁)< . . . <W(Q^{N}_{N-1}), where 0<=Q^{N}ᵢ<=N−1 is a bit index for i=0, 1, . . . , N−1 and W(Q^{N}ᵢ) is reliability of bit index Q^{N}ᵢ,
wherein determining the input u_n includes determining K input indices at which K bits of the information block are to be located and input indices to be frozen from among input indices 0 to N−1 of the polar code of length N, based on the polar sequence Q^{N-1}₀={Q₀, Q₁, . . . , Q_{N-1}} of length N, and
wherein bit indices of the polar sequence Q^{N-1}₀={Q₀, Q₁, . . . , Q_{N-1}} of length N satisfy: i) reliability increases as a number of is when expressed in binary increases, and ii) bit indices having the same number of is when expressed in binary are W(Q^{N}ₓ)<W(Q^{N}_{y}) for Q^{N}ₓ<Q^{N}_{y}.
